(19) United States
(12) Patent Application Publication
(10) Pub. No.: US 2026/0271508 A1
(43) Pub. Date: Sep. 10, 2026

(54) Light-Emitting Device

(71) Applicant: Semiconductor Energy Laboratory Co., Ltd., Kanagawa-ken (JP)

(72) Inventors: Takeyoshi WATABE, Atsugi (JP); Nobuharu OHSAWA, Zama (JP)

(73) Assignee: Semiconductor Energy Laboratory Co., Ltd., Kanagawa-ken (JP)

(21) Appl. No.: 19/555,039

(22) Filed: Mar. 3, 2026

(30) Foreign Application Priority Data
Mar. 7, 2025 (JP) 2025-036779

(51) Int. Cl. H10K 50/16

(52) U.S. Cl. CPC H10K 50/166

(57) ABSTRACT

A light-emitting device having favorable characteristics and a wide range of material choices. The light-emitting device includes an anode over an insulating surface, a cathode opposite to the anode, and a first electron-transport layer and a second electron-transport layer which are between the anode and the cathode. The first electron-transport layer and the second electron-transport layer are in contact with each other. The second electron-transport layer and the cathode are in contact with each other. The GSP_Slope (mV/nm) of an evaporated film of a material included in the second electron-transport layer is larger than the GSP_Slope (mV/nm) of an evaporated film of a material included in the first electron-transport layer. The thickness of the second electron-transport layer is greater than 0 nm and less than 10 nm. The GSP_Slope (mV/nm) is represented by ΔV/Δd, where ΔV (mV) is an amount of change in a surface potential with respect to an amount of change in a thickness Δd (nm).

### BACKGROUND OF THE INVENTION

### 1. Field of the Invention

One embodiment of the present invention relates to an organic compound, an organic semiconductor element, a light-emitting element, an organic EL element, a photodiode, a display module, a lighting module, a display device, a light-emitting apparatus, an electronic appliance, a lighting device, and an electronic device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display device, a liquid crystal display device, a light-emitting apparatus, a lighting device, a power storage device, a memory device, an image capturing device, a driving method thereof, and a manufacturing method thereof.

### 2. Description of the Related Art

Light-emitting devices (organic EL elements) including organic compounds and utilizing electroluminescence (EL) have been put into practical use. In the basic structure of such organic EL elements, an organic compound layer containing a light-emitting material (an EL layer) is located between a pair of electrodes. Carriers are injected by application of voltage to the device, and recombination energy of the carriers is used, whereby light emission can be obtained from the light-emitting material.

Such organic EL elements are of self-luminous type and thus have advantages over liquid crystal elements, such as high visibility and no need for backlight when used as pixels of a display, and are particularly suitable for flat panel displays. Displays including such organic EL elements are also highly advantageous in that they can be thin and lightweight. Another feature of such organic EL elements is that they have an extremely fast response speed.

Since light-emitting layers of such organic EL elements can be formed as continuous planar layers, planar light emission can be achieved. This feature is difficult to realize with point light sources typified by incandescent lamps and LEDs or linear light sources typified by fluorescent lamps; thus, the organic EL elements also have great potential as planar light sources, which can be used for lighting devices and the like.

Displays or lighting devices that include organic EL elements are suitable for a variety of electronic appliances as described above, and research and development of organic EL elements have progressed for better characteristics.

### REFERENCE

### Non-Patent Document

[Non-Patent Document 1] Yutaka Noguchi et al., “Spontaneous Orientation Polarization of Polar Molecules and Interface Properties of Organic Electronic Devices”, Journal of the Vacuum Society of Japan, 2015, Vol. 58, No. 3
[Non-Patent Document 2] Yutaka Noguchi et al., “Spontaneous orientation polarization in organic light-emitting diodes”, Japanese Journal of Applied Physics, 2019, Vol. 58, SF0801
[Non-Patent Document 3] Masaki Tanaka et al., “Spontaneous formation of metastable orientation with well-organized permanent dipole moment in organic glassy films”, Nature Materials, 2022, Vol. 21, pp. 819-825.

### SUMMARY OF THE INVENTION

An object of one embodiment of the present invention is to expand the range of material choices for a light-emitting device. An object of another embodiment of the present invention is to expand the range of material choices for a light-emitting device and provide a light-emitting device with favorable characteristics. An object of another embodiment of the present invention is to provide a light-emitting device with high current efficiency. An object of another embodiment of the present invention is to provide a light-emitting device with high external quantum efficiency. An object of another embodiment of the present invention is to provide a light-emitting device with a low driving voltage. An object of another embodiment of the present invention is to provide a light-emitting device with high power efficiency. An object of another embodiment of the present invention is to provide a light-emitting device with high reliability.

An object of another embodiment of the present invention is to provide any of a light-emitting apparatus, an electronic appliance, and a display device each having favorable characteristics. An object of another embodiment of the present invention is to provide any of a light-emitting apparatus, an electronic appliance, and a display device each having low power consumption. An object of another embodiment of the present invention is to provide any of a light-emitting apparatus, an electronic appliance, and a display device each having high reliability.

Note that the description of these objects does not preclude the existence of other objects. One embodiment of the present invention does not need to achieve all these objects. Other objects will be apparent from and can be derived from the description of the specification, the drawings, the claims, and the like.

One embodiment of the present invention is a light-emitting device including an anode over an insulating surface, a cathode opposite to the anode, and a first electron-transport layer and a second electron-transport layer which are between the anode and the cathode. The first electron-transport layer and the second electron-transport layer are in contact with each other. The second electron-transport layer and the cathode are in contact with each other. The GSP_Slope (mV/nm) of an evaporated film of a material included in the first electron-transport layer is smaller than 0 mV/nm. The thickness of the second electron-transport layer is greater than 0 nm and less than 10 nm.

Another embodiment of the present invention is a light-emitting device including an anode over an insulating surface, a cathode opposite to the anode, and a first electron-transport layer and a second electron-transport layer which are between the anode and the cathode. The first electron-transport layer and the second electron-transport layer are in contact with each other. The second electron-transport layer and the cathode are in contact with each other. The GSP_Slope (mV/nm) of an evaporated film of a material included in the second electron-transport layer is larger than the GSP_Slope (mV/nm) of an evaporated film of a material included in the first electron-transport layer. The thickness of the second electron-transport layer is greater than 0 nm and less than 10 nm.

Another embodiment of the present invention is a light-emitting device including an anode over an insulating surface, a cathode opposite to the anode, and a first electron-transport layer and a second electron-transport layer which are between the anode and the cathode. The first electron-transport layer and the second electron-transport layer are in contact with each other. The second electron-transport layer and the cathode are in contact with each other. The GSP_Slope (mV/nm) of an evaporated film of a material included in the second electron-transport layer is larger than the GSP_Slope (mV/nm) of an evaporated film of a material included in the first electron-transport layer. The thickness of the second electron-transport layer is smaller than the thickness of the first electron-transport layer.

Another embodiment of the present invention is a light-emitting device including an anode over an insulating surface, a cathode opposite to the anode, and a first electron-transport layer, a second electron-transport layer, and an electron-injection layer which are between the anode and the cathode. The first electron-transport layer and the second electron-transport layer are in contact with each other. The second electron-transport layer and the electron-injection layer are in contact with each other. The electron-injection layer and the cathode are in contact with each other. The GSP_Slope (mV/nm) of an evaporated film of a material included in the first electron-transport layer is smaller than 0 mV/nm. The total thickness of the second electron-transport layer and the electron-injection layer is greater than 0 nm and less than 10 nm.

Another embodiment of the present invention is a light-emitting device including an anode over an insulating surface, a cathode opposite to the anode, and a first electron-transport layer, a second electron-transport layer, and an electron-injection layer which are between the anode and the cathode. The first electron-transport layer and the second electron-transport layer are in contact with each other. The second electron-transport layer and the electron-injection layer are in contact with each other. The electron-injection layer and the cathode are in contact with each other. The GSP_Slope (mV/nm) of an evaporated film of a material included in the second electron-transport layer is larger than the GSP_Slope (mV/nm) of an evaporated film of a material included in the first electron-transport layer. The total thickness of the second electron-transport layer and the electron-injection layer is greater than 0 nm and less than 10 nm.

Another embodiment of the present invention is a light-emitting device including an anode over an insulating surface, a cathode opposite to the anode, and a first electron-transport layer, a second electron-transport layer, and an electron-injection layer which are between the anode and the cathode. The first electron-transport layer and the second electron-transport layer are in contact with each other. The second electron-transport layer and the electron-injection layer are in contact with each other. The electron-injection layer and the cathode are in contact with each other. The GSP_Slope (mV/nm) of an evaporated film of a material included in the second electron-transport layer is larger than the GSP_Slope (mV/nm) of an evaporated film of a material included in the first electron-transport layer. The total thickness of the second electron-transport layer and the electron-injection layer is smaller than the thickness of the first electron-transport layer.

Another embodiment of the present invention is the light-emitting device with the above structure, in which the electron-injection layer contains at least one of an alkali metal, an alkaline earth metal, and ytterbium.

Another embodiment of the present invention is the light-emitting device with the above structure, in which the GSP_Slope (mV/nm) of the evaporated film of the material included in the first electron-transport layer is smaller than or equal to −50 mV/nm.

Another embodiment of the present invention is the light-emitting device with the above structure, in which the refractive index of the evaporated film of the material included in the first electron-transport layer is lower than the refractive index of the evaporated film of the material included in the second electron-transport layer.

Another embodiment of the present invention is the light-emitting device with the above structure, in which a light-emitting layer is further included between the first electron-transport layer and the anode, and the light-emitting layer and the first electron-transport layer are in contact with each other.

Another embodiment of the present invention is the light-emitting device with the above structure, in which the GSP_Slope (mV/nm) of the evaporated film of the material included in the light-emitting layer is larger than the GSP_Slope (mV/nm) of an evaporated film of a material included in the first electron-transport layer.

Another embodiment of the present invention is the light-emitting device with the above structure, in which the GSP_Slope (mV/nm) of the evaporated film of the material included in the light-emitting layer is larger than the GSP_Slope (mV/nm) of an evaporated film of a material included in the second electron-transport layer.

Another embodiment of the present invention is the light-emitting device with the above structure, in which a difference between the GSP_Slope (mV/nm) of the evaporated film of the material included in the first electron-transport layer and the GSP_Slope (mV/nm) of the evaporated film of the material included in the second electron-transport layer is larger than or equal to 10 mV/nm.

Another embodiment of the present invention is the light-emitting device with the above structure, in which a difference between the GSP_Slope (mV/nm) of the evaporated film of the material included in the first electron-transport layer and the GSP_Slope (mV/nm) of the evaporated film of the material included in the second electron-transport layer is larger than or equal to 50 mV/nm.

Another embodiment of the present invention is the light-emitting device with the above structure, in which the thickness of the second electron-transport layer is greater than or equal to 3 nm.

Another embodiment of the present invention is the light-emitting device with the above structure, in which the second electron-transport layer is a layer containing an organic compound including a pyridine ring and having an acid dissociation constant pKₐ greater than 3 or a layer containing an organic complex of an alkali metal and an organic compound including a π-electron deficient heteroaromatic ring.

Another embodiment of the present invention is the light-emitting device with the above structure, in which the first electron-transport layer and the second electron-transport layer contain the same organic compound including a π-electron deficient heteroaromatic ring, the organic compound including a π-electron deficient heteroaromatic ring included in the first electron-transport layer and the organic compound including a π-electron deficient heteroaromatic ring included in the second electron-transport layer are the same, and the second electron-transport layer contains an organic complex of an alkali metal.

Another embodiment of the present invention is the light-emitting device with the above structure, in which the refractive index of an evaporated film of a material included in the first electron-transport layer is lower than the refractive index of an evaporated film of a material included in the light-emitting layer.

Another embodiment of the present invention is the light-emitting device with the above structure, in which the refractive index of an evaporated film of a material included in the first electron-transport layer is lower than the refractive index of an evaporated film of a material included in the second electron-transport layer.

Another embodiment of the present invention is the light-emitting device with the above structure, in which the GSP_Slope (mV/nm) of the evaporated film of the material included in the first electron-transport layer is smaller than 0 mV/nm.

Another embodiment of the present invention is the light-emitting device with the above structure, in which the GSP_Slope (mV/nm) of the evaporated film of the material included in the first electron-transport layer is smaller than or equal to −50 mV/nm.

Another embodiment of the present invention is the light-emitting device with the above structure, in which the first electron-transport layer contains fluorine.

Another embodiment of the present invention is the light-emitting device with the above structure, in which the first electron-transport layer contains an organic compound including an electron-withdrawing group.

Another embodiment of the present invention is the light-emitting device with the above structure, in which the first electron-transport layer contains an organic compound including a fluoro group or a cyano group.

Note that the GSP_Slope (mV/nm) is represented by ΔV/Δd, where ΔV (mV) is an amount of change in a surface potential with respect to an amount of change in a thickness Δd (nm), and the refractive index is an ordinary refractive index at a peak wavelength of an emission spectrum of the light-emitting device.

Another embodiment of the present invention is an electronic appliance including any of the above-described light-emitting devices, and any of a sensor, an operation button, a speaker, and a microphone.

Another embodiment of the present invention is a lighting device including any of the above-described light-emitting devices and a housing.

Embodiments of the present invention are not limited to the above embodiments.

One embodiment of the present invention can expand the range of material choices for a light-emitting device. Another embodiment of the present invention can expand the range of material choices for a light-emitting device and provide a light-emitting device with favorable characteristics. Another embodiment of the present invention can provide a light-emitting device with high current efficiency. Another embodiment of the present invention can provide a light-emitting device with high external quantum efficiency. Another embodiment of the present invention can provide a light-emitting device with a low driving voltage. Another embodiment of the present invention can provide a light-emitting device with high power efficiency. Another embodiment of the present invention can provide a light-emitting device with high reliability.

Another embodiment of the present invention can provide any of a light-emitting apparatus, an electronic appliance, and a display device each having favorable characteristics. Another embodiment of the present invention can provide any of a light-emitting apparatus, an electronic appliance, and a display device each having low power consumption. Another embodiment of the present invention can provide any of a light-emitting apparatus, an electronic appliance, and a display device each having high reliability.

Note that the description of these effects does not preclude the existence of other effects. One embodiment of the present invention does not need to have all these effects. Other effects will be apparent from and can be derived from the description of the specification, the drawings, the claims, and the like.

### BRIEF DESCRIPTION OF THE DRAWINGS

FIGS. 1A and 1B each illustrate a structure of a light-emitting device.

FIG. 2 illustrates a structure of a light-emitting device.

FIGS. 3A and 3B each illustrate a structure of a light-emitting device.

FIG. 4 shows the capacitance-voltage characteristics of a measurement device 1 and a measurement device 2.

FIG. 5 shows the current density-voltage characteristics of the measurement devices 1 and 2.

FIGS. 6A and 6B each illustrate a structure of a light-emitting device.

FIGS. 7A and 7B are a top view and a cross-sectional view, respectively, of a light-emitting apparatus.

FIGS. 8A and 8B are perspective views illustrating a structure example of a display module.

FIGS. 9A and 9B are cross-sectional views each illustrating a structure example of a display device.

FIG. 10 is a perspective view illustrating a structure example of a display device.

FIG. 11 is a cross-sectional view illustrating a structure example of a display device.

FIG. 12 is a cross-sectional view illustrating a structure example of a display device.

FIG. 13 is a cross-sectional view illustrating a structure example of a display device.

FIGS. 14A to 14D illustrate examples of electronic appliances.

FIGS. 15A to 15F illustrate examples of electronic appliances.

FIGS. 16A to 16G illustrate examples of electronic appliances.

FIG. 17 shows the luminance-current density characteristics of light-emitting devices 1-0, 1-1, 1-2, 1-3, and 1-4.

FIG. 18 shows the current efficiency-luminance characteristics of the light-emitting devices 1-0 to 1-4.

FIG. 19 shows the luminance-voltage characteristics of the light-emitting devices 1-0 to 1-4.

FIG. 20 shows the current density-voltage characteristics of the light-emitting devices 1-0 to 1-4.

FIG. 21 shows the external quantum efficiency-luminance characteristics of the light-emitting devices 1-0 to 1-4.

FIG. 22 shows the electroluminescence spectra of the light-emitting devices 1-0 to 1-4.

FIG. 23 shows the relation between the voltage and the thickness of the second electron-transport layer of each of light-emitting devices 2a-1 to 2a-8 and light-emitting devices 2b-1 to 2b-5.

FIG. 24 shows the luminance-current density characteristics of light-emitting devices 3-1, 3-2, and 3-3.

FIG. 25 shows the current efficiency-luminance characteristics of the light-emitting devices 3-1 to 3-3.

FIG. 26 shows the luminance-voltage characteristics of the light-emitting devices 3-1 to 3-3.

FIG. 27 shows the current density-voltage characteristics of the light-emitting devices 3-1 to 3-3.

FIG. 28 shows the power efficiency-luminance characteristics of the light-emitting devices 3-1 to 3-3.

FIG. 29 shows the electroluminescence spectra of the light-emitting devices 3-1 to 3-3.

FIG. 30 shows the normalized luminance-time change characteristics of the light-emitting devices 3-1 to 3-3.

FIG. 31 illustrates a device structure of each of the measurement devices 1 and 2.

### DETAILED DESCRIPTION OF THE INVENTION

Embodiments of the present invention will be described in detail below with reference to the drawings. Note that the present invention is not limited to the following description, and the modes and details of the present invention can be modified in various ways without departing from the spirit and scope of the present invention. Therefore, the present invention should not be construed as being limited to the description in the following embodiments.

Note that the position, size, range, or the like of each component illustrated in drawings does not represent the actual position, size, range, or the like in some cases for easy understanding. Therefore, the disclosed invention is not necessarily limited to the position, size, range, or the like disclosed in the drawings and the like.

Ordinal numbers such as “first” and “second” in this specification and the like are used for convenience and do not limit the number or the order of components. The order of components includes, for example, the order of steps or the stacking order of layers. That is, the ordinal numbers used in embodiments of this specification are not necessarily the same as the ordinal numbers used in the claims in some cases. In addition, the ordinal numbers used in examples of this specification are not necessarily the same as the ordinal numbers used in the claims in some cases. Furthermore, the ordinal numbers used in embodiments of this specification are not necessarily the same as the ordinal numbers used in examples of this specification in some cases.

In the description of structures of the present invention in this specification and the like with reference to the drawings, the same components in different drawings are denoted by the same reference numeral in some cases.

In this specification and the like, the term “film” and the term “layer” can be interchanged with each other. For example, the term “conductive layer” can be changed to the term “conductive film” in some cases. Alternatively, for example, the term “insulating film” can be changed to the term “insulating layer” in some cases

Note that in this specification and the like, a photoluminescence (PL) spectrum refers to a spectrum obtained by separating light emitted from a sample irradiated with excitation light into different wavelengths and measuring the emission intensity distribution of each wavelength in fluorometry. Such a spectrum is also referred to as an emission spectrum in some cases. Note that an emission spectrum may include a fluorescence component and a phosphorescence component. In this specification and the like, an emission spectrum including a fluorescence component is particularly referred to as a fluorescence spectrum, and an emission spectrum including a phosphorescence component is particularly referred to as a phosphorescence spectrum in some cases.

In the case where light is incident on a material having optical anisotropy, light with a plane of vibration parallel to the optical axis is referred to as extraordinary light (rays) and light with a plane of vibration perpendicular to the optical axis is referred to as ordinary light (rays); the refractive index of the material with respect to ordinary light may differ from that with respect to extraordinary light. In such a case, the ordinary refractive index and the extraordinary refractive index can be separately calculated by anisotropy analysis. Note that in the case where the measured material has both the ordinary refractive index and the extraordinary refractive index, the ordinary refractive index is used as an index in this specification.

### Embodiment 1

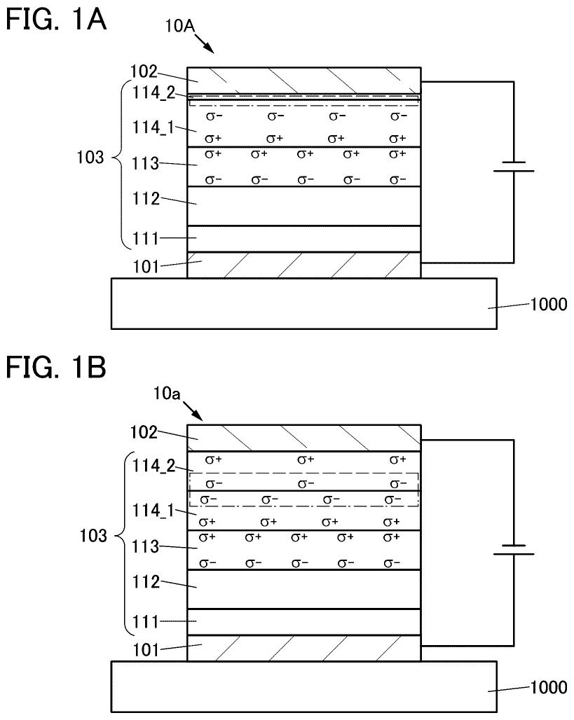

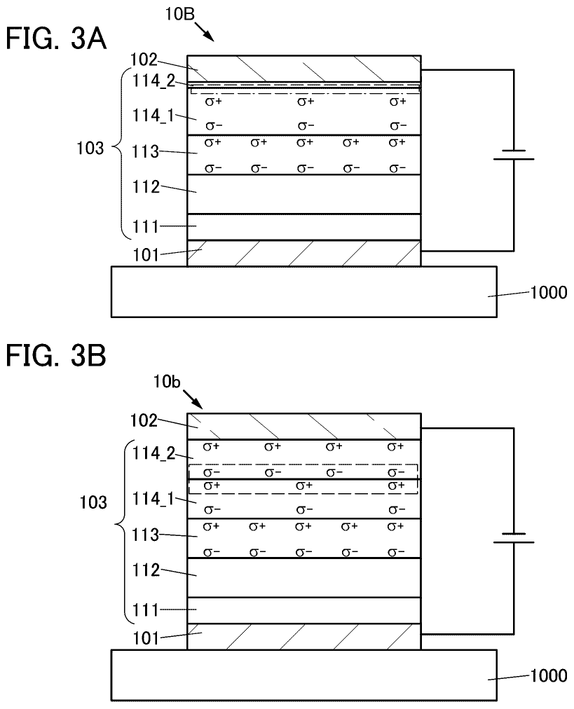

In this embodiment, a light-emitting device 10A and a light-emitting device 10B which are embodiments of the present invention are described with reference to FIG. 1A and FIG. 3A.

As illustrated in FIG. 1A and FIG. 3A, each of the light-emitting devices 10A and 10B is positioned over a substrate 1000. Each of the light-emitting devices 10A and 10B includes a first electrode 101, a second electrode 102, and an EL layer 103 positioned between the first electrode 101 and the second electrode 102. As illustrated in FIG. 1A and FIG. 3A, the EL layer 103 includes at least a light-emitting layer 113, a first electron-transport layer 114_1, and a second electron-transport layer 114_2. The first electron-transport layer 114_1 and the second electron-transport layer 114_2 have a function of transporting, to the light-emitting layer 113, electrons injected from either one of the first electrode 101 and the second electrode 102 to the EL layer 103. Note that the first electron-transport layer 114_1 is positioned between the light-emitting layer 113 and the second electron-transport layer 114_2.

As illustrated in FIG. 1A and FIG. 3A, in the light-emitting devices 10A and 10B, the first electrode 101 is formed over the substrate 1000. In other words, the first electrode 101 is provided between the second electrode 102 and the substrate 1000. That is, the first electrode 101 is provided earlier than the second electrode 102. Note that in the case where the substrate 1000 is provided with a transistor, the first electrode 101 is electrically connected to the transistor through a wiring. Alternatively, the first electrode 101 is provided over an insulating layer provided with an external connection electrode used as, for example, a terminal to which an FPC or the like is attached. Alternatively, an end portion of the first electrode 101 is covered with an insulating film.

In the light-emitting devices 10A and 10B, the first electrode 101 functions as an anode and the second electrode 102 functions as a cathode. In this specification and the like, in some cases, a light-emitting device like the light-emitting device 10A or the light-emitting device 10B in which the first electrode on the substrate side functions as an anode is referred to as an orderly stacked light-emitting device.

The orderly stacked light-emitting device (the light-emitting device 10A and the light-emitting device 10B) emits light when holes injected from the first electrode 101 functioning as an anode into the EL layer 103 and then transported through a hole-transport layer 112 are recombined with, in the light-emitting layer 113, electrons injected from the second electrode 102 functioning as a cathode into the EL layer 103 and then transported through an electron-transport layer 114. Thus, in the light-emitting devices 10A and 10B, the hole-transport layer 112 is positioned between the first electrode 101 and the light-emitting layer 113, and the electron-transport layer 114 is positioned between the second electrode 102 and the light-emitting layer 113.

In the light-emitting devices 10A and the light-emitting device 10B, the electron-transport layer 114 has a stacked-layer structure (a stack of the first electron-transport layer 114_1 and the second electron-transport layer 114_2). The hole-transport layer 112 may have a single-layer structure or a stacked-layer structure. Note that the first electron-transport layer 114_1 and the second electron-transport layer 114_2 are collectively referred to as the electron-transport layer 114 in some cases.

Note that the reason why the electron-transport layer 114 has a stacked-layer structure is because the layers have different functions: the first electron-transport layer 114_1 is responsible for electron transport and the second electron-transport layer 114_2 is responsible for electron injection from the cathode. A light-emitting device with a structure in which a layer formed with a material capable of electron injection from the cathode (the second electron-transport layer 114_2) is stacked over a layer formed with a material having an excellent electron-transport property but being less suitable for electron injection from the cathode (the first electron-transport layer 1141) performs electron injection and electron transport more smoothly than a light-emitting device including a single-layer electron-transport layer. The first electron-transport layer 114_1 preferably contains an organic compound including a π-electron deficient heteroaromatic ring. The second electron-transport layer 114_2 preferably contains an organic compound having an acid dissociation constant pKₐ larger than 3 and including a pyridine ring or contains an organic complex of an alkali metal and an organic compound including a π-electron deficient heteroaromatic ring.

Note that in the case where the second electron-transport layer 114_2 contains an organic complex of an alkali metal and an organic compound including a π-electron deficient heteroaromatic ring, a skeleton including the π-electron deficient heteroaromatic ring of the organic compound contained in the second electron-transport layer 114_2 and a skeleton including the π-electron deficient heteroaromatic ring of the organic compound contained in the first electron-transport layer 114_1 preferably include the same skeleton or are preferably the same skeleton, in which case electrons can be transported smoothly. The organic compound including the π-electron deficient heteroaromatic ring contained in the second electron-transport layer 114_2 and the organic compound including the π-electron deficient heteroaromatic ring contained in the first electron-transport layer 114_1 are preferably the same organic compound, in which case electrons can be transported smoothly and the productivity can be improved due to shared use of materials.

Each of the light-emitting devices 10A and 10B preferably includes the hole-transport layer 112 between the anode and the light-emitting layer 113, and further preferably includes a hole-injection layer 111 between the anode and the hole-transport layer 112. Each of the light-emitting devices 10A and 10B may include an electron-injection layer between the cathode and the electron-transport layer 114. Note that in the present invention, a layer formed using only an inorganic compound is regarded as an electrode, and a layer containing an organic compound is regarded as an EL layer. That is, the electron-injection layer is a layer containing an organic compound.

In each of the orderly stacked light-emitting device 10A illustrated in FIG. 1A and the orderly stacked light-emitting device 10B illustrated in FIG. 3A, the hole-injection layer 111, the hole-transport layer 112, the light-emitting layer 113, the electron-transport layer 114, and the second electrode 102 functioning as the cathode are stacked in this order over the first electrode 101 functioning as the anode.

Note that the structures of the light-emitting devices 10A and 10B are not limited to the structures illustrated in FIG. 1A and FIG. 3A. For example, the hole-transport layer may have a two-layer structure, or one or both of the hole-transport layer and the electron-transport layer may have a layered structure of three or more layers.

The present inventors have found that in the light-emitting devices 10A and 10B in which the electron-transport layer 114 has a stacked-layer structure, by setting the thickness of the second electron-transport layer 114_2 to greater than 0 nm and less than 10 nm, the light-emitting device can have favorable characteristics without consideration of the order of the slopes (GSP_Slope) of the giant surface potentials (GSP) of the first electron-transport layer 114_1 and the second electron-transport layer 114_2.

Note that GSP is a phenomenon due to spontaneous orientation polarization (SOP) caused by deviation in the thickness direction of permanent electric dipole moment orientation of a vapor deposited film.

The surface potential of an evaporated film with GSP changes linearly with increasing thickness without saturation. For example, the surface potential of a vapor deposited film of tris(8-quinolinolato)aluminum (abbreviation: Alq₃) reaches approximately 28 V at a thickness of 560 nm. The electric field strength reaches 5×10⁵ V/cm, which is approximately the same level as electric field strength during driving of a general light-emitting device.

The slope of GSP (GSP_Slope) is represented by ΔV/Δd, where ΔV is the amount of change in surface potential (mV) and Δd is the amount of change in thickness (nm) of a film whose GSP changes approximately in proportion to the thickness. Note that the GSP_Slope of a film whose surface potential increases with an increase in thickness is positive, and the GSP_Slope of a film whose surface potential decreases with an increase in thickness is negative. It can be said that Alq₃ described above is a material with a positive GSP_Slope. The potential of a layer with a positive GSP_Slope is lower on the substrate side, and the potential of a layer with a negative GSP_Slope is higher on the substrate side.

As described above, GSP is a phenomenon due to SOP caused by deviation of permanent electric dipole moment orientation to the thickness direction. That is, the following phenomena can be regarded as occurring: a negative polarization charge is induced on the substrate side of a layer with a positive GSP_Slope, and a positive polarization charge is induced on the second electrode side of the layer; in a similar manner, a positive polarization charge is induced on the substrate side of a layer with a negative GSP_Slope, and a negative polarization charge is induced on the second electrode side of the layer. Thus, GSP originates in such phenomena. In FIGS. 1A and 1B to FIGS. 3A and 3B, the degree of SOP caused by deviation of permanent electric dipole moment orientation to the thickness direction in each layer deposited by evaporation is indicated by σ+ or σ−; σ+ indicates positive polarization and σ− indicates negative polarization. A larger number of σ's in each layer in the vicinity of the interface with another layer means a higher degree of spontaneous polarization. The SOP of the layer exhibiting negative polarization on the substrate side and positive polarization on the second electrode side is positive.

In the case where a stacked-layer structure is formed with an organic compound 1 and an organic compound 2 both having a positive SOP in film form, when a second layer of the organic compound 2 is formed over and in contact with a first layer of the organic compound 1, the first layer and the second layer both have positive GSP_Slopes and it can be considered that a negative polarization charge is induced on the substrate side of each layer and a positive polarization charge is induced on the second electrode side of each layer. In that case, a negative polarization charge of the second layer on the first layer side is canceled out by a positive polarization charge of the first layer on the second layer side, and only a remaining charge can be regarded as an interface charge (fixed charge) at the interface between the first layer and the second layer. Note that a virtual charge that can be regarded as an interface charge is sometimes referred to as an interface charge in this specification and the like.

A value obtained by dividing SOP by the dielectric constant of a film also represents GSP_Slope. Since organic films have substantially the same dielectric constants regardless of materials of the organic films, whether the interface charge (fixed charge) is positive or negative and the magnitude of the interface charge can be estimated from the difference in GSP_Slope between the first layer and the second layer.

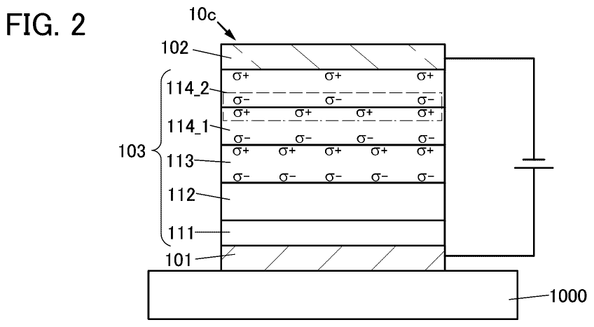

FIG. 2 illustrates an example of a light-emitting device 10c in which the first electron-transport layer 114_1 has a larger GSP_Slope than the second electron-transport layer 114_2. In the light-emitting device having such a structure, charges generated at the interface between the first electron-transport layer 114_1 and the second electron-transport layer 114_2 (the portion surrounded by the dashed-dotted line in the drawing) are positive interface charges. Since positive interface charges exist at the interface between the first electron-transport layer 114_1 and the second electron-transport layer 114_2, electron injection from the second electrode 102 to the second electron-transport layer 114_2 is promoted in the light-emitting device 10c. As a result, the driving voltage of the light-emitting device 10c decreases; thus, in order to obtain a light-emitting device with a low driving voltage, the device is preferably designed such that the GSP_Slope of the first electron-transport layer 114_1 is larger than that of the second electron-transport layer 114_2.

In contrast to FIG. 2, FIG. 1B and FIG. 3B illustrate examples of a light-emitting device 10a and a light-emitting device 10b, respectively, in which the first electron-transport layer 114_1 has a smaller GSP_Slope than the second electron-transport layer 114_2. In the light-emitting devices having such a structure, charges generated at the interface between the first electron-transport layer 114_1 and the second electron-transport layer 114_2 (the portion surrounded by the dashed-dotted line in the drawing) are negative interface charges. Since negative interface charges exist at the interface between the first electron-transport layer 114_1 and the second electron-transport layer 114_2, electron injection from the second electrode 102 to the second electron-transport layer 114_2 is inhibited in the light-emitting devices 10a and 10b. As a result, the driving voltages of the light-emitting devices 10a and 10b are increased. Note that the light-emitting device 10a in FIG. 1B shows an example in which the GSP_Slope of the first electron-transport layer 114_1 has a negative value and the light-emitting device 10b in FIG. 3B shows an example in which the GSP_Slope has a positive value.

In such a light-emitting device including the electron-transport layer having a stacked-layer structure, the GSP_Slope of each electron-transport layer significantly influences the driving voltage. In particular, in the case where the GSP_Slope of the first electron-transport layer 114_1 is negative, it is difficult to find a material for the second electron-transport layer 114_2 whose GSP_Slope is smaller than that of the first electron-transport layer 114_1 because the GSP_Slope of an evaporated film of an organic compound generally has a positive value. Thus, in the case where the GSP_Slope of the first electron-transport layer 114_1 is negative, it has been difficult to fabricate a light-emitting device having a structure similar to that of the light-emitting device 10c in FIG. 2.

Here, the light-emitting device of one embodiment of the present invention has a structure in which the thickness of the second electron-transport layer 114_2 is smaller (specifically, greater than 0 nm and less than 10 nm) than the thickness of the first electron-transport layer 114_1, as in the light-emitting devices illustrated in FIG. 1A and FIG. 3A. In the light-emitting device of one embodiment of the present invention having such a structure, when carriers generated by the interaction between the second electron-transport layer 114_2 and the second electrode 102 (cathode) are diffused, the interface charges at the interface between the first electron-transport layer 114_1 and the second electron-transport layer 114_2 (the portion surrounded by the dashed-dotted line in the drawing) can be eliminated. As a result, negative interface charges that hinder electron injection from the cathode are eliminated, so that an increase in driving voltage can be inhibited.

In particular, in the case where the GSP_Slope of the first electron-transport layer 114_1 is negative as illustrated in FIG. 1B, the interface charges generated at the interface between the first electron-transport layer 114_1 and the second electron-transport layer 114_2 (the portion surrounded by the dashed-dotted line in the drawing) have an extremely large negative value. In such a light-emitting device, inhibition of electron injection is also extremely serious, and an increase in driving voltage is also serious. However, even in such a light-emitting device, the interface charges can be eliminated by reducing the thickness of the second electron-transport layer 114_2 as illustrated in FIG. 1A. That is, when the GSP_Slope of the evaporated film has a negative value, in particular, when the GSP_Slope is extremely small, e.g., −50 mV/nm or less, even an organic compound that has been difficult to use for the electron-transport layer can be used for the first electron-transport layer 114_1. Accordingly, one embodiment of the present invention is particularly effective in the case where the difference in GSP_Slope between the first electron-transport layer 114_1 and the second electron-transport layer 114_2 is larger than or equal to 10 mV/nm, and more effective in the case where the difference in GSP_Slope is larger than or equal to 50 mV/nm.

For example, 6,6′-[(perfluoropropane-2,2-diyl)bis(4,1-phenylene)]bis(2,4-diphenyl-1,3,5-triazine) (abbreviation: 6F-2TRZ) has an excellent electron-transport property and can thus be used to provide a light-emitting device with a low driving voltage as long as electron injection is not inhibited. Since 6F-2TRZ contains fluorine, the refractive index of the evaporated film of 6F-2TRZ is low; thus, when 6F-2TRZ is used for an electron-transport layer of a light-emitting device, the light-emitting device can have improved light extraction efficiency. In addition, the reliability of the light-emitting device is expected to be improved because 6F-2TRZ is stable.

Although 6F-2TRZ has such favorable characteristics, the GSP_Slope of the evaporated film of 6F-2TRZ is −108 mV/nm, which is extremely small. Moreover, 6F-2TRZ has difficulty with direct injection of electrons from the cathode due to its molecular structure and thus is difficult to use alone for the second electron-transport layer 114_2. Thus, 6F-2TRZ has been difficult to use as a material for the electron-transport layer of the light-emitting device.

However, in the light-emitting device of one embodiment of the present invention, even when an organic compound having a small GSP_Slope in an evaporated film state, such as 6F-2TRZ, is used for the first electron-transport layer 114_1, the light-emitting device can have favorable characteristics with a low driving voltage. Specifically, an organic compound having a small GSP_Slope in an evaporated film state, such as 6F-2TRZ, is used for the first electron-transport layer 114_1, a material that facilitates electron injection from an electrode is used for the second electron-transport layer 114_2, and the thickness of the second electron-transport layer 114_2 is set to greater than 0 nm and less than 10 nm. When an organic compound having an extremely small GSP_Slope in an evaporated film state, e.g., 6F-2TRZ having a GSP_Slope of −108 mV/nm in an evaporated film state, is used, it is difficult for the GSP_Slope of the second electron-transport layer 114_2 to be smaller than the GSP_Slope of the first electron-transport layer 114_1. However, with the use of this structure, even when an organic compound having a larger GSP_Slope in an evaporated film state than an organic compound for the first electron-transport layer 114_1 is used for the second electron-transport layer 114_2, the interface charges at the interface between the first electron-transport layer 114_1 and the second electron-transport layer 114_2 (the portion surrounded by a dashed-dotted line in the drawing) can be eliminated by diffusion of carriers generated by the interaction between the second electron-transport layer 114_2 and the second electrode 102 (cathode). As a result, negative interface charges that hinder electron injection from the cathode are eliminated, so that an increase in driving voltage can be inhibited; accordingly, a light-emitting device with a low driving voltage can be obtained with use of an organic compound having a small GSP_Slope in an evaporated film state, such as 6F-2TRZ.

Note that as a result of suppression of an increase in driving voltage derived from GSP_Slope mismatch, the light-emitting device can have a lower driving voltage reflecting a high electron-transport property of the first electron-transport layer 114_1. When an organic compound having a low refractive index in an evaporated film state, such as 6F-2TRZ, is used for the first electron-transport layer 1141, the light-emitting device can have high emission efficiency. Furthermore, when an organic compound having a high electron-transport property, such as 6F-2TRZ, is used, an increase in driving voltage is less likely to be caused even when a layer of the organic compound has a large thickness, so that a layer with a low refractive index can be formed to have a large thickness; thus, a light-emitting device with high light extraction efficiency and high emission efficiency can be provided. As a result, a light-emitting device in which an organic compound such as 6F-2TRZ is used for the first electron-transport layer 114_1 can have high power efficiency. In addition, the light-emitting device can have high stability and high reliability.

Like 6F-2TRZ, an organic compound including an electron-withdrawing group, such as a fluoro group or a cyano group, in film form tends to have an extremely large or small GSP_Slope, and thus is difficult to use as a material for a light-emitting device as described above; such a material can be easily used, however, for the light-emitting device of one embodiment of the present invention.

As described above, in the light-emitting device of one embodiment of the present invention, an organic compound that is difficult to use due to its GSP_Slope in an evaporated film state can be used, so that the range of material choices can be greatly expanded. As a result, a light-emitting device with favorable characteristics can be obtained.

Note that the first electron-transport layer 114_1 is preferably in contact with the light-emitting layer 113. In that case, the GSP_Slope of the light-emitting layer 113 is preferably larger than that of the first electron-transport layer 114_1. In the structure in which the first electron-transport layer 114_1 and the light-emitting layer 113 are in contact with each other and the GSP_Slope of the light-emitting layer 113 is larger than the GSP_Slope of the first electron-transport layer 1141, positive interface charges are generated at the interface between the light-emitting layer 113 and the first electron-transport layer 114_1. This promotes electron injection from the cathode, the second electron-transport layer 114_2, and the like, so that a light-emitting device having a lower driving voltage can be obtained. The GSP_Slope of the light-emitting layer 113 is preferably larger than that of the second electron-transport layer 114_2. Thus, positive interface charges are generated at any interface between the light-emitting layer 113 and the second electron-transport layer 114_2, so that a light-emitting device having a lower driving voltage can be obtained.

The refractive index of the first electron-transport layer 114_1 is preferably lower than that of the light-emitting layer 113, in which case light extraction efficiency can be improved. The refractive index of the first electron-transport layer 114_1 is preferably lower than that of the second electron-transport layer 114_2. Note that the refractive index is preferably an ordinary refractive index at a peak wavelength of an emission spectrum of the light-emitting device or an ordinary refractive index at a wavelength of 633 nm. Alternatively, the ordinary refractive index of the first electron-transport layer 114_1 at a wavelength greater than or equal to 450 nm and less than or equal to 600 nm is preferably lower than or equal to 1.75, further preferably lower than or equal to 1.70, still preferably lower than or equal to 1.68, in which case light extraction efficiency can be increased.

An electron-injection layer may be provided in contact with the second electron-transport layer 114_2 and the second electrode 102 between the second electron-transport layer 114_2 and the second electrode 102. This further facilitates electron injection from the cathode to the EL layer 103, so that a light-emitting device having a lower driving voltage can be obtained. Note that the electron-injection layer is preferably a layer containing one or more selected from an alkali metal, an alkaline earth metal, and ytterbium.

### <Method for Obtaining GSP_Slope>

Here, a method for obtaining the GSP_Slope of an organic compound film formed by a vacuum evaporation method will be described.

A phenomenon in which the surface potential of an evaporated film increases in proportion to the thickness of the film is called the giant surface potential as described above. In general, a slope of a plot of the surface potential of an evaporated film in the thickness direction by Kelvin probe measurement is assumed as the level of the giant surface potential, that is, a GSP_Slope (mV/nm); in the case where two different layers are stacked, a change in the density of charges (mC/m²) accumulated at the interface, which is in association with GSP, can be utilized to estimate the GSP_Slope. The density of the charges accumulated at the interface is obtained by C-V (capacitance-voltage) measurement on an element structure in which charges are accumulated on one of the layers.

In the case where organic thin films having different SOPs (a thin film 1 positioned on the anode side and a thin film 2 positioned on the cathode side, with the anode positioned on the substrate side) are stacked and voltage is applied thereto, when carriers accumulated at the interface (accumulated carriers) are electrons, the following equations are satisfied.

$$[ Equation 1 ]$$

$${σ}_{acc} = ( {V}_{th} - {V}_{inj} ) \frac{{ε}_{1}}{{d}_{1}} = {σ}_{int} \qquad ( 1 )$$

$$[ Equation 2 ]$$

$${σ}_{int} = {P}_{1} - {P}_{2} = \frac{{ε}_{1} {V}_{1}}{{d}_{1}} - \frac{{ε}_{2} {V}_{2}}{{d}_{2}} \qquad ( 2 )$$

In Equation (1), σ_{acc} is the accumulated charge density, σᵢₙₜ is the interface charge density, Vᵢₙⱼ is the electron-injection voltage (V), Vₜₕ is the threshold voltage, d₁ is the thickness of the thin film 1, and ε₁ is the dielectric constant of the thin film 1. Note that Vᵢₙⱼ and Vₜₕ can be estimated from the capacitance-voltage characteristics of a device. The square of an ordinary refractive index nₒ (wavelength: 633 nm) can be used as the dielectric constant. As described above, according to Equation (1), the interface charge density σᵢₙₜ can be calculated using Vᵢₙⱼ and Vₜₕ estimated from the capacitance-voltage characteristics, the dielectric constant ε₁ of the thin film 1 calculated from the refractive index, and the thickness d₁ of the thin film 1.

In Equation (2), P₁ and P₂ are SOP of the thin film 1 and SOP of the thin film 2, respectively, ε₂ is a dielectric constant of the thin film 2, and d₂ is a thickness of the thin film 2. Since the interface charge density σᵢₙₜ can be obtained from Equation (1) above, the use of a substance with a known GSP_Slope for the thin film 1 enables the GSP_Slope of the thin film 2 to be estimated.

Thus, an example is described below in which a measurement device 1 and a measurement device 2 are fabricated with use of 3,6-bis(diphenylamino)-9-[4-(4,6-diphenyl-1,3,5-triazin-2-yl)phenyl]-9H-carbazole (abbreviation: DACT-II), which has a known GSP_Slope, for the thin film 1 and a film formed by co-evaporation of 6F-2TRZ and Liq with a weight ratio of 1:1 as the thin film 2 and the GSP_Slope of the film formed by co-evaporation of 6F-2TRZ and Liq with a weight ratio of 1:1 is obtained. According to Non-Patent Document 2, the GSP_Slope of DACT-II is 13 mV/nm. The film formed by co-evaporation of 6F-2TRZ and Liq with a weight ratio of 1:1 is hereinafter referred to as “6F-2TRZ:Liq (1:1)” in some cases.

As illustrated in FIG. 31, each of the measurement devices 1 and 2 has a structure in which a layer 952, a layer 953, a layer 954, a layer 955, and a layer 956 are stacked in this order over an anode 951 formed over a glass substrate 950, and a cathode 957 is stacked over the layer 956.

Table 1 shows device structures of the measurement devices 1 and 2.

In the measurement device 1 and the measurement device 2, the layer 953 corresponds to the thin film 1 and the layer 954 corresponds to the thin film 2. The layer 952 was formed by co-evaporation of N-(biphenyl-4-yl)-N-[4-(9-phenyl-9H-carbazol-3-yl)phenyl]-9,9-dimethyl-9H-fluoren-2-amine (abbreviation: PCBBiF) and OCHD-003, which is an electron-acceptor material, to a thickness of 10 nm at the weight ratio of PCBBiF to OCHD-003 of 1:0.1. The layer 953 was formed by evaporation of DACT-II to a thickness of 80 nm (the measurement device 1) or 100 nm (the measurement device 2). The layer 954 was formed by co-evaporation of 6F-2TRZ and Liq to a thickness of 100 nm with a weight ratio of 6F-2TRZ to Liq of 1:1. The layer 955 was formed by evaporation of 4,7-di-1-pyrrolidinyl-1,10-phenanthroline (abbreviation: Pyrrd-Phen) to a thickness of 1 nm.

TABLE 1

| | | |
|---|---|---|
| Thickness | Measurement device 1 | Measurement device 2 |

| | | | |
|---|---|---|---|
| Cathode 957 | 200 | nm | Al |
| Layer 956 | 1 | nm | LiF |
| Layer 955 | 1 | nm | Pyrrd-Phen |
| Layer 954 | 100 | nm | 6F-2TRZ:Liq (1:1) |

| | | | |
|---|---|---|---|
| Layer 953 | — | DACT-II (80 nm) | DACT-II (100 nm) |

| | | | |
|---|---|---|---|
| Layer 952 | 10 | nm | PCBBiF:OCHD-003 (1:0.1) |
| Anode 951 | 110 | nm | ITSO |

Note that layers 952 to 956 and the cathode in each measurement device are formed from an anode side by a vacuum evaporation method under the conditions where the substrate temperature is set to room temperature and the deposition rate ranges from 0.2 nm/s to 0.6 nm/s. Each layer is formed without interruption of evaporation. In fabrication of the measurement device, the deposition rate of each layer is preferably within the range of 3 nm/min to 600 nm/min. The thickness of each layer in the measurement device is preferably greater than or equal to 3 nm and less than or equal to 500 nm, further preferably greater than or equal to 50 nm and less than or equal to 300 nm.

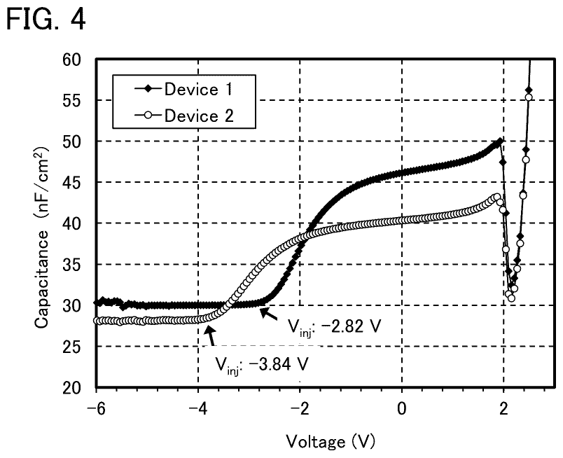

FIG. 4 shows capacitance-voltage characteristics of the measurement devices 1 and 2 and FIG. 5 shows current density-voltage characteristics thereof. Note that in the legends in FIG. 4 and FIG. 5, the measurement device 1 and the measurement device 2 are denoted as Device 1 and Device 2, respectively.

With reference to FIG. 4, injected charges and the order of GSP_Slopes of two stacked layers are determined. When the two devices having different thicknesses of the layer 953 are compared with each other, the charge injection voltage (Vᵢₙⱼ) and the capacitance at around 0 V after the charge injection are found to differ. In the measurement device 2 in which the layer 953 has a larger thickness than in the measurement device 1, charge injection voltage is shifted to be lower, and the capacitance value at around 0 V after the charge injection is small. The results show that charges are injected to the layer 954 at the charge injection voltage (Vᵢₙⱼ), and it can be determined that the charges are accumulated at the interface of the layer 953 after the charge injection. Thus, it can be determined that the charges injected at the injection voltage (Vᵢₙⱼ) are electrons. The layer 954 can be determined to have a smaller GSP_Slope than the layer 953.

Table 2 shows the electron-injection voltage Vᵢₙⱼ, the interface charge density σᵢₙₜ, and the GSP_Slope of the measurement devices 1 and 2, which were obtained from FIG. 5 and Equations (1) and (2), and the refractive indices nₒ of DACT-II and a co-evaporated film of 6F-2TRZ and Liq, the actually measured thickness d₁ of the layer 953, and the threshold voltage Vₜₕ obtained from FIG. 5, which were used in the calculation. Note that the threshold voltage Vₜₕ can also be determined from the capacitance-voltage characteristics.

TABLE 2

| | Measurement device 1 | Measurement device 2 |
|---|---|---|
| Electron injection voltage Vᵢₙⱼ (V) | −2.82 | −3.84 |
| Threshold voltage Vₜₕ (V) | 1.85 | 1.85 |
| Interface charge density σᵢₙₜ (mC/m²) | 1.66 | 1.62 |
| Ordinary refractive index nₒ (@ 633 nm) | 1.77 | 1.77 |
| of DACT-II | | |
| Ordinary refractive index nₒ (@ 633 nm) | 1.64 | 1.64 |
| of 6F-2TRZ: Liq(1:1) | | |
| d₁ (nm) | 78.4 | 97.8 |
| GSP_slope (mV/nm) | −54.2 | −52.7 |

As the actually measured thickness d₁ of DACT-II, a highly accurate value of an actually formed film calculated by a spectroscopic ellipsometry method was used.

By averaging the GSP_Slope of the layer 954 obtained from the measurement results of the measurement device 1 and the GSP_Slope of the layer 954 obtained from the measurement results of the measurement device 2, the GSP_Slope of 6F-2TRZ:Liq (1:1) was estimated to be −53.45 mV/nm.

In this manner, a device in which DACT-II with a known GSP_Slope and a film of an organic compound whose GSP_Slope is to be obtained are stacked is fabricated and the capacitance-voltage characteristics are measured, so that the GSP_Slope of the organic compound can be estimated.

Note that a film to which an organic complex containing an alkali metal such as Liq is added is known to have a favorable electron-injection property from an electrode when used at the vicinity of the cathode interface. Thus, it has been considered that the film to which an organic complex containing an alkali metal is added might be doped with electrons from the organic complex containing an alkali metal and thus have n-type conductivity. Meanwhile, it has been thought that in the film having n-type conductivity, an electric field derived from spontaneous polarization which is caused by orientation of organic molecules is canceled by the electrons added by doping, and thus, GSP and the GSP_Slope do not occur. However, as shown in FIG. 4, the present inventors have confirmed that, even in a structure in which a film to which an organic complex containing an alkali metal is added is stacked over a normal organic film, interface charges are generated at the interface between these films, and charges drawn by the interface charges are accumulated. Thus, GSP and GSP_Slope are generated also in the film to which an alkali metal complex is added.

In the above, the method for calculating the GSP_Slope of the organic compound used for the electron-transport layer in which electrons serve as carriers is described. In the case of using the GSP_Slope of an organic compound used for a hole-transport layer in which holes serve as carriers, the GSP_Slope can be calculated in a similar manner using Equation (3) shown below, as described in Non-Patent Document 1.

$$[ Equation 3 ]$$

$${σ}_{acc} = ( {V}_{th} - {V}_{inj} ) \frac{{ε}_{1}}{{d}_{1}} = - {σ}_{int} \qquad ( 3 )$$

The GSP_Slope of an evaporated film of an organic compound can be measured by the above measurement method.

In the case where the GSP_Slope or the refractive index of a layer in a light-emitting device is desired to be estimated, the estimation is possible by measuring the GSP_Slope or the refractive index of a layer having a structure similar to that of the layer whose GSP_Slope or refractive index is desired to be estimated. Here, layers having structures similar to each other mean layers whose kinds of materials are the same. In the case where each of the layers is formed with a plurality of materials, their mixing ratios are not necessarily the same; however, the orders of mixing ratios are preferably the same, in which case an accurate value can be obtained. Note that the component with 10 wt % or less is not necessarily taken into consideration.

The structures described in this embodiment can be used in combination with any of the structures described in the other embodiments, as appropriate.

### Embodiment 2

In this embodiment, light-emitting devices of one embodiment of the present invention will be described in detail.

FIG. 1A and FIG. 3A are schematic diagrams of light-emitting devices of embodiments of the present invention. The light-emitting device includes the first electrode 101 over the substrate 1000, and the EL layer 103 between the first electrode 101 and the second electrode 102. The EL layer 103 includes the light-emitting layer 113 and the light-emitting layer 113 contains a light-emitting substance that emits light when voltage is applied between the first electrode 101 and the second electrode 102.

The EL layer 103 includes at least the first electron-transport layer 114_1 and the second electron-transport layer 114_2 in addition to the light-emitting layer 113 and has a structure similar to the structure described in Embodiment 1. The light-emitting device of one embodiment of the present invention with the above structure can have favorable characteristics because the range of material choices is expanded.

As illustrated in FIG. 1A and FIG. 3A, the light-emitting device of one embodiment of the present invention preferably includes other functional layers such as the hole-injection layer 111 and the hole-transport layer 112. Note that the EL layer 103 may include functional layers other than the above functional layers, such as a hole-blocking layer, an electron-blocking layer, an exciton-blocking layer, a charge-generation layer, and an electron-injection layer. Alternatively, any of the above layers may be omitted.

The first electrode 101 (anode) and the second electrode 102 (cathode) each have a single-layer structure or a stacked-layer structure. In the case of the stacked-layer structure, a layer in contact with the EL layer 103 serves as an anode or a cathode. In the case where the electrodes each have the stacked-layer structure, there is no limitation on work functions of materials for layers other than the layer in contact with the EL layer 103, and the materials can be selected in accordance with required properties such as a resistance value, processing easiness, reflectivity, light-transmitting property, and stability.

The anode is preferably formed using a metal, an alloy, a conductive compound, or a mixture thereof each having a high work function (specifically, higher than or equal to 4.0 eV), for example. Specific examples include indium oxide-tin oxide (ITO: indium tin oxide), indium oxide-tin oxide containing silicon or silicon oxide (ITSO: indium tin silicon oxide), indium oxide-zinc oxide, and indium oxide containing tungsten oxide and zinc oxide (IWZO). Films of such conductive metal oxides are usually formed by a sputtering method, but may be formed by a sol-gel method or the like. For example, a film of indium oxide-zinc oxide is formed by a sputtering method using a target in which 1 wt % to 20 wt % zinc oxide is added to indium oxide. Furthermore, a film of indium oxide containing tungsten oxide and zinc oxide (IWZO) can be formed by a sputtering method using a target in which 0.5 wt % to 5 wt % tungsten oxide and 0.1 wt % to 1 wt % zinc oxide are added to indium oxide. Alternatively, gold (Au), platinum (Pt), nickel (Ni), tungsten (W), chromium (Cr), molybdenum (Mo), iron (Fe), cobalt (Co), copper (Cu), palladium (Pd), titanium (Ti), aluminum (Al), a nitride of a metal material (e.g., titanium nitride), or the like can be used for the anode. The anode may be a stack of layers formed using any of these materials. For example, a film in which Al, Ti, and ITSO are stacked in this order over Ti is preferable because the film has high efficiency owing to high reflectivity and enables a high resolution of several thousand ppi. Graphene can also be used for the anode. When a composite material that can be included in the hole-injection layer 111 described later is used for a layer (typically, the hole-injection layer) in contact with the anode, an electrode material can be selected regardless of its work function.

The hole-injection layer 111 is provided in contact with the anode and has a function of facilitating injection of holes into the EL layer 103. The hole-injection layer 111 can be formed using phthalocyanine (abbreviation: H₂Pc), a phthalocyanine-based compound or a phthalocyanine-based complex compound such as copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N-(3-methylphenyl)-N-phenylamino]phenyl}-N-phenylamino)biphenyl (abbreviation: DNTPD), or a high molecular compound such as poly(3,4-ethylenedioxythiophene)/poly(styrenesulfonic acid) (abbreviation: PEDOT/PSS), for example.

The hole-injection layer 111 may be formed using a substance having an electron-acceptor property. Examples of the substance having an acceptor property include organic compounds having an electron-withdrawing group (e.g., a halogen group or a cyano group), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylene-1,3,4,5,6,8,9,10-octafluoro-7H-pyren-2-ylidene)malononitrile. A compound in which electron-withdrawing groups are bonded to a condensed aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a significantly high electron-acceptor property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an acceptor property, a transition metal oxide such as molybdenum oxide, vanadium oxide, ruthenium oxide, tungsten oxide, or manganese oxide can be used, other than the above-described organic compounds.

The hole-injection layer 111 is preferably formed using a composite material containing any of the aforementioned materials having an acceptor property and an organic compound having a hole-transport property.

As the organic compound having a hole-transport property that is used in the composite material, any of a variety of organic compounds such as aromatic amine compounds, heteroaromatic compounds, aromatic hydrocarbons, and high molecular compounds (e.g., oligomers, dendrimers, and polymers) can be used. Note that the organic compound having a hole-transport property that is used in the composite material preferably has a hole mobility higher than or equal to 1×10⁻⁶ cm²/Vs. The organic compound having a hole-transport property that is used in the composite material preferably has a condensed aromatic hydrocarbon ring or a π-electron rich heteroaromatic ring. As the condensed aromatic hydrocarbon ring, an anthracene ring, a naphthalene ring, or the like is preferable. As the π-electron rich heteroaromatic ring, a condensed aromatic ring having at least one of a pyrrole skeleton, a furan skeleton, and a thiophene skeleton in the ring is preferable; specifically, a carbazole ring, a dibenzothiophene ring, or a ring in which an aromatic ring or a heteroaromatic ring is further condensed to a carbazole ring or a dibenzothiophene ring is preferable.

Such an organic compound having a hole-transport property further preferably has at least one of a carbazole skeleton, a dibenzofuran skeleton, a dibenzothiophene skeleton, and an anthracene skeleton. In particular, an aromatic amine having a substituent that has a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the organic compound having a hole-transport property 5 preferably has an N,N-bis(4-biphenyl)amino group to enable fabricating a light-emitting device having a long lifetime.

Specific examples of the organic compound having a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-([2,1′-binaphthyl]-6-yl)triphenylamine (abbreviation: BBAαNβNB), 4,4′-diphenyl-4″-([2,1′-binaphthyl]-7-yl)triphenylamine (abbreviation: BBAαNβNB-03), 4,4′-diphenyl-4″-(7-phenyl)naphthyl-2-yltriphenylamine (abbreviation: BBA(βNB-03), 4,4′-diphenyl-4″-([2,2′-binaphthyl]-6-yl)triphenylamine (abbreviation: BBA(βN2)B), 4,4′-diphenyl-4″-([2,2′-binaphthyl]-7-yl)triphenylamine (abbreviation: BBA(βN2)B-03), 4,4′-diphenyl-4″-([1,2′-binaphthyl]-4-yl)triphenylamine (abbreviation: BBAβNαNB), 4,4′-diphenyl-4″-([1,2′-binaphthyl]-5-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), NN-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

Examples of the aromatic amine compounds that can be used as the organic compound with a hole-transport property include N,N-di(p-tolyl)-N,-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

The formation of the hole-injection layer 111 can improve the hole-injection property, which allows the light-emitting device to be driven at a low voltage.

Among substances having an acceptor property, an organic compound having an acceptor property is easy to use because the organic compound is easily deposited by evaporation as a film.

The hole-transport layer 112 is formed using an organic compound having a hole-transport property. The organic compound having a hole-transport property preferably has a hole mobility of 1×10⁻⁶ cm²/Vs or higher.

Examples of the aforementioned organic compound having a hole-transport property include the following compounds: compounds having an aromatic amine skeleton, such as 4,4′-bis[N-(1-naphthyl)-N-phenylamino]biphenyl (abbreviation: NPB), N,N′-diphenyl-N,N-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), andN-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-3,3′-bi-9H-carbazole (abbreviation: βNCCP), 9-(3-biphenyl)-9′-(2-naphthyl)-3,3′-bi-9H-carbazole (abbreviation: βNCCmBP), 9-(4-biphenyl)-9′-(2-naphthyl)-3,3′-bi-9H-carbazole (abbreviation: βNCCBP), 9,9′-di-2-naphthyl-3,3′-9H,9′H-bicarbazole (abbreviation: BisβNCz), 9-(2-naphthyl)-9′-[1,1′:4′,1″-terphenyl]-3-yl-3,3′-9H,9′H-bicarbazole, 9-(2-naphthyl)-9′-[1,1′: 3′,1″-terphenyl]-3-yl-3,3′-9H,9′H-bicarbazole, 9-(2-naphthyl)-9′-[1,1′: 3′,1″-terphenyl]-5′-yl-3,3′-9H,9′H-bicarbazole, 9-(2-naphthyl)-9′-[1,1′:4′,1″-terphenyl]-4-yl-3,3′-9H,9′H-bicarbazole, 9-(2-naphthyl)-9′-[1,1′: 3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, and 9-(4-biphenyl)-9′-(triphenylen-2-yl)-3,3′-9H,9′H-bicarbazole, 9-(triphenylen-2-yl)-9′-[1,1′: 3′,1″-terphenyl]-4-yl-3,3′-9H,9′H-bicarbazole; compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above compounds, the compound having an aromatic amine skeleton and the compound having a carbazole skeleton are preferable because these compounds are highly reliable and have a high hole-transport property to contribute to a reduction in driving voltage. Note that any of the substances given as examples of the organic compound having a hole-transport property that is used for the composite material for the hole-injection layer 111 can also be suitably used as the material contained in the hole-transport layer 112.

The light-emitting substance may be a fluorescent substance, a phosphorescent substance, a substance exhibiting thermally activated delayed fluorescence (TADF), or any other light-emitting substance.

Examples of the material that can be used as a fluorescent substance in the light-emitting layer are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N-bis[4-(9-phenyl-9H-fluoren-9-yl)phenyl]pyrene-1,6-diamine (abbreviation: 1,6FLPAPrn), N,N-bis(3-methylphenyl)-N,N-bis[3-(9-phenyl-9H-fluoren-9-yl)phenyl]pyrene-1,6-diamine (abbreviation: 1,6mMemFLPAPrn), N,N-bis[4-(9H-carbazol-9-yl)phenyl]-N,N-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis(N,N′,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N′-diphenyl-N,N′-(1,6-pyrene-diyl)bis[(6-phenylbenzo[b]naphtho[1,2-d]furan)-8-amine](abbreviation: 1,6BnfAPrn-03), N,N-diphenyl-N,N-bis(9-phenyl-9H-carbazol-2-yl)naphtho[2,3-b;6,7-b′]bisbenzofuran-3,10-diamine (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Condensed aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

A condensed heteroaromatic compound containing nitrogen and boron, especially a compound having a diaza-boranaphtho-anthracene skeleton, exhibits a narrow emission spectrum, emits blue light with high color purity, and can thus be used suitably. Examples of the compound include 5,9-diphenyl-5H,9H-[1,4]benzazaborino[2,3,4-kl]phenazaborine (abbreviation: DABNA-1), 9-(diphenyl-3-yl)-N,N,5,11-tetraphenyl-5,9-dihydro-5,9-diaza-13b-boranaphtho[3,2,1-de]anthracen-3-amine (abbreviation: DABNA-2), 2,12-di(tert-butyl)-5,9-di(4-tert-butylphenyl)-N,N-diphenyl-5H,9H-[1,4]benzazaborino[2,3,4-kl]phenazaborin-7-amine (abbreviation: DPhA-tBu4DABNA), 2,12-di(tert-butyl)-N,N,5,9-tetra(4-tert-butylphenyl)-5H,9H-[1,4]benzazaborino[2,3,4-kl]phenazaborin-7-amine (abbreviation: tBuDPhA-tBu4DABNA), 2,12-di(tert-butyl)-5,9-di(4-tert-butylphenyl)-7-methyl-5H,9H-[1,4]benzazaborino[2,3,4-kl]phenazaborine (abbreviation: Me-tBu4DABNA), N⁷,N⁷,N¹³,N¹³,5,9,11,15-octaphenyl-5H,9H,11H,15H-[1,4]benzazaborino[2,3,4-kl][1,4]benzazaborino[4′,3′,2′:4,5][1,4]benzazaborino[3,2-b]phenazaborine-7,13-diamine (abbreviation: v-DABNA), and 2-(4-tert-butylphenyl)benz[5,6]indolo[3,2,1-jk]benzo[b]carbazole (abbreviation: tBuPBibc).

Besides the above compounds, a compound having an indole skeleton, such as 9,10,11-tris[3,6-bis(1,1-dimethylethyl)-9H-carbazolyl-9-yl]-2,5,15,18-tetrakis(1,1-dimethylethyl)indolo[3,2,1-de]indolo[3′,2′,1′: 8,1][1,4]benzazaborino[2,3,4-kl]phenazaborine (abbreviation: BBCz-G), 9,11-bis[3,6-bis(1,1-dimethylethyl)-9H-carbazolyl-9-yl]-2,5,15,18-tetrakis(1,1-dimethylethyl)indolo[3,2,1-de]indolo[3′,2′,1′: 8,1][1,4]benzazaborino[2,3,4-kl]phenazaborine (abbreviation: BBCz-Y), or the like can be suitably used.

In the case where a phosphorescent substance is used as the light-emitting device in the light-emitting layer, a metal complex, in particular, an iridium complex or a platinum complex is preferable as the phosphorescent substance; examples of the materials are as follows.

The examples include organometallic iridium complexes having a 4H-triazole skeleton, such as tris{2-[5-(2-methylphenyl)-4-(2,6-dimethylphenyl)-4H-1,2,4-triazol-3-yl-κN²]phenyl-iC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[5-(2-trimethylphenyl)-4-(2,4,6-trimethylphenyl)-4H-1,2,4-triazol-3-yl-κN²]phenyl-KC iridium(III) (abbreviation: Ir(mpptz-tmp)₃), tris{2-[4-(4-cyano-2,6-diisobutylphenyl)-5-(2-methylphenyl)-4H-1,2,4-triazol-3-yl-κN²]phenyl-κC}iridium(III) (abbreviation: Ir(mpptz-diBuCNp)₃), and tris{2-[4-(2-adamantyl)-3-methyl-4H-1,2,4-triazol-5-yl-κN]phenyl-κC}iridium(III) (abbreviation: Ir(Mptz-Δdm2)₃); organometallic iridium complexes having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptz1-Me)₃]); organometallic iridium complexes having an imidazole skeleton, such as fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-j]phenanthridinato]iridium(III) (abbreviation: [Ir(dmpimpt-Me)₃]), and tris(2-{1-[2,6-bis(1-methylethyl)phenyl]-1H-imidazol-2-yl-κN³}-4-cyanophenyl-κC)iridium(III) (abbreviation: CNImIr); organometallic complexes having a benzimidazolidene skeleton, such as tris[(6-tert-butyl-3-phenyl-2H-imidazo[4,5-b]pyrazin-1-yl-κC²)phenyl-κC]iridium(III) (abbreviation: [Ir(cb)₃]); organometallic iridium complexes in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIracac); and platinum complexes such as (2-{3-[3-(3,5-di-tert-butylphenyl)benzimidazol-1-yl-2-ylidene-κC²]phenoxy-κC²}-9-(4-tert-butyl-2-pyridinyl-κN)carbazole-2,1-diyl-κC¹)platinum(II) (abbreviation: PtON-TBBI) and (2-{3-[3-(3,5-di-tert-butylphenyl)benzimidazol-1-yl-2-ylidene-κC²]phenoxy-κC²}-9-[3,5-di(methyl-d₃)-4-phenyl-2-pyridinyl-κN]carbazole-2,1-diyl-κC)platinum(II) (abbreviation: Pt(mmtBubOcz35dm4ppy-d₆)). These compounds emit phosphorescent light with a blue hue and have an emission peak in the wavelength range from 450 nm to 520 nm. Alternatively, a compound obtained by substituting deuterium for part of hydrogen in any of these compounds can also be used.

Other examples include organometallic iridium complexes having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), and (acetylacetonato)bis(4,6-diphenylpyrimidinato)iridium(III) (abbreviation: [Ir(dppm)₂(acac)]); organometallic iridium complexes having a pyrazine skeleton, such as (acetylacetonato)bis(3,5-dimethyl-2-phenylpyrazinato)iridium(III) (abbreviation: [Ir(mppr-Me)₂(acac)]) (acetylacetonato)bis(5-isopropyl-3-methyl-2-phenylpyrazinato)iridium(III) (abbreviation: [Ir(mppr-iPr)₂(acac)]); and bis{2-[6-(4-cyano-2,6-dimethylphenyl)-4-pyrimidinyl-κN³]phenyl-iC}(2,4-pentanedionato-κ²O,O′)iridium(III) (abbreviation: Ir(ppm-dmCP)₂(acac)); organometallic iridium complexes having a pyridine skeleton, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]), [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: [Ir(5mppy-d₃)₂(mbfpypy-d₃)]), {2-(methyl-d₃)-8-[4-(1-methylethyl-1-d)-2-pyridinyl-κN]benzofuro[2,3-b]pyridin-7-yl-κC}bis{5-(methyl-d₃)-2-[5-(methyl-d₃)-2-pyridinyl-κN]phenyl-κC}iridium(III) (abbreviation: Ir(5mtpy-d₆)₂(mbfpypy-iPr-d₄)), [2-(methyl-d₃)-8-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy-d₃)]), [2-(4-methyl-5-phenyl-2-pyridinyl-κN)phenyl-κC]bis[2-(2-pyridinyl-κN)phenyl-κC]iridium(III) (abbreviation: [Ir(ppy)₂(mdppy)]), [2-(4-d₃-methyl-5-phenyl-2-pyridinyl-κN²)phenyl-κC]bis[2-(5-d₃-methyl-2-pyridinyl-κN²)phenyl-κC]iridium(III) (abbreviation: [Ir(5mppy-d₃)₂(mdppy-d₃)]), [2-methyl-8-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy)]), and tris{2-[5-(methyl-d₃)-4-phenyl-2-pyridinyl-κN]phenyl-xC}iridium(III) (abbreviation: Ir(5m4dppy-d₃)₃); and organometallic platinum complexes such as (2-{1-(5-tert-butylbiphenyl-2-yl)-4-[3-tert-butyl-5-(4-phenyl-2-pyridinyl-κN)phenyl-κC⁶]-2-benzimidazolyl-κN3}-4,6-di-tert-butylphenolato-κO)platinum(II) (abbreviation: Pt(tBudppymmtBubiz-tBubp)) and [2-(4-(3,5-di-tert-butylphenyl)-6-{3-[4-(5′-tert-butyl[1,1′: 3′,1″-terphenyl]-2′-yl)-2-pyridinyl-κN]phenyl-κC²}-2-pyridinyl-κN)phenolato-κO]platinum(II) (abbreviation: Pt(4tButpppypyp-mmtBup)). These compounds mainly emit green phosphorescent light and have an emission peak in the wavelength range from 500 nm to 600 nm. Note that organometallic iridium complexes having a pyrimidine skeleton have distinctively high reliability or emission efficiency and thus are particularly preferable. Alternatively, a compound obtained by substituting deuterium for part of hydrogen in any of these compounds can also be used.

Other examples include organometallic iridium complexes having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and bis[4,6-di(naphthalen-1-yl)pyrimidinato](dipivaloylmethanato)iridium(III) (abbreviation: [Ir(d1npm)₂(dpm)]); organometallic iridium complexes having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), (acetylacetonato)bis[2,3-bis(4-fluorophenyl)quinoxalinato]iridium(III) (abbreviation: [Ir(Fdpq)₂(acac)]), bis{4,6-dimethyl-2-[5-(5-cyano-2-methylphenyl)-3-(3,5-dimethylphenyl)-2-pyrazinyl-κN]phenyl-κC}(2,2,6,6-tetramethyl-3,5-heptanedionato-κ²O,O′)iridium(III) (abbreviation: Ir(dmdppr-m5CP)₂(dpm)), and bis{2-[5-(2,6-dimethylphenyl)-3-(3,5-dimethylphenyl)-2-pyrazinyl-κN]-4,6-dimethylphenyl-κC}(2,2′,6,6′-tetramethyl-3,5-heptanedionato-κ²O,O′)iridium(III) (abbreviation: Ir(dmdppr-dmp)₂(dpm)); organometallic iridium complexes having a pyridine skeleton, such as tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), (3,7-diethyl-4,6-nonanedionato-κO⁴,κO⁶)bis[2,4-dimethyl-6-[7-(1-methylethyl)-1-isoquinolinyl-K]phenyl-κC]iridium(III), and (3,7-diethyl-4,6-nonanedionato-κO⁴,κO⁶)bis[2,4-dimethyl-6-[5-(1-methylethyl)-2-quinolinyl-K]phenyl-iC]iridium(III); platinum complexes such as 2,3,7,8,12,13,17,18-octaethyl-21H,23H-porphyrinplatinum(II) (abbreviation: PtOEP); and rare earth metal complexes such as tris(1,3-diphenyl-1,3-propanedionato)(monophenanthroline)europium(III) (abbreviation: [Eu(DBM)₃(Phen)]) and tris[l-(2-thenoyl)-3,3,3-trifluoroacetonato](monophenanthroline)europium(III) (abbreviation: [Eu(TTA)₃(Phen)]). These compounds emit phosphorescent light with a red hue and have an emission peak in the wavelength range from 600 nm to 700 nm. Furthermore, the organometallic iridium complexes having a pyrazine skeleton can provide red light emission with favorable chromaticity. A compound obtained by substituting deuterium for part of hydrogen in any of these compounds can also be used.

Besides the above phosphorescent compounds, known phosphorescent compounds may be selected and used.

Examples of the TADF material include a fullerene, a derivative thereof, an acridine, a derivative thereof, and an eosin derivative. Furthermore, a metal-containing porphyrin, such as a porphyrin containing magnesium (Mg), zinc (Zn), cadmium (Cd), tin (Sn), platinum (Pt), indium (In), or palladium (Pd), can be given. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

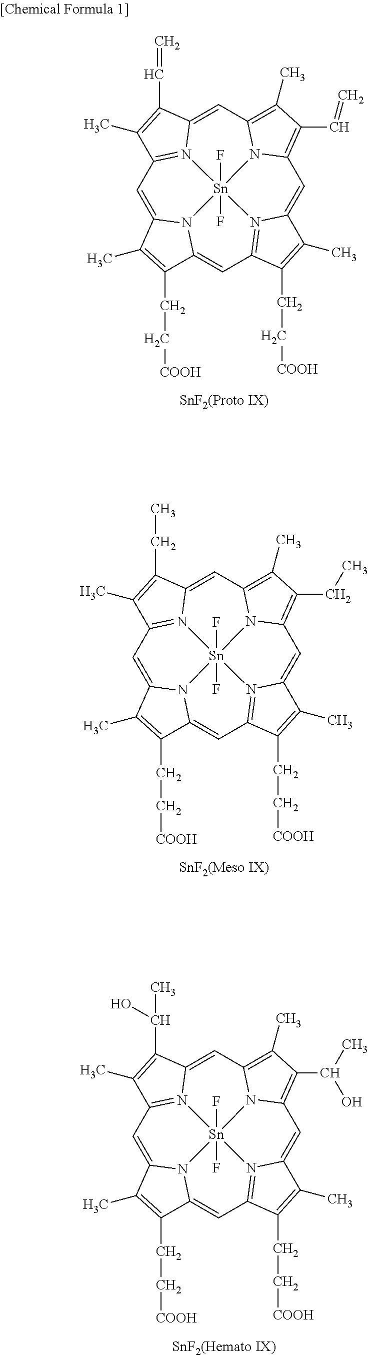

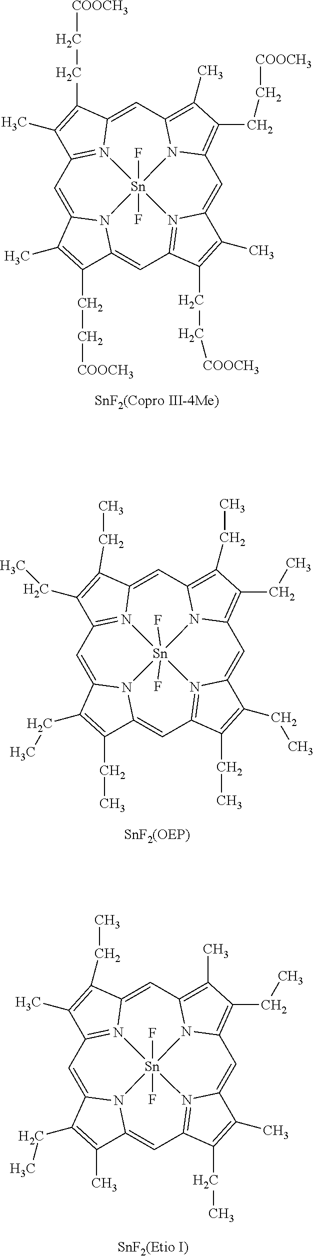

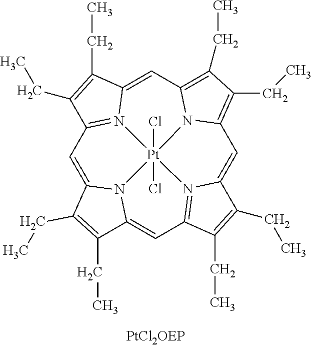

Alternatively, it is possible to use a heterocyclic compound including one or both of a π-electron rich heteroaromatic ring and a π-electron deficient heteroaromatic ring that is represented by any of the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 9-[4-(4,6-diphenyl-1,3,5-triazin-2-yl)phenyl]-9′-phenyl-3,3′-bi-9H-carbazole (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA). Such a heterocyclic compound is preferable because of having high electron-transport and hole-transport properties owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferable because the electron-donating property of the π-electron rich heteroaromatic ring and the electron-acceptor property of the π-electron deficient heteroaromatic ring are both improved, the energy difference between the S₁ level and the T₁ level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton including boron such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

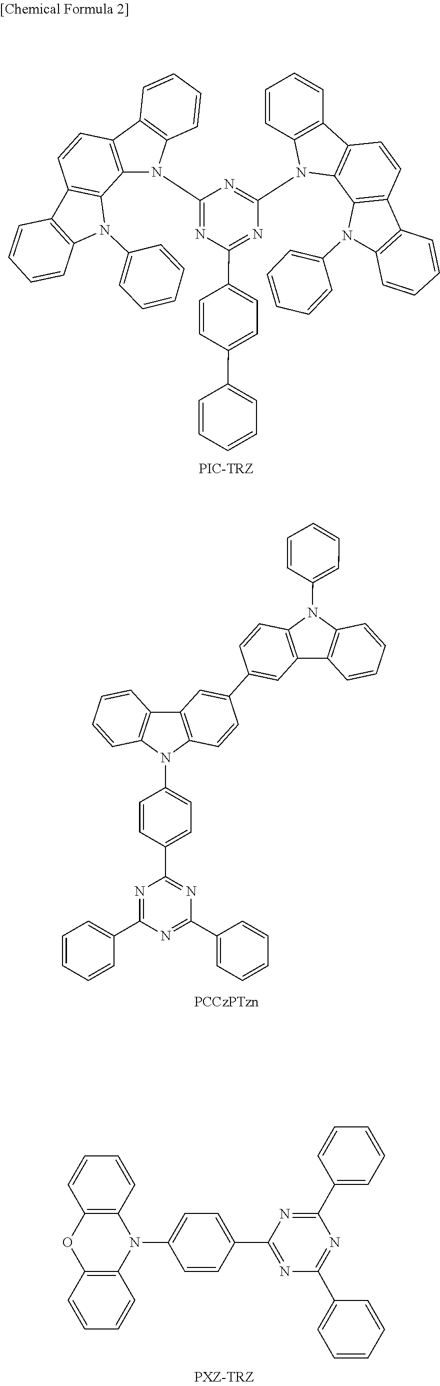 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-c3ccc(N4c5ccccc5Oc5ccccc54)cc3)n2)cc1]

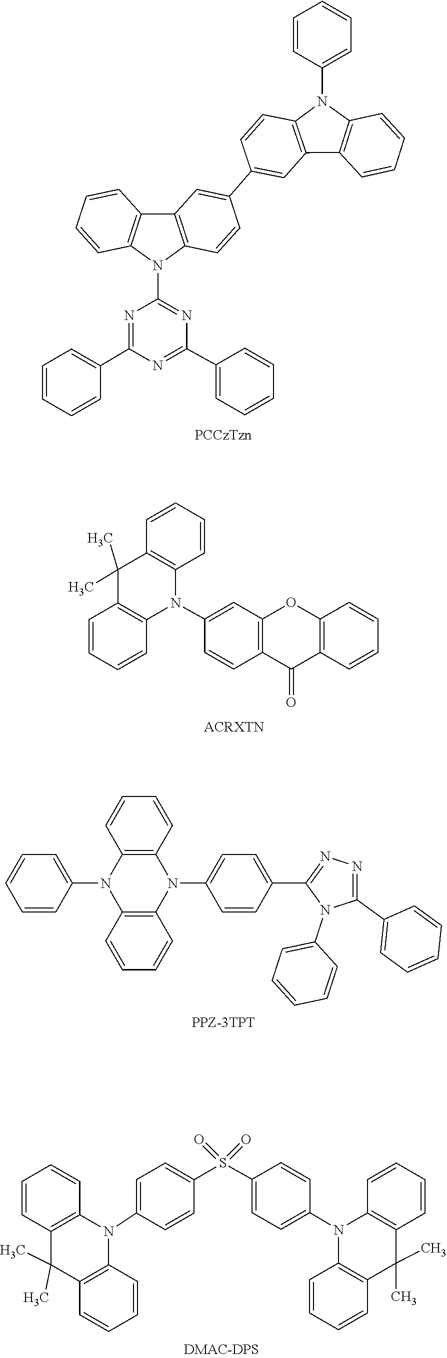

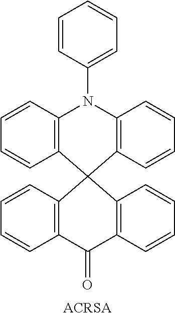 [SMILES: O=C1c2ccccc2C2(c3ccccc31)c1ccccc1N(c1ccccc1)c1ccccc12]

Note that a TADF material is a material having a small energy difference between the S₁ level and the T₁ level and a function of converting triplet excitation energy into singlet excitation energy by reverse intersystem crossing. Thus, a TADF material can upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed of two kinds of substances has an extremely small energy difference between the S₁ level and the T₁ level and functions as a TADF material capable of converting triplet excitation energy into singlet excitation energy.

A phosphorescence spectrum observed at a low temperature (e.g., 77 K to 10 K) is used for an index of the T₁ level. When the level of energy of light with a wavelength of a line obtained by extrapolating a tangent to the fluorescence spectrum at a tail on the shorter wavelength side is the S₁ level and the level of energy of light with a wavelength of a line obtained by extrapolating a tangent to the phosphorescence spectrum at a tail on the shorter wavelength side is the T₁ level, the energy difference between the S₁ level and the T₁ level of the TADF material is preferably less than or equal to 0.3 eV, further preferably less than or equal to 0.2 eV.

When the TADF material is used as a light-emitting substance, the S₁ level of the host material is preferably higher than that of the TADF material, and the T₁ level of the host material is preferably higher than that of the TADF material.

As the host material in the light-emitting layer, any of various carrier-transport materials such as materials having an electron-transport property and/or materials having a hole-transport property, and the TADF materials can be used.

The material having a hole-transport property is preferably an organic compound having an amine skeleton or a π-electron rich heteroaromatic ring skeleton, for example. As the π-electron rich heteroaromatic ring, a condensed aromatic ring having at least one of an acridine skeleton, a phenoxazine skeleton, a phenothiazine skeleton, a furan skeleton, a thiophene skeleton, and a pyrrole skeleton in the ring is preferable; specifically, a carbazole ring, a dibenzothiophene ring, or a ring in which an aromatic ring or a heteroaromatic ring is further condensed to a carbazole ring or a dibenzothiophene ring is preferable.

Such an organic compound having a hole-transport property further preferably has at least one of a carbazole skeleton, a dibenzofuran skeleton, a dibenzothiophene skeleton, and an anthracene skeleton. In particular, an aromatic amine having a substituent that has a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the organic compound having a hole-transport property preferably has an N,N-bis(4-biphenyl)amino group to enable fabricating a light-emitting device having a long lifetime.

Examples of such an organic compound include the following compounds: compounds having an aromatic amine skeleton, such as 4,4′-bis[N-(1-naphthyl)-N-phenylamino]biphenyl (abbreviation: NPB), N,N-diphenyl-N,-bis(3-methylphenyl)-4,4′-diaminobiphenyl (abbreviation: TPD), N,N-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 3,9-bis(9-phenyl-9H-carbazol-3-yl)-9H-carbazole (abbreviation: PCCzPC), 9-(biphenyl-4-yl)-9′-phenyl-3,3′-bi-9H-carbazole (abbreviation: PCCzBP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-3,3′-bi-9H-carbazole (abbreviation: βNCCP), 9-(3-biphenyl)-9′-(2-naphthyl)-3,3′-bi-9H-carbazole (abbreviation: βNCCmBP), 9-(4-biphenyl)-9′-(2-naphthyl)-3,3′-bi-9H-carbazole (abbreviation: βNCCBP), 9,9′-di-2-naphthyl-3,3′-9H,9′H-bicarbazole (abbreviation: BisβNCz), 9-(2-naphthyl)-9′-[1,1′:4′,1″-terphenyl]-3-yl-3,3′-9H,9′H-bicarbazole, 9-(2-naphthyl)-9′-[1,1′:3′,1″-terphenyl]-3-yl-3,3′-9H,9′H-bicarbazole, 9-(2-naphthyl)-9′-[1,1′: 3′,1″-terphenyl]-5′-yl-3,3′-9H,9′H-bicarbazole, 9-(2-naphthyl)-9′-[1,1′:4′,1″-terphenyl]-4-yl-3,3′-9H,9′H-bicarbazole, 9-(2-naphthyl)-9′-[1,1′: 3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′:3′,1″-terphenyl]-4-yl-3,3′-9H,9′H-bicarbazole, N,N-bis(9,9-dimethyl-9H-fluoren-2-yl)-9,9′-spirobi-9H-fluoren-1-amine, 9-[3-(triphenylsilyl)phenyl]-3,9′-bi-9H-carbazole (abbreviation: PSiCzCz), and 9′-[3-(triphenylsilyl)phenyl]-9′H-9,3′: 6′,9″-tercarbazole (abbreviation: PSiCzGI); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above compounds, the compound having an aromatic amine skeleton and the compound having a carbazole skeleton are preferable because these compounds are highly reliable and have a high hole-transport property to contribute to a reduction in driving voltage. In addition, the organic compounds given as examples of the material having a hole-transport property that can be used for the hole-transport layer can also be used.

The material having an electron-transport property preferably has an electron mobility higher than or equal to 1×10⁻⁷ cm²/Vs, further preferably higher than or equal to 1×10⁻⁶ cm²/Vs when the square root of the electric field strength [V/cm] is 600. Note that any other substance can also be used as long as the substance has an electron-transport property higher than a hole-transport property.

As the material having an electron-transport property, for example, a metal complex such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); or an organic compound including a π-electron deficient heteroaromatic ring is preferably used. Examples of the organic compound having a π-electron deficient heteroaromatic ring skeleton include an organic compound that has a heteroaromatic ring having an azole skeleton, an organic compound that has a heteroaromatic ring having a pyridine skeleton, an organic compound that has a heteroaromatic ring having a diazine skeleton, and an organic compound that has a heteroaromatic ring having a triazine skeleton.

Among the above materials, the organic compound that has a heteroaromatic ring having a diazine skeleton (a pyrimidine skeleton, a pyrazine skeleton, or a pyridazine skeleton), the organic compound that has a heteroaromatic ring having a pyridine skeleton, and the organic compound that has a heteroaromatic ring having a triazine skeleton have high reliability and thus are preferable. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. A benzofuropyrimidine skeleton, a benzothienopyrimidine skeleton, a benzofuropyrazine skeleton, and a benzothienopyrazine skeleton are preferable because of their high acceptor properties and high reliability.

Examples of the organic compound having a π-electron deficient heteroaromatic ring skeleton include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOs); an organic compound that has a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), 4,7-diphenyl-1,10-phenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthryl)-1-naphthyl]-1,10-phenanthroline (abbreviation: PnNPhen), or 2-[4-(2-triphenylenyl)phenyl]-1,10-phenanthroline (abbreviation: pTpPPhen); an organic compound having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 2-{3-[3-(N-phenyl-9H-carbazol-3-yl)-9H-carbazol-9-yl]phenyl}dibenzo[f,h]quinoxaline (abbreviation: 2mPCCzPDBq), 9-[3′-(dibenzothiophen-4-yl)biphenyl-3-yl]naphtho[1′,2′: 4,5]furo[2,3-b]pyrazine (abbreviation: 9mDBtBPNfpr), 9-[3′-(dibenzothiophen-4-yl)biphenyl-4-yl]naphtho[1′,2′: 4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 11-[3′-(dibenzothiophen-4-yl)biphenyl-3-yl]phenanthro[9′,10′: 4,5]furo[2,3-b]pyrazine (abbreviation: 11mDBtBPPnfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)biphenyl-3-yl]naphtho[1′,2′: 4,5]furo[3,2-d]pyrimidine (abbreviation: 8mDBtBPNfpm), 8-([2,2′-binaphthalen]-6-yl)-4-[3-(dibenzothiophen-4-yl)phenyl]-[1]benzofuro[3,2-d]pyrimidine (abbreviation: 8(PN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP-PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), 7-[4-(9-phenyl-9H-carbazol-2-yl)quinazolin-2-yl]-7H-dibenzo[c,g]carbazole (abbreviation: PC-cgDBCzQz), 8-(p-terphenyl-3-yl)-4-[3-(dibenzothiophen-4-yl)phenyl]-[1]benzofuro[3,2-d]pyrimidine (abbreviation: 8mpTP-4mDBtPBfpm), or 2,2′-[(2,2′-bipyridine)-6,6′-diyl]bis(4-phenylbenzo[h]quinazoline) (abbreviation: 6,6′(P-Bqn)2BPy); and an organic compound that has a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 9-[4-(4,6-diphenyl-1,3,5-triazin-2-yl)phenyl]-9′-phenyl-3,3′-bi-9H-carbazole (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthryl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn), 2-[4-(2-naphthyl)phenyl]-4-phenyl-6-spiro[9H-fluorene-9,9′-[9H]xanthen]-4-yl-1,3,5-triazine (abbreviation: βNP-SFx(4)Tzn), 9,9′-{6-[3-(triphenylsilyl)phenyl]-1,3,5-triazine-2,4-diyl}bis(9H-carbazole) (abbreviation: SiTrzCz2), 2-phenyl-4,6-bis[3-(triphenylsilyl)phenyl]-1,3,5-triazine (abbreviation: mSiTrz), 11-[4-(biphenyl-4-yl)-6-phenyl-1,3,5-triazin-2-yl]-11,12-dihydro-12-(biphenyl-3-yl)indolo[2,3-a]carbazole (abbreviation: BP-mBPIcz(II)Tzn), 3-{3-[9-(4,6-diphenyl-1,3,5-triazin-2-yl)-2-dibenzofuranyl]phenyl}-9-phenyl-9H-carbazole (abbreviation: mPCPDBfTzn), 9,9′-[6-(biphenyl-4-yl)-2-phenyl-1,3,5-triazine-4,3″-diyl]bis(9H-carbazole) (abbreviation: Cz-pmCzBPTzn), 3-phenyl-9-[4-phenyl-6-(9-phenyl-3-dibenzofuranyl)-1,3,5-triazin-2-yl]-9H-carbazole (abbreviation: PDBf-PCzTzn), 9-[4-(4,6-diphenyl-1,3,5-triazin-2-yl)-2-dibenzothienyl]-2-phenyl-9H-carbazole (abbreviation: PCzDBtTzn), or 2,4,6-tris(2-pyridyl)-1,3,5-triazine (abbreviation: 2Py3Tzn). The organic compound that has a heteroaromatic ring having a diazine skeleton, the organic compound that has a heteroaromatic ring having a pyridine skeleton, and the organic compound that has a heteroaromatic ring having a triazine skeleton have high reliability and thus are preferable. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage.

As the TADF material that can be used as the host material, the above materials mentioned as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S₁ level of the TADF material is preferably higher than that of the fluorescent substance in order that high emission efficiency can be achieved. Furthermore, the T₁ level of the TADF material is preferably higher than the S₁ level of the fluorescent substance. Therefore, the T₁ level of the TADF material is preferably higher than that of the fluorescent substance.

It is also preferable to use a TADF material that emits light whose wavelength overlaps with the wavelength of the lowest-energy-side absorption band of the fluorescent substance. This enables smooth transfer of excitation energy from the TADF material to the fluorescent substance and accordingly enables efficient light emission, which is preferable.

In order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton that brings about light emission) of the fluorescent substance. As the protective group, a substituent having no 7C bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituents having no π bond are poor in carrier transport performance, whereby the TADF material and the luminophore of the fluorescent substance can be made away from each other with little influence on carrier transportation or carrier recombination. Here, the luminophore refers to an atomic group (skeleton) that brings about light emission in a fluorescent substance. The luminophore is preferably a skeleton having a π bond, further preferably has an aromatic ring, and still further preferably has a condensed aromatic ring or a condensed heteroaromatic ring. Examples of the luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance, a material having an acene skeleton, especially an anthracene skeleton, is suitably used as the host material. The use of a substance having an anthracene skeleton as the host material for the fluorescent substance makes it possible to obtain a light-emitting layer with high emission efficiency and high durability. Among the substances having an anthracene skeleton that are used as the host materials, a substance having a diphenylanthracene skeleton, in particular, a substance having a 9,10-diphenylanthracene skeleton, is chemically stable and thus is preferably used as the host material. The host material preferably has a carbazole skeleton to have higher hole-injection and hole-transport properties; further preferably, the host material has a benzocarbazole skeleton in which a benzene ring is further condensed to a carbazole skeleton, because the highest occupied molecular orbital (HOMO) level of the host material having a benzocarbazole skeleton is higher than that of the host material having a carbazole skeleton by approximately 0.1 eV and the host material having a benzocarbazole skeleton is thus easier for holes to enter than the host material having a carbazole skeleton. In particular, the host material preferably has a dibenzocarbazole skeleton, because the HOMO level of the host material having a dibenzocarbazole skeleton is higher than that of the host material having a carbazole skeleton by approximately 0.1 eV, the host material having a dibenzocarbazole skeleton is thus easier for holes to enter than the host material having a carbazole skeleton, and the host material having a dibenzocarbazole skeleton has a higher hole-transport property and higher heat resistance than the host material having a carbazole skeleton. Accordingly, a substance that has both a 9,10-diphenylanthracene skeleton and a carbazole skeleton (or a benzocarbazole or dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Furthermore, a dibenzofuran skeleton is preferably included, in which case the reliability can be ensured without a reduction in the T 1 level.

Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthryl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4-(9-phenyl-9H-fluoren-9-yl)biphenyl-4′-yl]anthracene (abbreviation: FLPPA), 9-(1-naphthyl)-10-[4-(2-naphthyl)phenyl]anthracene (abbreviation: αN-QNPAnth), 9-(1-naphthyl)-10-(2-naphthyl)anthracene (abbreviation: α,βADN), 2-(10-phenylanthracen-9-yl)dibenzofuran, 2-(10-phenyl-9-anthryl)benzo[b]naphtho[2,3-d]furan (abbreviation: Bnf(II)PhA), 9-(2-naphthyl)-10-[3-(2-naphthyl)phenyl]anthracene (abbreviation: βN-mQNPAnth), 1-{4-[10-(biphenyl-4-yl)-9-anthryl]phenyl}-2-ethyl-1H-benzimidazole (abbreviation: EtBImPBPhA), and 7-(phenyl-2,3,4,5,6-d₅)-1-[10-(phenyl-2,3,4,5,6-d₅)-9-anthryl]dibenzofuran (abbreviation: PDBfPhA-d10). In particular, CzPA, cgDBCzPA, 2mBnfPPA, and PCzPA exhibit excellent characteristics and thus are preferably selected.

Note that the host material may be a mixture of a plurality of kinds of substances; in the case of using a mixed host material, it is preferable to mix a material having an electron-transport property with a material having a hole-transport property. By mixing the material having an electron-transport property with the material having a hole-transport property, the transport property of the light-emitting layer 113 can be easily adjusted and a recombination region can be easily controlled. The weight ratio of the content of the material having a hole-transport property to the content of the material having an electron-transport property may be 1:19 to 19:1.

Note that a phosphorescent substance can be used as part of the mixed material. When a fluorescent substance is used as the light-emitting substance, a phosphorescent substance can be used as an energy donor for supplying excitation energy to the fluorescent substance.

These mixed materials may form an exciplex. These mixed materials are preferably selected so as to form an exciplex that exhibits light emission whose wavelength overlaps with the wavelength of the lowest-energy-side absorption band of the light-emitting substance, in which case energy can be transferred smoothly and light emission can be obtained efficiently. The use of such a structure is preferable because the driving voltage can also be reduced.

Note that at least one of the materials forming an exciplex may be a phosphorescent substance. In this case, triplet excitation energy can be efficiently converted into singlet excitation energy by reverse intersystem crossing.

In order to form an exciplex efficiently, a material having an electron-transport property is preferably combined with a material having a hole-transport property and a HOMO level higher than or equal to that of the material having an electron-transport property. In addition, the lowest unoccupied molecular orbital (LUMO) level of the material having a hole-transport property is preferably higher than or equal to that of the material having an electron-transport property. Note that the LUMO levels and the HOMO levels of the materials can be derived from the electrochemical characteristics (the reduction potentials and the oxidation potentials) of the materials that are measured by cyclic voltammetry (CV).

The formation of an exciplex can be confirmed by a phenomenon in which the emission spectrum of the mixed film in which the material having a hole-transport property and the material having an electron-transport property are mixed is shifted to the longer wavelength side than the emission spectrum of each of the materials (or has another peak on the longer wavelength side) observed by comparison of the emission spectra of the material having a hole-transport property, the material having an electron-transport property, and the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed by comparison of transient PL of the material having a hole-transport property, the material having an electron-transport property, and the mixed film of these materials. The transient PL can be rephrased as transient electroluminescence (EL). That is, the formation of an exciplex can also be confirmed by a difference in transient response observed by comparison of the transient EL of the material having a hole-transport property, the material having an electron-transport property, and the mixed film of these materials.

The electron-transport layer 114 (the first electron-transport layer 114_1 and the second electron-transport layer 114_2) contains a material having an electron-transport property and has the above-described structure. The material having an electron-transport property preferably has an electron mobility higher than or equal to 1×10⁻⁷ cm²/Vs, further preferably higher than or equal to 1×10⁻⁶ cm²/Vs when the square root of the electric field strength [V/cm] is 600. Note that any other substance can also be used as long as the substance has an electron-transport property higher than a hole-transport property. The above organic compound is preferably an organic compound that has a π-electron deficient heteroaromatic ring. The organic compound that has a π-electron deficient heteroaromatic ring is preferably one or more of an organic compound that has a heteroaromatic ring having an azole skeleton, an organic compound that has a heteroaromatic ring having a pyridine skeleton, an organic compound that has a heteroaromatic ring having a diazine skeleton, and an organic compound that has a heteroaromatic ring having a triazine skeleton.

As the organic compound having an electron-transport property that can be used in the electron-transport layer 114, any of the organic compounds that can be used as the organic compound having an electron-transport property in the light-emitting layer 113 can be similarly used. Among the above organic compounds, the organic compound that has a heteroaromatic ring having a diazine skeleton, the organic compound that has a heteroaromatic ring having a pyridine skeleton, and the organic compound that has a heteroaromatic ring having a triazine skeleton have high reliability and thus are preferable. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. Note that 6,6′-[(perfluoropropane-2,2-diyl)bis(4,1-phenylene)]bis(2,4-diphenyl-1,3,5-triazine) (abbreviation: 6F-2TRZ), 2-(9,9′-spirobi[fluoren]-2-yl)-4,6-diphenyl-1,3,5-triazine (abbreviation: SF2-TRZ), 2-(2′,7′-di-tert-butyl-9,9′-spirobi[9H-fluoren]-2-yl)-4,6-diphenyl-1,3,5-triazine (abbreviation: tBu-SFTzn), 2-[3′-(9,9′-spirobi[9H-fluoren]-2-yl)biphenyl-3-yl]-4,6-diphenyl-1,3,5-triazine (abbreviation: mSFBPTzn), 2-[3′-(9,9-dimethyl-9H-fluoren-2-yl)biphenyl-3-yl]-4,6-diphenyl-1,3,5-triazine (abbreviation: mFBPTzn), 2-(biphenyl-4-yl)-4-phenyl-6-(9,9′-spirobi[9H-fluoren]-2-yl)-1,3,5-triazine (abbreviation: BP-SFTzn), or the like is preferable.

Note that the second electron-transport layer 114_2 is preferably formed with a material that facilitates electron injection from the cathode. As the material, a material that includes an organic compound including a pyridine ring and having an acid dissociation constant pKₐ larger than 3 or a material that includes an organic complex of an alkali metal and an organic compound including a π-electron deficient heteroaromatic ring is preferable.

In the case where the second electron-transport layer 114_2 is formed with a material including an organic compound including a pyridine ring and having an acid dissociation constant pKₐ larger than 3, the organic compound preferably includes two or more pyridine rings. In particular, a phenanthroline ring is preferably included. Specifically, the organic compound is preferably an organic compound including a phenanthroline skeleton, such as mTpPPhen, PnNPhen, or mPPhen2P, and is further preferably an organic compound having a phenanthroline dimeric structure, such as mPPhen2P, because of its high stability.

In the case where the second electron-transport layer 114_2 is formed with a material containing an organic complex of an alkali metal and an organic compound including a π-electron deficient heteroaromatic ring, the organic complex of an alkali metal is preferably an organic complex of lithium, and in particular, 8-quinolinolato-lithium (abbreviation: Liq) is preferable. The organic compounds contained in the first electron-transport layer 114_1 and the second electron-transport layer 114_2 preferably have the same π-electron deficient heteroaromatic ring, and are further preferably the same organic compound, in which case electrons can be transferred smoothly between the first electron-transport layer 114_1 and the second electron-transport layer 114_2.

In the case where the acid dissociation constant pKₐ of an organic compound is unknown, the acid dissociation constants pKₐ of skeletons in the organic compound are calculated and the largest acid dissociation constant pKₐ can be regarded as the acid dissociation constant pKₐ of the organic compound.

The acid dissociation constant pKₐ can be calculated by the following calculation method.

The initial molecular structure of a material serving as a calculation model is the most stable structure (the singlet ground state) obtained by first-principles calculation.

For the first-principles calculation, Jaguar, which is the quantum chemical computational software produced by Schrödinger, Inc., is used, and the most stable structure in the singlet ground state is calculated by the density functional theory (DFT). As a basis function, 6-31G** is used, and as a functional, B3LYP-D3 is used. The structure subjected to quantum chemical calculation is sampled by conformational analysis in mixed torsional/low-mode sampling with Maestro GUI produced by SchrÖdinger, Inc.

In calculation of pKₐ, one or more atoms of the molecule is designated as a basic site, Macro Model is used for searching for a structure that allows the protonated molecule to be stable in water, conformation is searched for with the use of the OPLS 2005 force field, and the lowest-energy conformational isomer thereby obtained is used. Structure optimization is performed by B3LYP/6-31G* using the pKₐ calculation module of Jaguar; then, single point calculation is performed with cc-pVTZ(+) to obtain a pKₐ value through empirical correction for a functional group. In the case where one or more atoms are designated as basic sites in a molecule, the largest of obtained values is used as a pKₐ value.

From the above calculation, the following values of acid dissociation constant pKₐ are obtained, for example: 1-(9,9′-spirobi[9H-fluoren]-2-yl)-1,3,4,6,7,8-hexahydro-2H-pyrimido[1,2-a]pyrimidine (abbreviation: 2hppSF) has a pKₐ of 13.95; 2,9-di(naphthalen-2-yl)-4,7-diphenyl-1,10-phenanthroline (abbreviation: NBPhen) has a pKₐ of 5.59; 4,7-diphenyl-1,10-phenanthroline (abbreviation: BPhen) has a pKₐ of 5.62; 2,2′-(1,3-phenylene)bis(9-phenyl-1,10-phenanthroline) (abbreviation: mPPhen2P) has a pKₐ of 5.16; 2-[3-(2,6-dimethyl-3-pyridinyl)-5-(9-phenanthryl)phenyl]-4,6-diphenyl-1,3,5-triazine (abbreviation: mPn-mDMePyPTzn) has a pKₐ of 5.42; and 4,6-bis[3,5-di(pyridin-3-yl)phenyl]-2-methylpyrimidine (abbreviation: B3PYMPM) has a pKₐ of 4.07.

In the electron-transport layer 114, the layer in contact with the light-emitting layer 113 may function as a hole-blocking layer. In the case where the electron-transport layer in contact with the light-emitting layer functions as a hole-blocking layer, the electron-transport layer is preferably formed using a material having a lower HOMO level than a material contained in the light-emitting layer 113 by greater than or equal to 0.5 eV.

An electron-injection layer may be provided between the second electron-transport layer 114_2 and the second electrode 102. As the electron-injection layer, a layer containing a compound of an alkali metal or an alkaline earth metal or a complex thereof, such as Liq, a layer containing an organic compound having a skeleton with high basicity, such as 1,1′-pyridine-2,6-diyl-bis(1,3,4,6,7,8-hexahydro-2H-pyrimido[1,2-a]pyrimidine) (abbreviation: hpp2Py) or 4,7-di-1-pyrrolidinyl-1,10-phenanthroline (abbreviation: Pyrrd-Phen), may be provided. As the electron-injection layer, a layer which is formed using a substance having an electron-transport property and contains an alkali metal, an alkaline earth metal, or a compound thereof may be used. Note that in the case where the electron-injection layer is provided, the total thickness of the electron-injection layer and the second electron-transport layer 114_2 is preferably less than 10 nm in consideration of the diffusion distance of carriers generated by the interaction between the cathode and the electron-injection layer, further preferably smaller than or equal to 7 nm, in which case the driving voltage can be reduced. The total thickness of the electron-injection layer and the second electron-transport layer 114_2 is preferably greater than 0 nm, further preferably greater than 1 nm, still further preferably greater than or equal to 3 nm, in which case the driving voltage can be further reduced. That is, it is particularly preferable that the total thickness of the electron-injection layer and the second electron-transport layer 114_2 be greater than or equal to 3 nm and less than or equal to 7 nm.

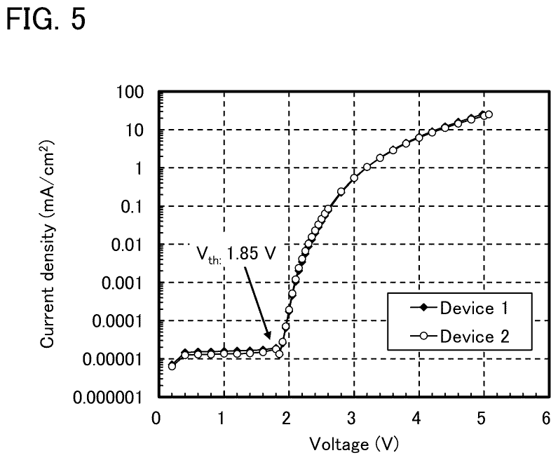

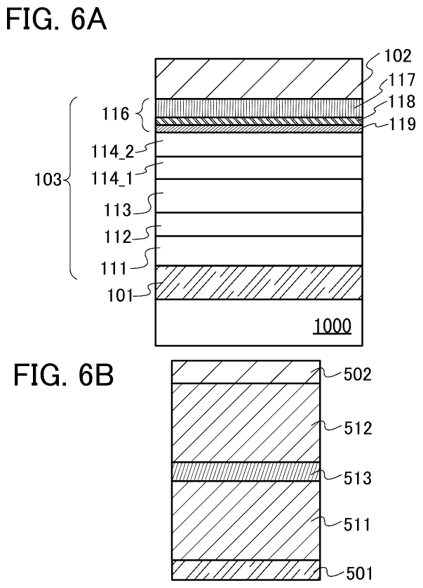

A charge-generation layer 116 may be provided between the second electrode 102 and the second electron-transport layer 114_2 (FIG. 6A). The charge-generation layer 116 refers to a layer capable of injecting holes into a layer in contact with the cathode side of the charge-generation layer 116 and electrons into a layer in contact with the anode side thereof when a potential is applied. The charge-generation layer 116 includes at least a p-type layer 117. The p-type layer 117 is preferably formed using any of the composite materials given above as examples of materials that can be used for the hole-injection layer 111. The p-type layer 117 may be formed by stacking a film containing the acceptor material as a material included in the composite material and a film containing an organic compound having a hole-transport property. When a potential is applied to the p-type layer 117, electrons are injected into the electron-transport layer 114 and holes are injected into the cathode; thus, the light-emitting device operates. Since the organic compound of one embodiment of the present invention in film form has a low refractive index, using the organic compound for the p-type layer 117 enables the light-emitting device to have high external quantum efficiency.

Note that the charge-generation layer 116 preferably includes one or both of an electron-relay layer 118 and an electron-injection buffer layer 119 in addition to the p-type layer 117.

The electron-relay layer 118 contains at least a substance having an electron-transport property and has a function of preventing an interaction between the electron-injection buffer layer 119 and the p-type layer 117 and smoothly transferring electrons. The LUMO level of the substance having an electron-transport property that is contained in the electron-relay layer 118 is preferably between the LUMO level of the acceptor substance in the p-type layer 117 and the LUMO level of a substance contained in a layer of the electron-transport layer 114 that is in contact with the charge-generation layer 116. As a specific value of the energy level, the LUMO level of the substance having an electron-transport property in the electron-relay layer 118 is preferably higher than or equal to −5.0 eV, further preferably higher than or equal to −5.0 eV and lower than or equal to −3.0 eV. Note that as the substance having an electron-transport property in the electron-relay layer 118, a phthalocyanine-based material or a metal complex having a metal-oxygen bond and an aromatic ligand is preferably used.

The electron-injection buffer layer 119 can be formed using a substance having a high electron-injection property, e.g., an alkali metal, an alkaline earth metal, a rare earth metal, or a compound thereof (an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)).

In the case where the electron-injection buffer layer 119 contains a substance having an electron-transport property and a donor substance, the donor substance can be an organic compound such as tetrathianaphthacene (abbreviation: TTN), nickelocene, or decamethylnickelocene, as well as an alkali metal, an alkaline earth metal, a rare earth metal, or a compound thereof (e.g., an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)). As the substance having an electron-transport property, a material similar to the above-described material for the electron-transport layer 114 can be used.

The second electrode 102 includes the cathode. The second electrode 102 may have a stacked-layer structure, in which case a layer in contact with the EL layer 103 functions as the cathode. The cathode is preferably formed using a metal, an alloy, an electrically conductive compound, or a mixture thereof each having a low work function (specifically, lower than or equal to 3.8 eV), for example. Specific examples of such a cathode material include elements belonging to Group 1 or 2 of the periodic table, such as alkali metals (e.g., lithium (Li) and cesium (Cs)), magnesium (Mg), calcium (Ca), and strontium (Sr), alloys containing these elements (e.g., MgAg and AlLi), compounds containing these elements (e.g., lithium fluoride (LiF), cesium fluoride (CsF), and calcium fluoride (CaF₂)), rare earth metals such as europium (Eu) and ytterbium (Yb), and alloys containing these rare earth metals. However, when the electron-injection layer 115 or a thin film formed using any of the above materials having a low work function is provided between the second electrode 102 and the electron-transport layer, a variety of conductive materials such as Al, Ag, ITO, or indium oxide-tin oxide containing silicon or silicon oxide can be used for the cathode regardless of the work function.

When the second electrode 102 is formed using a material that transmits visible light, the light-emitting device can emit light from the second electrode 102 side.

Films of these conductive materials can be formed by a dry process such as a vacuum evaporation method or a sputtering method, an ink-jet method, a spin coating method, or the like. Alternatively, a wet process using a sol-gel method or a wet process using a paste of a metal material may be employed.

The EL layer 103 can be formed by any of a variety of methods, including a dry process and a wet process. For example, a vacuum evaporation method, a gravure printing method, an offset printing method, a screen printing method, an ink-jet method, a spin coating method, or the like may be used.

Different film formation methods may be used to form the electrodes or the layers described above.

Next, an embodiment of a light-emitting device with a structure in which a plurality of light-emitting units are stacked (this type of light-emitting device is also referred to as a stacked or tandem element) is described with reference to FIG. 6B. This light-emitting device includes a plurality of light-emitting units between an anode and a cathode. One light-emitting unit has substantially the same structure as the EL layers 103 illustrated in FIGS. 1A and 1B and FIG. 2. In other words, the light-emitting device illustrated in FIG. 6B includes a plurality of light-emitting units, and each of the light-emitting devices illustrated in FIGS. 1A and 1B and FIG. 2 includes a single light-emitting unit.

In FIG. 6B, a first light-emitting unit 511 and a second light-emitting unit 512 are stacked between a first electrode 501 and a second electrode 502, and a charge-generation layer 513 is provided between the first light-emitting unit 511 and the second light-emitting unit 512. The first electrode 501 and the second electrode 502 correspond, respectively, to the first electrode 101 and the second electrode 102 illustrated in FIG. 1A and FIG. 3A, and can be formed using the materials given in the description for FIG. 1A and FIG. 3A. Furthermore, the first light-emitting unit 511 and the second light-emitting unit 512 may have the same structure or different structures.

The charge-generation layer 513 has a function of injecting electrons into one of the light-emitting units and injecting holes into the other of the light-emitting units when voltage is applied between the first electrode 501 and the second electrode 502. That is, in FIG. 6B, the charge-generation layer 513 injects electrons into the first light-emitting unit 511 and holes into the second light-emitting unit 512 when voltage is applied such that the potential of the anode becomes higher than the potential of the cathode.

The charge-generation layer 513 preferably has a structure similar to that of the charge-generation layer 116 described with reference to FIG. 6A. A composite material of an organic compound and a metal oxide enables low-voltage driving and low-current driving because of having an excellent carrier-injection property and an excellent carrier-transport property.

In the case where the anode-side surface of a light-emitting unit is in contact with the charge-generation layer 513, the charge-generation layer 513 can also function as a hole-injection layer of the light-emitting unit; therefore, a hole-injection layer is not necessarily provided in the light-emitting unit.

In the case where the electron-injection buffer layer 119 is provided in the charge-generation layer 513, the electron-injection buffer layer 119 functions as an electron-injection layer in the light-emitting unit on the anode side; thus, an electron-injection layer is not necessarily formed in the light-emitting unit on the anode side.

Since the charge-generation layer 513 can also be regarded as an electrode, when the light-emitting unit in contact with the anode side of the charge-generation layer 513 has a structure similar to that of the EL layer described in Embodiment 1 (the electron-transport layer has a stacked-layer structure, the GSP_Slope of the electron-transport layer on the anode side is smaller than that of the electron-transport layer on the cathode side, and the thickness of the electron-transport layer on the cathode side is greater than 0 nm and less than 10 nm), the range of choices of the materials for the light-emitting device can be expanded and the light-emitting device can have favorable characteristics.

The light-emitting device having two light-emitting units is described with reference to FIG. 6B; however, one embodiment of the present invention can also be applied to a light-emitting device in which three or more light-emitting units are stacked. With a plurality of light-emitting units partitioned by the charge-generation layer 513 between a pair of electrodes as in the light-emitting device of this embodiment, it is possible to provide a long-life element that can emit light with high luminance at a low current density. A light-emitting apparatus that can be driven at a low voltage and has low power consumption can also be provided.

When the emission colors of the light-emitting units are different, light emission of a desired color can be obtained from the light-emitting device as a whole. For example, in a light-emitting device having two light-emitting units, the emission colors of the first light-emitting unit may be red and green and the emission color of the second light-emitting unit may be blue, so that the light-emitting device can emit white light as the whole.

The EL layer 103, the first light-emitting unit 511, the second light-emitting unit 512, the layers such as the charge-generation layer, and the electrodes that are described above can be formed by a method such as an evaporation method (including a vacuum evaporation method), a droplet discharge method (also referred to as an inkjet method), a coating method, or a gravure printing method. A low molecular material, a middle molecular material (including an oligomer and a dendrimer), or a high molecular material may be included in the above components.

### Embodiment 3

Described in this embodiment is an example in which the light-emitting device of one embodiment of the present invention is used as a display element of a display device. Note that although a light-emitting device shown in this embodiment is formed by a photolithography method, the light-emitting device may be formed by a method using a fine metal mask or the like.

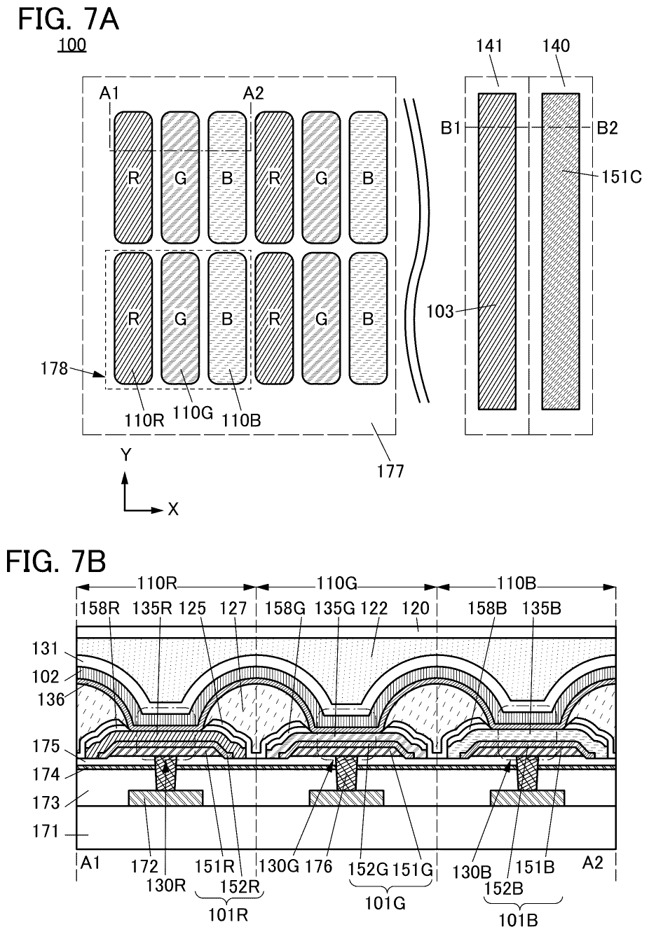

As illustrated in FIG. 7B, a plurality of light-emitting devices 130 are formed over an insulating layer 175 to constitute a display device.

As illustrated in FIG. 7A, the display device includes a pixel portion 177 in which a plurality of pixels 178 are arranged in a matrix. The pixel 178 includes a subpixel 110R, a subpixel 110G, and a subpixel 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals without the letters of the alphabet.

The subpixel 110R emits red light, the subpixel 110G emits green light, and the subpixel 110B emits blue light. Thus, an image can be displayed on the pixel portion 177. Note that in this embodiment, three colors of red (R), green (G), and blue (B) are given as examples of colors of light emitted by the subpixels; however, subpixels of a different combination of colors may be employed. The number of subpixels is not limited to three, and may be four or more. Examples of four subpixels include subpixels emitting light of four colors of R, G, B, and white (W), subpixels emitting light of four colors of R, G, B, and yellow (Y), and four subpixels emitting light of R, G, and B and infrared light (IR).

In this specification and the like, the row direction and the column direction are sometimes referred to as the X direction and the Y direction, respectively. The X direction and the Y direction intersect with each other and are perpendicular to each other, for example.

FIG. 7A illustrates an example where subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 is provided and a region 141 may also be provided. The region 141 is provided between the pixel portion 177 and the connection portion 140. The EL layer 103 is provided in the region 141. A conductive layer 151C is provided in the connection portion 140.

Although FIG. 7A illustrates an example where the region 141 and the connection portion 140 are positioned on the right side of the pixel portion 177, the positions of the region 141 and the connection portion 140 are not particularly limited. The number of the regions 141 and the number of the connection portions 140 can each be one or more.

FIG. 7B is an example of a cross-sectional view along the dashed-dotted line A1-A2 in FIG. 7A. As illustrated in FIG. 7B, the display device includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layers 175, 174, and 173, and a plug 176 is provided to fill the opening.

In the pixel portion 177, the light-emitting device 130 is provided over the insulating layer 175 and the plug 176. A protective layer 131 is provided to cover the light-emitting device 130. A substrate 120 is bonded to the protective layer 131 with a resin layer 122. An inorganic insulating layer 125 and an insulating layer 127 over the inorganic insulating layer 125 are preferably provided between the adjacent light-emitting devices 130.

Although FIG. 7B illustrates cross sections of a plurality of inorganic insulating layers 125 and a plurality of insulating layers 127, the inorganic insulating layers 125 are preferably connected to each other and the insulating layers 127 are preferably connected to each other when the display device is seen from above. That is, the inorganic insulating layer 125 and the insulating layer 127 preferably include opening portions over first electrodes.

In FIG. 7B, a light-emitting device 130R, a light-emitting device 130G, and a light-emitting device 130B are each illustrated as the light-emitting device 130. The light-emitting devices 130R, 130G, and 130B emit light of different colors. For example, the light-emitting device 130R can emit red light, the light-emitting device 130G can emit green light, and the light-emitting device 130B can emit blue light. Alternatively, the light-emitting device 130R, the light-emitting device 130G, or the light-emitting device 130B may emit visible light of another color or infrared light. It can be said that in FIG. 7B, the light-emitting devices 130R and 130G are adjacent light-emitting devices and the light-emitting devices 130G and 130B are adjacent light-emitting devices.

The display device of one embodiment of the present invention can be, for example, a top-emission display device where light is emitted in the direction opposite to a substrate over which light-emitting devices are formed. Note that the display device of one embodiment of the present invention may be of a bottom emission type.

The light-emitting device 130R emits red light (preferably phosphorescent light), and preferably has the structure shown in Embodiment 2. The light-emitting device 130R includes a first electrode 101R (pixel electrode) including a conductive layer 151R and a conductive layer 152R, a first layer 135R over the first electrode 101R, a common layer 136 over the first layer 135R, and the second electrode (common electrode) 102 over the common layer 136. The common layer 136 is preferably the electron-transport layer.

The light-emitting device 130G emits green light (preferably phosphorescent light), and preferably has the structure shown in Embodiment 2. The light-emitting device 130G includes a first electrode 101G (pixel electrode) including a conductive layer 151G and a conductive layer 152G, a first layer 135G over the first electrode 101G, the common layer 136 over the first layer 135G, and the second electrode (common electrode) 102 over the common layer 136. The common layer 136 is preferably the electron-transport layer.

The light-emitting device 130B emits blue light (preferably fluorescent light), and preferably has the structure shown in Embodiment 2. The light-emitting device 130B includes a first electrode 101B (pixel electrode) including a conductive layer 151B and a conductive layer 152B, a first layer 135B over the first electrode 101B, the common layer 136 over the first layer 135B, and the second electrode (common electrode) 102 over the common layer 136. The common layer 136 is preferably the electron-transport layer.

In the light-emitting device, one of the pixel electrode (first electrode) and the common electrode (second electrode) functions as an anode and the other functions as a cathode. In this embodiment, the pixel electrode functions as an anode, and the common electrode functions as a cathode.

The first layers 135R, 135G, and 135B are island-shaped layers that are independent of each other on a light-emitting device basis or on an emission color basis. It is preferable that the first layers 135R, 135G, and 135B not overlap with one another. The first layers included in the plurality of light-emitting devices 130 formed in the light-emitting apparatus, such as the first layers 135R, 135G, and 135B, are collectively referred to as a first layer group 135A in some cases. Providing the island-shaped first layer group 135A in the light-emitting devices 130 can inhibit leakage current between the adjacent light-emitting devices 130 even in a high-resolution display device. This can prevent crosstalk, so that a display device with extremely high contrast can be obtained. Specifically, a display device having high current efficiency at low luminance can be obtained.

The island-shaped first layer group 135A is formed by forming an EL film for each emission color and processing the EL film by a photolithography method.

The first layer 135 is preferably provided to cover the top surface and the side surface of the first electrode 101 (pixel electrode) of the light-emitting device 130. In this case, the aperture ratio of the display device can be easily increased as compared to the structure where an end portion of the first layer 135 is positioned inward from an end portion of the pixel electrode. Covering the side surface of the pixel electrode of the light-emitting device 130 with the first layer 135 can inhibit the first electrode 101 from being in contact with the second electrode 102; hence, a short circuit of the light-emitting device 130 can be inhibited.

In the display device of one embodiment of the present invention, the first electrode 101 (pixel electrode) of the light-emitting device preferably has a stacked-layer structure. For example, in the example illustrated in FIG. 7B, the first electrode 101 of the light-emitting device 130 has a stacked-layer structure of the conductive layer 151 provided on the insulating layer 171 side and the conductive layer 152 provided on the EL layer side.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a work function higher than or equal to 4.0 eV, for example.

The conductive layer 151 and the conductive layer 152 may each be a stack of a plurality of layers containing different materials. In that case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 is a stack of two or more layers, for example, a layer in contact with the conductive layer 152 can be formed using a material that can be used for the conductive layer 152.

Note that the conductive layer 151 preferably has a tapered end portion. Specifically, the conductive layer 151 preferably has a tapered end portion with a taper angle of less than 90°. In that case, the conductive layer 152 provided along the side surface of the conductive layer 151 also has a tapered shape. When the side surface of the conductive layer 152 has a tapered shape, coverage with the first layer 135 provided along the side surface of the conductive layer 152 can be improved.

### Embodiment 4

In this embodiment, a display device of one embodiment of the present invention will be described.

The display device in this embodiment can be a high-resolution display device. Thus, the display device in this embodiment can be used for display portions of information terminals (wearable devices) such as watch-type and bracelet-type information terminals and display portions of wearable devices capable of being worn on a head, such as a virtual reality (VR) device like a head mounted display (HMD) and a glasses-type augmented reality (AR) device.

The display device in this embodiment can be a high-definition display device or a large-sized display device. Accordingly, the display device in this embodiment can be used for display portions of a digital camera, a digital video camera, a digital photo frame, a mobile phone, a portable game console, a portable information terminal, and an audio reproducing device, in addition to display portions of electronic appliances with a relatively large screen, such as a television device, desktop and notebook personal computers, a monitor of a computer and the like, digital signage, and a large game machine such as a pachinko machine.

### [Display Module]

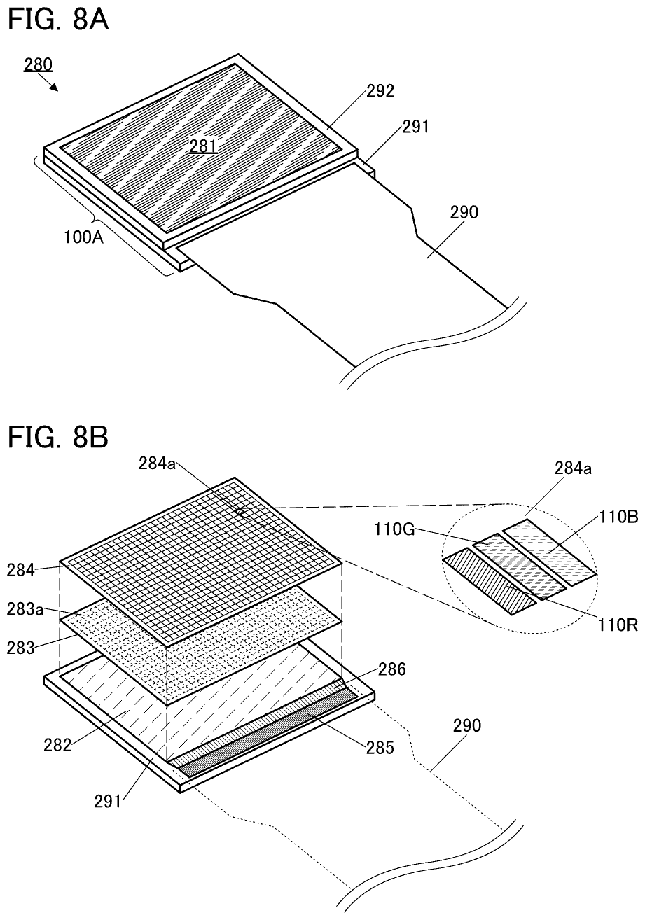

FIG. 8A is a perspective view of a display module 280. The display module 280 includes a display device 100A and an FPC 290. Note that the display device included in the display module 280 is not limited to the display device 100A and may be any of display devices 100B to 100E described later.

The display module 280 includes a substrate 291 and a substrate 292. The substrate 291 can be, for example, a substrate formed of glass, quartz, a metal, an alloy, or a semiconductor or a plastic substrate formed of fiber reinforced plastic (FRP), polyvinyl fluoride (PVF), polyester, or an acrylic resin. Among the above substrates, a substrate having a light-transmitting property can be used as the substrate 292. The display module 280 includes a display portion 281. The display portion 281 is a region of the display module 280 where an image is displayed, and is a region where light emitted from pixels provided in a pixel portion 284 described later can be seen.

FIG. 8B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 8B. The pixels 284a can employ any of the structures described in the above embodiments. FIG. 8B illustrates an example where the pixel 284a has a structure similar to that of the pixel 178 illustrated in FIG. 7A.

The pixel circuit portion 283 includes a plurality of pixel circuits 283a arranged periodically.

One pixel circuit 283a is a circuit that controls driving of a plurality of elements included in one pixel 284a.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An integrated circuit (IC) may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic appliances including a relatively small display portion.

### [Display Device 100A]

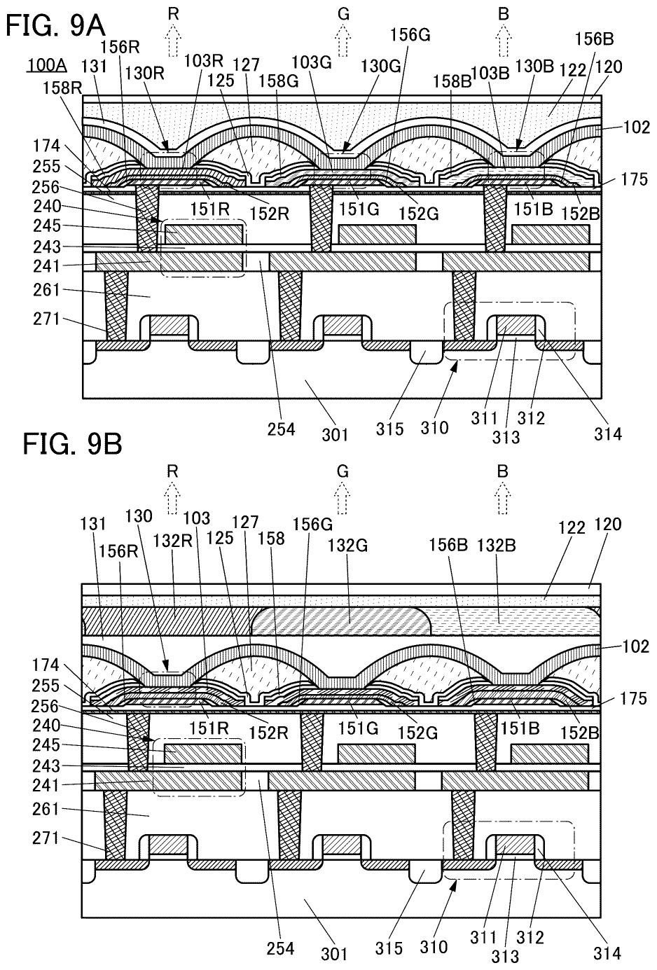

The display device 100A illustrated in FIG. 9A includes a substrate 301, the light-emitting devices 130R, 130G, and 130B, a capacitor 240, and a transistor 310.

The substrate 301 corresponds to the substrate 291 in FIGS. 8A and 8B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. An insulator is provided in regions between adjacent light-emitting devices.

An insulating layer 156R is provided to include a region overlapping with the side surface of the conductive layer 151R. An insulating layer 156G is provided to include a region overlapping with the side surface of the conductive layer 151G. An insulating layer 156B is provided to include a region overlapping with the side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. A sacrificial layer 158R is positioned over the first layer 135R. A sacrificial layer 158G is positioned over the first layer 135G. A sacrificial layer 158B is positioned over the first layer 135B.

Each of the conductive layers 151R, 151G, and 151B is electrically connected to one of the source and the drain of the corresponding transistor 310 through a plug 256 embedded in the insulating layers 243, 255, 174, and 175, the conductive layer 241 embedded in the insulating layer 254, and the plug 271 embedded in the insulating layer 261. Any of a variety of conductive materials can be used for the plugs.

The protective layer 131 is provided over the light-emitting devices 130R, 130G, and 130B. The substrate 120 is bonded to the protective layer 131 with the resin layer 122. Embodiment 3 can be referred to for the details of the light-emitting device 130 and the components thereover up to the substrate 120. The substrate 120 corresponds to the substrate 292 in FIG. 8A.

FIG. 9B illustrates a variation example of the display device 100A illustrated in FIG. 9A. The display device illustrated in FIG. 9B includes a coloring layer 132R, a coloring layer 132G, and a coloring layer 132B, and each of the light-emitting devices 130 includes a region overlapping with one of the coloring layers 132R, 132G, and 132B. In the display device illustrated in FIG. 9B, the light-emitting device 130 can emit white light, for example. The coloring layer 132R, the coloring layer 132G, and the coloring layer 132B can transmit red light, green light, and blue light, respectively, for example.

### [Display Device 100B]

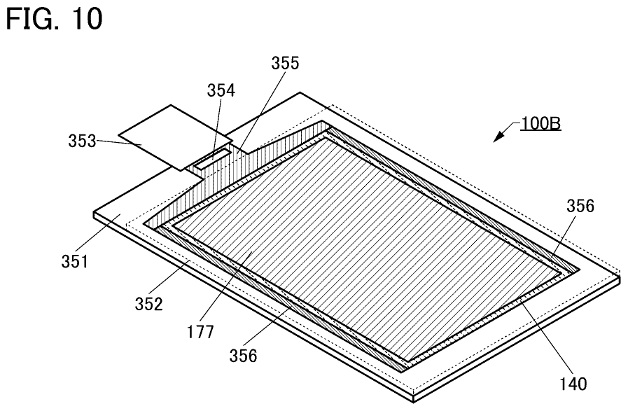

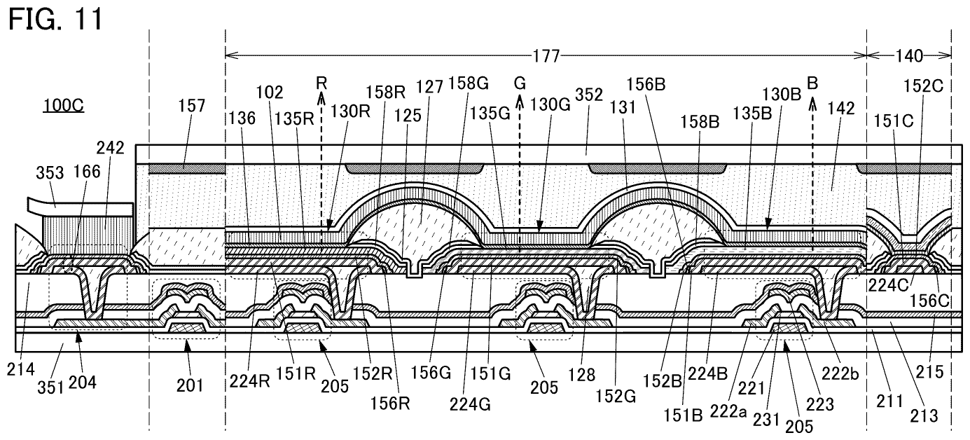

FIG. 10 is a perspective view of the display device 100B, and FIG. 11 is a cross-sectional view of the display device 100C.

In the display device 100B, a substrate 352 and a substrate 351 are bonded to each other. In FIG. 10, the substrate 352 is denoted by a dashed line.

The display device 100B includes the pixel portion 177, the connection portion 140, a circuit 356, a wiring 355, and the like. FIG. 10 illustrates an example where an IC 354 and an FPC 353 are mounted on the display device 100B. Thus, the structure illustrated in FIG. 10 can be regarded as a display module including the display device 100B, the IC, and the FPC. Here, a display device in which a substrate is equipped with a connector such as an FPC or mounted with an IC is referred to as a display module.

The connection portion 140 is provided outside the pixel portion 177. The number of connection portions 140 may be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 10 illustrates an example where the IC 354 is provided over the substrate 351 by a chip on glass (COG) method, a chip on film (COF) method, or the like. An IC including a scan line driver circuit, a signal line driver circuit, or the like can be used as the IC 354, for example. Note that the display device 100B and the display module are not necessarily provided with an IC. Alternatively, the IC may be mounted on the FPC by a COF method, for example.

FIG. 11 illustrates an example of cross sections of part of a region including the FPC 353, part of the circuit 356, part of the pixel portion 177, part of the connection portion 140, and part of a region including an end portion of the display device 100n.

### [Display Device 100C]

The display device 100C illustrated in FIG. 11 includes a transistor 201, a transistor 205, the light-emitting device 130R that emits red light, the light-emitting device 130G that emits green light, the light-emitting device 130B that emits blue light, and the like between the substrate 351 and the substrate 352.

Embodiment 1 can be referred to for the details of the light-emitting devices 130R, 130G, and 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through an opening provided in an insulating layer 214. An end portion of the conductive layer 151R is positioned outward from an end portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layers 224G, 151G, and 152G and the insulating layer 156G in the light-emitting device 130G are not described in detail because they are respectively similar to the conductive layers 224R, 151R, and 152R and the insulating layer 156R in the light-emitting device 130R; the same applies to the conductive layers 224B, 151B, and 152B and the insulating layer 156B in the light-emitting device 130B.

The conductive layers 224R, 224G, and 224B each have a depressed portion covering the opening provided in the insulating layer 214. A layer 128 is embedded in the depressed portion.

The layer 128 has a function of filling the depressed portions of the conductive layers 224R, 224G, and 224B to obtain planarity. Over the conductive layers 224R, 224G, and 224B and the layer 128, the conductive layers 151R, 151G, and 151B that are respectively electrically connected to the conductive layers 224R, 224G, and 224B are provided. Thus, the regions overlapping with the depressed portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 131 is provided over the light-emitting devices 130R, 130G, and 130B. The protective layer 131 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 10, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided in a frame shape not to overlap with the light-emitting device. Furthermore, the space may be filled with a resin other than the frame-shaped adhesive layer 142.

FIG. 11 illustrates an example where the connection portion 140 includes a conductive layer 224C obtained by processing the same conductive film as the conductive layers 224R, 224G, and 224B; the conductive layer 151C obtained by processing the same conductive film as the conductive layers 151R, 151G, and 151B; and a conductive layer 152C obtained by processing the same conductive film as the conductive layers 152R, 152G, and 152B. In the example illustrated in FIG. 11, an insulating layer 156C is provided to include a region overlapping with the side surface of the conductive layer 151C.

The display device 100C has a top-emission structure. Light from the light-emitting device is emitted toward the substrate 352. For the substrate 352, a material with a high visible-light-transmitting property is preferably used. In the case where the light-emitting device emits infrared or near-infrared light, a material having a high transmitting property with respect to infrared or near-infrared light is preferably used. The first electrode (pixel electrode) contains a material that reflects visible light, and the second electrode (counter electrode) contains a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or more.

An inorganic insulating film is preferably used as each of the insulating layers 211, 213, and 215.

An organic insulating layer is suitable as the insulating layer 214 functioning as a planarization layer.

Each of the transistors 201 and 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate.

A connection portion 204 is provided in a region of the substrate 351 not overlapping with the substrate 352. In the connection portion 204, the wiring 355 is electrically connected to the FPC 353 through a conductive layer 166 and a connection layer 242. An example is described in which the conductive layer 166 has a stacked-layer structure of a conductive film obtained by processing the same conductive film as the conductive layers 224R, 224G, and 224B; a conductive film obtained by processing the same conductive film as the conductive layers 151R, 151G, and 151B; and a conductive film obtained by processing the same conductive film as the conductive layers 152R, 152G, and 152B. On the top surface of the connection portion 204, the conductive layer 166 is exposed. Thus, the connection portion 204 and the FPC 353 can be electrically connected to each other through the connection layer 242.

The light-blocking layer 157 is preferably provided on the surface of the substrate 352 on the substrate 351 side. The light-blocking layer 157 can be provided over a region between adjacent light-emitting devices, in the connection portion 140, in the circuit 356, and the like. A variety of optical members can be arranged on the outer surface of the substrate 352.

A material that can be used for the substrate 120 can be used for each of the substrates 351 and 352.

A material that can be used for the resin layer 122 can be used for the adhesive layer 142.

As the connection layer 242, an anisotropic conductive film (ACF), an anisotropic conductive paste (ACP), or the like can be used.

### [Display Device 100D]

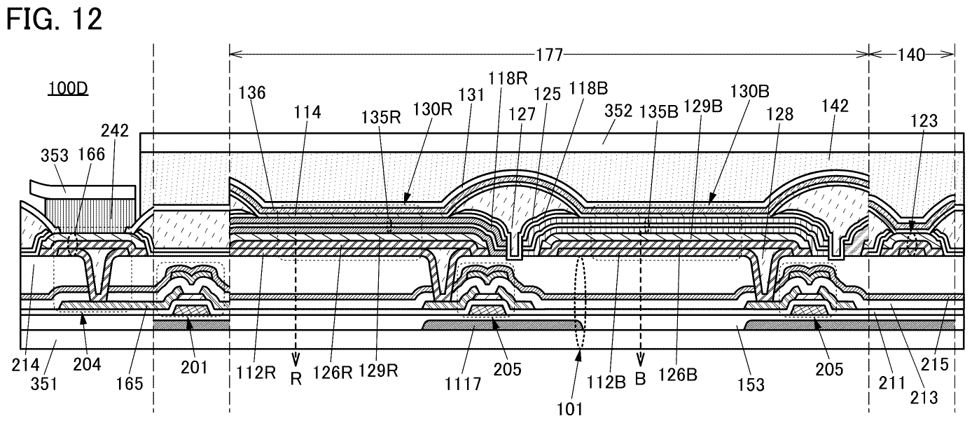

The display device 100D illustrated in FIG. 12 differs from the display device 100C illustrated in FIG. 11 mainly in having a bottom-emission structure.

Light from the light-emitting device is emitted toward the substrate 351. For the substrate 351, a material with a high visible-light-transmitting property is preferably used. By contrast, there is no limitation on the light-transmitting property of a material used for the substrate 352.

The light-blocking layer 1117 is preferably formed between the substrate 351 and the transistor 201 and between the substrate 351 and the transistor 205. FIG. 12 illustrates an example where the light-blocking layer 1117 is provided over the substrate 351, an insulating layer 153 is provided over the light-blocking layer 1117, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material with a high visible-light-transmitting property is used for each of the conductive layers 112R, 112B, 126R, 126B, 129R, and 129B. A material that reflects visible light is preferably used for the second electrode.

Although not illustrated in FIG. 12, the light-emitting device 130G is also provided.

Although FIG. 12 and the like illustrate an example where the top surface of the layer 128 includes a flat portion, the shape of the layer 128 is not particularly limited.

### [Display Device 100E]

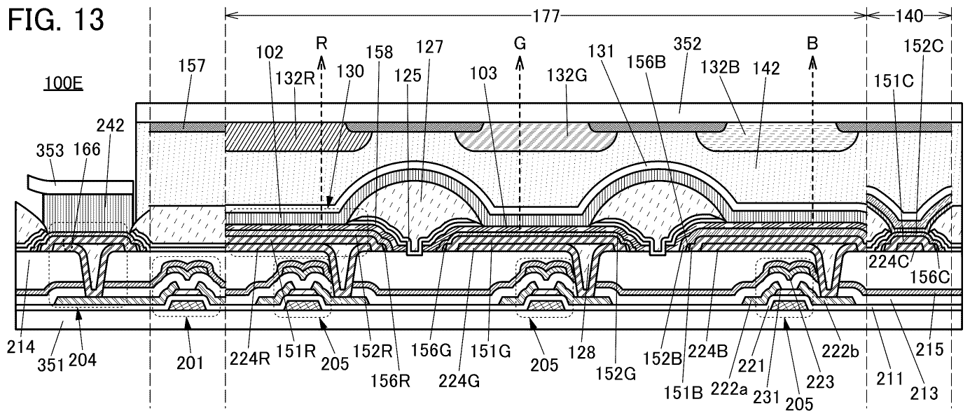

The display device 100E illustrated in FIG. 13 is a variation example of the display device 100C illustrated in FIG. 11 and differs from the display device 100C mainly in including the coloring layers 132R, 132G, and 132B.

In the display device 100E, the light-emitting device 130 includes a region overlapping with one of the coloring layers 132R, 132G, and 132B. The coloring layers 132R, 132G, and 132B can be provided on a surface of the substrate 352 on the substrate 351 side. End portions of the coloring layers 132R, 132G, and 132B can overlap with the light-blocking layer 157.

In the display device 100E, the light-emitting device 130 can emit white light, for example. The coloring layer 132R, the coloring layer 132G, and the coloring layer 132B can transmit red light, green light, and blue light, respectively, for example. Note that in the display device 100E, the coloring layers 132R, 132G, and 132B may be provided between the protective layer 131 and the adhesive layer 142.

Although FIG. 11, FIG. 13, and the like illustrate an example in which the top surface of the layer 128 includes a flat portion, the shape of the layer 128 is not particularly limited.

This embodiment can be combined as appropriate with the other embodiments or the examples. In this specification, in the case where a plurality of structure examples are shown in one embodiment, the structure examples can be combined as appropriate.

### Embodiment 5

In this embodiment, electronic appliances of embodiments of the present invention will be described.

Electronic appliances in this embodiment each include the display device of one embodiment of the present invention in a display portion. The display device of one embodiment of the present invention has low power consumption. Thus, the display device of one embodiment of the present invention can be used for display portions of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and notebook personal computers, a monitor of a computer and the like, digital signage, and a large game machine such as a pachinko machine.

In particular, the display device of one embodiment of the present invention has low power consumption, and thus can be suitably used for a relatively small electronic appliance. Examples of such an electronic appliance include watch-type and bracelet-type information terminals (wearable devices) and wearable devices capable of being worn on a head, such as a VR device like a head-mounted display, a glasses-type AR device, and an MR device.

The electronic appliance in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

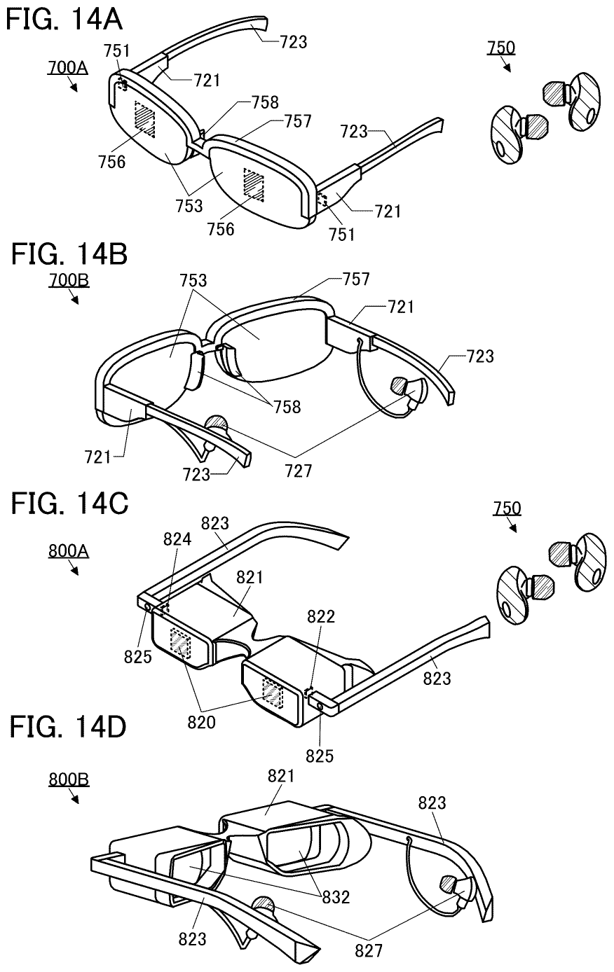

Examples of wearable devices capable of being worn on a head are described with reference to FIGS. 14A to 14D.

An electronic appliance 700A illustrated in FIG. 14A and an electronic appliance 700B illustrated in FIG. 14B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic appliance can have low power consumption and be driven for a long time.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753.

In the electronic appliances 700A and 700B, a camera capable of capturing images of the front side may be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic appliances 700A and 700B are provided with a battery, so that they can be charged wirelessly and/or by wire.

A touch sensor module may be provided in the housing 721.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

An electronic appliance 800A illustrated in FIG. 14C and an electronic appliance 800B illustrated in FIG. 14D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, the electronic appliance can have low power consumption and be driven for a long time.

The display portions 820 are positioned inside the housing 821 so as to be seen through the lenses 832. When the pair of display portions 820 display different images, three-dimensional display using parallax can be performed.

The electronic appliances 800A and 800B preferably include a mechanism for adjusting the lateral positions of the lenses 832 and the display portions 820 so that the lenses 832 and the display portions 820 are positioned optimally in accordance with the positions of the user's eyes.

The electronic appliance 800A or the electronic appliance 800B can be mounted on the user's head with the wearing portions 823.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

The electronic appliance 800A may include a vibration mechanism that functions as bone-conduction earphones.

The electronic appliances 800A and 800B may each include an input terminal. To the input terminal, a cable for supplying a video signal from a video output device or the like, power for charging a battery provided in the electronic appliance, and the like can be connected.

The electronic appliance of one embodiment of the present invention may have a function of performing wireless communication with earphones 750.

The electronic appliance may include an earphone portion. The electronic appliance 700B illustrated in FIG. 14B includes earphone portions 727. Part of a wiring that connects the earphone portion 727 and the control portion may be positioned inside the housing 721 or the wearing portion 723.

Similarly, the electronic appliance 800B illustrated in FIG. 14D includes earphone portions 827. For example, the earphone portion 827 can be connected to the control portion 824 by wire.

As described above, both the glasses-type device (e.g., the electronic appliances 700A and 700B) and the goggles-type device (e.g., the electronic appliances 800A and 800B) are preferable as the electronic appliance of one embodiment of the present invention.

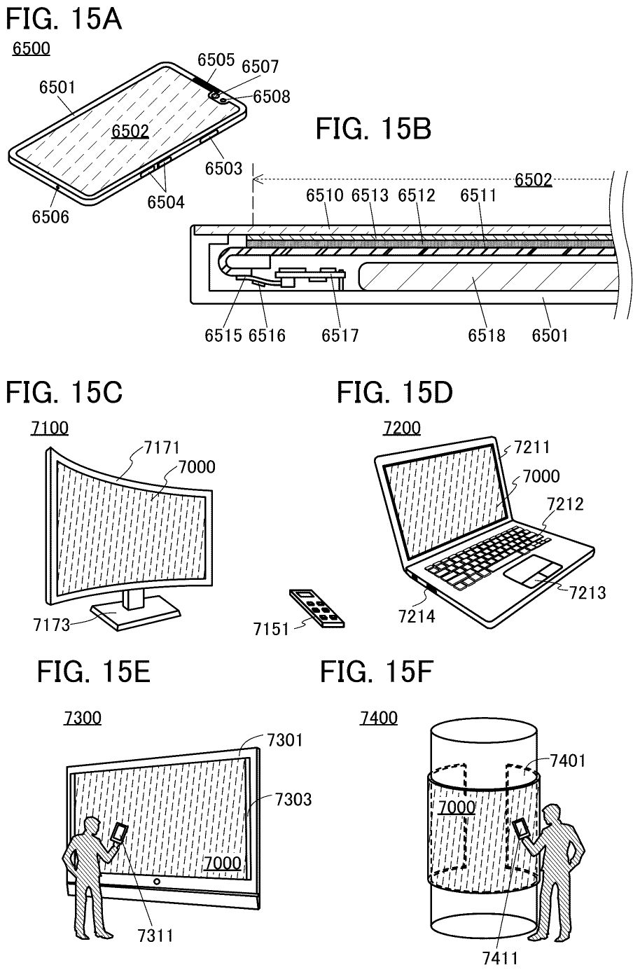

An electronic appliance 6500 illustrated in FIG. 15A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, the electronic appliance can have low power consumption and be driven for a long time.

FIG. 15B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with a bonding layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be used in the display panel 6511. Thus, an extremely lightweight electronic appliance can be obtained. Since the display panel 6511 is extremely thin, the battery 6518 with high capacity can be mounted without an increase in the thickness of the electronic appliance. Moreover, part of the display panel 6511 is folded back so that a connection portion with the FPC 6515 is provided on the back side of the pixel portion, whereby an electronic appliance with a narrow bezel can be obtained.

FIG. 15C illustrates an example of a television device. In a television device 7100, a display portion 7000 is incorporated in a housing 7171. Here, the housing 7171 is supported by a stand 7173.

The display device of one embodiment of the present invention can be used in the display portion 7000. Thus, the electronic appliance can have low power consumption and be driven for a long time.

Operation of the television device 7100 illustrated in FIG. 15C can be performed with an operation switch provided in the housing 7171 and a separate remote control 7151.

FIG. 15D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000. Thus, the electronic appliance can have low power consumption and be driven for a long time.

FIGS. 15E and 15F illustrate examples of digital signage.

Digital signage 7300 illustrated in FIG. 15E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 15F illustrates digital signage 7400 attached to a cylindrical pillar 7401. The digital signage 7400 includes the display portion 7000 provided along a curved surface of the pillar 7401.

In FIGS. 15E and 15F, the display device of one embodiment of the present invention can be used in the display portion 7000. Thus, a highly reliable electronic appliance can be obtained.

A larger area of the display portion 7000 can increase the amount of information that can be provided at a time. The larger display portion 7000 attracts more attention, so that the effectiveness of the advertisement can be increased, for example.

As illustrated in FIGS. 15E and 15F, it is preferable that the digital signage 7300 or the digital signage 7400 can work with an information terminal 7311 or an information terminal 7411, such as a smartphone that a user has, through wireless communication.

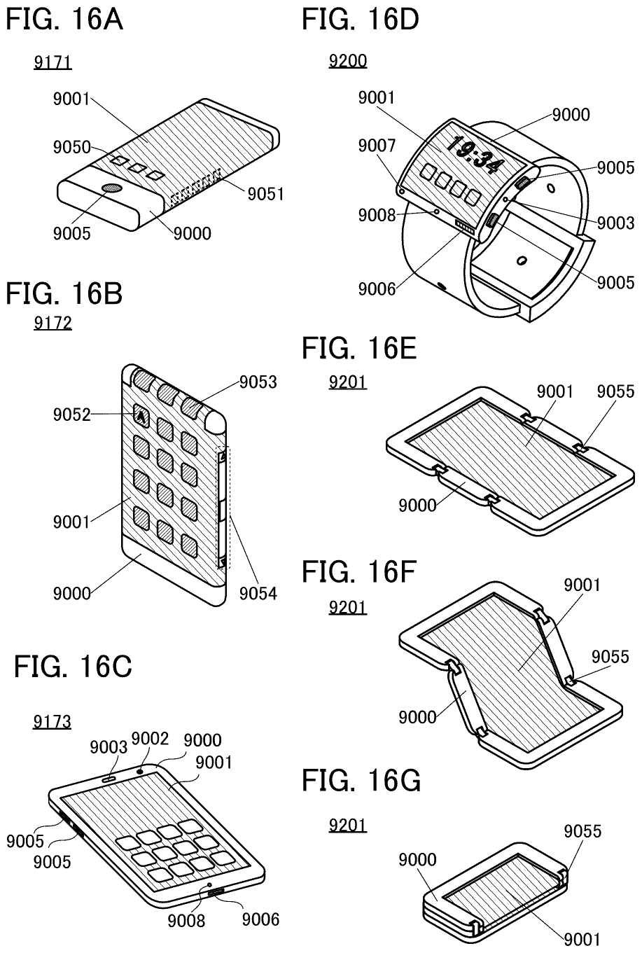

Electronic appliances illustrated in FIGS. 16A to 16G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic appliances illustrated in FIGS. 16A to 16G have a variety of functions. For example, the electronic appliances can have a function of displaying a variety of information (e.g., a still image, a moving image, and a text image) on the display portion, a touch panel function, a function of displaying a calendar, date, time, and the like, a function of controlling processing with use of a variety of software (programs), a wireless communication function, and a function of reading out and processing a program or data stored in a recording medium.

The electronic appliances illustrated in FIGS. 16A to 16G are described in detail below.

FIG. 16A is a perspective view of a portable information terminal 9171. The portable information terminal 9171 can be used as a smartphone, for example. The portable information terminal 9171 may include the speaker 9003, the connection terminal 9006, the sensor 9007, or the like. The portable information terminal 9171 can display text and image information on its plurality of surfaces. FIG. 16A illustrates an example where three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 16B is a perspective view of a portable information terminal 9172. The portable information terminal 9172 has a function of displaying information on three or more surfaces of the display portion 9001. In the example illustrated here, information 9052, information 9053, and information 9054 are displayed on different surfaces. For example, the user of the portable information terminal 9172 can check the information 9053 displayed such that it can be seen from above the portable information terminal 9172, with the portable information terminal 9172 put in a breast pocket of his/her clothes.

FIG. 16C is a perspective view of a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 16D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 16E to 16G are perspective views of a foldable portable information terminal 9201. FIG. 16E is a perspective view illustrating the portable information terminal 9201 that is opened. FIG. 16G is a perspective view illustrating the portable information terminal 9201 that is folded. FIG. 16F is a perspective view illustrating the portable information terminal 9201 that is shifted from one of the states in FIGS. 16E and 16G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined as appropriate with the other embodiments or the examples. In this specification, in the case where a plurality of structure examples are shown in one embodiment, the structure examples can be combined as appropriate.

### Example 1

Described in this example are specific methods for fabricating a light-emitting device 1-0, a light-emitting device 1-1, a light-emitting device 1-2, a light-emitting device 1-3, and a light-emitting device 1-4 and characteristics of the light-emitting devices. Structural formulae of main compounds used in this example are shown below.

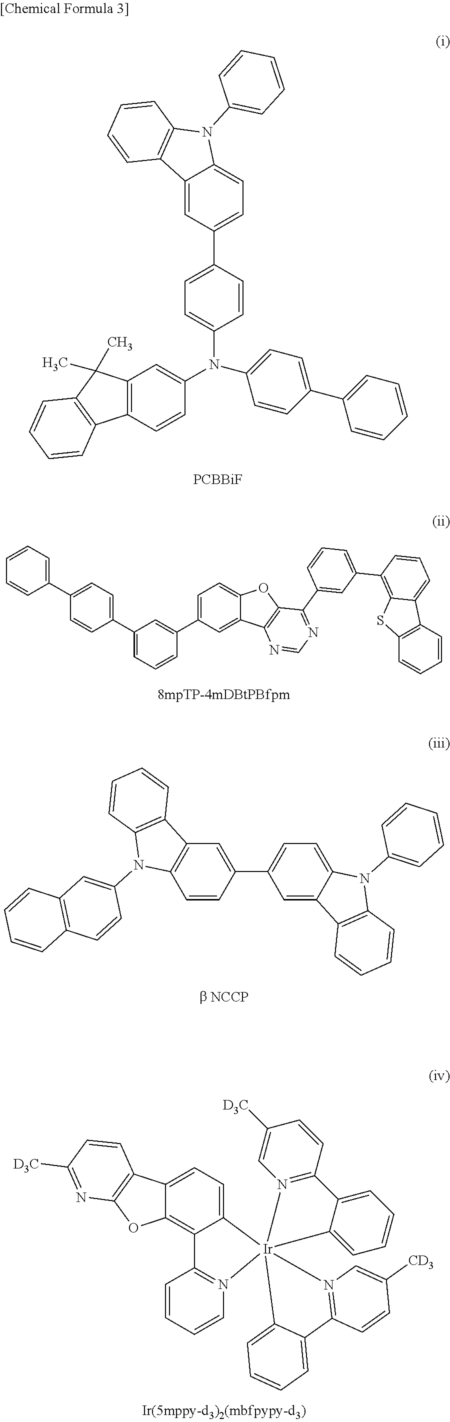

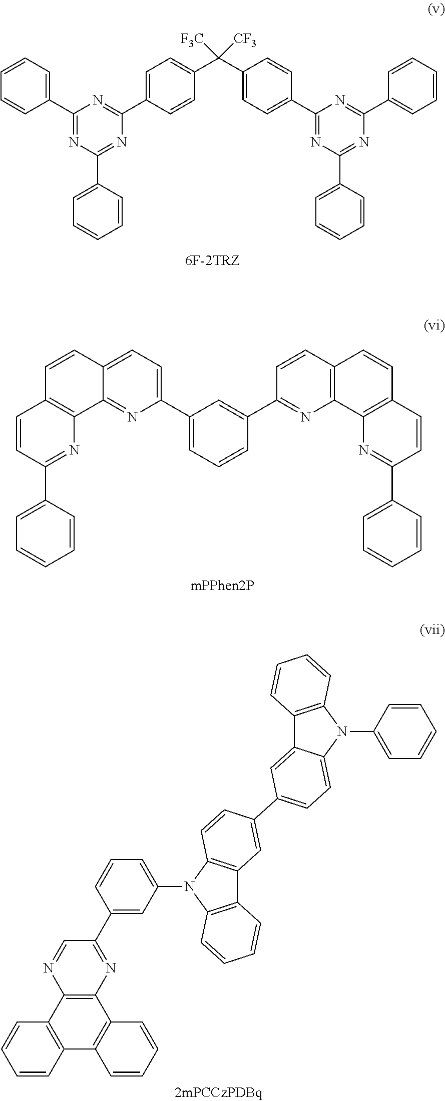 [SMILES: FC(F)(F)C(c1ccc(-c2nc(-c3ccccc3)nc(-c3ccccc3)n2)cc1)(c1ccc(-c2nc(-c3ccccc3)nc(-c3ccccc3)n2)cc1)C(F)(F)F ; c1ccc(-c2ccc3ccc4ccc(-c5cccc(-c6ccc7ccc8ccc(-c9ccccc9)nc8c7n6)c5)nc4c3n2)cc1 ; c1ccc(-n2c3ccccc3c3cc(-c4ccc5c(c4)c4ccccc4n5-c4cccc(-c5cnc6c7ccccc7c7ccccc7c6n5)c4)ccc32)cc1]

### (Fabrication Method of Light-Emitting Device 1-0)

First, indium tin oxide containing silicon oxide (ITSO) was deposited over a glass substrate to a thickness of 70 nm by a sputtering method, so that the first electrode 101 having a size of 2 mm×2 mm was formed. Note that the ITSO serves as an anode.

Then, pretreatment for formation of the light-emitting device over the substrate was performed by washing the substrate surface with water.

After that, the substrate was transferred into a vacuum evaporation apparatus where the internal pressure was reduced to approximately 1×10⁻⁴ Pa, and was subjected to vacuum baking at 170° C. for 30 minutes in a heating chamber of the vacuum evaporation apparatus, and then the substrate was cooled down for approximately 30 minutes.

Next, the substrate provided with the first electrode 101 was fixed to a substrate holder provided in the vacuum evaporation apparatus such that the surface on which the first electrode 101 was formed faced downward. Then, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron-acceptor material with a molecular weight of 672 (OCHD-003) were deposited over the inorganic insulating film and the first electrode 101 to a thickness of 10 nm by co-evaporation such that the weight ratio of PCBBiF to OCHD-003 was 1:0.03, whereby the hole-injection layer 111 was formed.

Over the hole-injection layer 111, PCBBiF was deposited by evaporation to a thickness of 40 nm, whereby the hole-transport layer 112 was formed.

Then, over the hole-transport layer 112, 8-(p-terphenyl-3-yl)-4-[3-(dibenzothiophen-4-yl)phenyl]-[1]benzofuro[3,2-d]pyrimidine (abbreviation: 8mpTP-4mDBtPBfpm) represented by Structural Formula (ii) above, 9-(2-naphthyl)-9′-phenyl-3,3′-bi-9H-carbazole (abbreviation: QNCCP) represented by Structural Formula (iii) above, and [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)) represented by Structural Formula (iv) above were deposited by co-evaporation to a thickness of 40 nm such that the weight ratio of 8mpTP-4mDBtPBfpm to βNCCP to Ir(5mppy-d₃)₂(mbfpypy-d₃) was 0.5:0.5:0.1, whereby the light-emitting layer 113 was formed. The GSP_Slope of the film formed by co-evaporation of 8mpTP-4mDBtPBfpm, βNCCP, and Ir(5mppy-d₃)₂(mbfpypy-d₃) with a weight ratio of 8mpTP-4mDBtPBfpm to βNCCP to Ir(5mppy-d₃)₂(mbfpypy-d₃) of 0.5:0.5:0.1 is 51.5 mV/nm. Note that the GSP_Slope of each of the materials in this example was measured by the method described in Embodiment 1.

After that, 6,6′-[(perfluoropropane-2,2-diyl)bis(4,1-phenylene)]bis(2,4-diphenyl-1,3,5-triazine) (abbreviation: 6F-2TRZ) represented by Structural Formula (v) above was deposited by evaporation to a thickness of 40 nm, whereby an electron-transport layer was formed. The evaporated film of 6F-2TRZ has an extremely small GSP_Slope of −108 mV/nm.

After the electron-transport layer was formed, lithium fluoride (LiF) was deposited by evaporation to a thickness of 1 nm, and then aluminum (Al) was deposited by evaporation to a thickness of 100 nm, whereby the second electrode 102 (cathode) was formed. That is, the light-emitting device 1-0 is a light-emitting device in which the number of the electron-transport layer is one.

Next, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under atmospheric pressure for one hour. In this manner, the light-emitting device 1-0 was fabricated.

### (Fabrication Method of Light-Emitting Device 1-1)

The light-emitting device 1-1 was fabricated in a manner similar to that of the light-emitting device 1-0 except that the electron-transport layer in the light-emitting device 1-1 was formed in the following manner: 6F-2TRZ was deposited by evaporation to a thickness of 40 nm to form a first electron-transport layer, and then 2,2′-(1,3-phenylene)bis(9-phenyl-1,10-phenanthroline) (abbreviation: mPPhen2P) represented by Structural Formula (vi) above was deposited by evaporation to a thickness of 5 nm to form a second electron-transport layer.

Note that the GSP_Slope of the evaporated film of mPPhen2P was 1.50 mV/nm. That is, the light-emitting device 1-1 includes the first electron-transport layer on the anode side and the second electron-transport layer on the cathode side; the first electron-transport layer is in contact with the second electron-transport layer; the second electron-transport layer is in contact with the cathode; the GSP_Slope of an evaporated film of the material included in the second electron-transport layer is larger than the GSP_Slope of an evaporated film of the material included in the first electron-transport layer; and the thickness of the second electron-transport layer is 5 nm. Note that the difference in GSP_Slope between the first electron-transport layer and the second electron-transport layer is larger than or equal to 100 mV/nm, and mPPhen2P included in the second electron-transport layer is an organic compound including a pyridine ring and having an acid dissociation constant pKₐ greater than 3. The pKₐ of mPPhen2P is 5.16.

### (Fabrication Method of Light-Emitting Device 1-2)

The light-emitting device 1-2 was fabricated in a manner similar to that of the light-emitting device 1-1 except that the thickness of the second electron-transport layer in the light-emitting device 1-2 was 10 nm. That is, the light-emitting device 1-2 includes the first electron-transport layer on the anode side and the second electron-transport layer on the cathode side; the first electron-transport layer is in contact with the second electron-transport layer; the second electron-transport layer is in contact with the cathode; the GSP_Slope of an evaporated film of the material included in the second electron-transport layer is larger than the GSP_Slope of an evaporated film of the material included in the first electron-transport layer; and the thickness of the second electron-transport layer is 10 nm. Note that the difference in GSP_Slope between the first electron-transport layer and the second electron-transport layer is larger than or equal to 100 mV/nm, and mPPhen2P included in the second electron-transport layer is an organic compound including a pyridine ring and having an acid dissociation constant pKₐ greater than 3. The pKₐ of mPPhen2P is 5.16.

### (Fabrication Method of Light-Emitting Device 1-3)

The light-emitting device 1-3 was fabricated in a manner similar to that of the light-emitting device 1-1 except that the thickness of the second electron-transport layer in the light-emitting device 1-3 was 20 nm. That is, the light-emitting device 1-3 includes the first electron-transport layer on the anode side and the second electron-transport layer on the cathode side; the first electron-transport layer is in contact with the second electron-transport layer; the second electron-transport layer is in contact with the cathode; the GSP_Slope of an evaporated film of the material included in the second electron-transport layer is larger than the GSP_Slope of an evaporated film of the material included in the first electron-transport layer; and the thickness of the second electron-transport layer is 20 nm. Note that the difference in GSP_Slope between the first electron-transport layer and the second electron-transport layer is larger than or equal to 100 mV/nm, and mPPhen2P included in the second electron-transport layer is an organic compound including a pyridine ring and having an acid dissociation constant pKₐ greater than 3. The pKₐ of mPPhen2P is 5.16.

### (Fabrication Method of Light-Emitting Device 1-4)

The light-emitting device 1-4 was fabricated in a manner similar to that of the light-emitting device 1-3 except that the first electron-transport layer in the light-emitting device 1-4 was formed in the following manner: 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (vii) above was deposited by evaporation to a thickness of 20 nm. Note that the GSP_Slope of the evaporated film of 2mPCCzPDBq was 12.4 mV/nm. That is, the light-emitting device 1-4 includes the first electron-transport layer on the anode side and the second electron-transport layer on the cathode side; the first electron-transport layer is in contact with the second electron-transport layer; the second electron-transport layer is in contact with the cathode; the GSP_Slope of an evaporated film of the material included in the second electron-transport layer is smaller than the GSP_Slope of an evaporated film of the material included in the first electron-transport layer; and the thickness of the second electron-transport layer is 20 nm.

The device structures of the light-emitting devices 1-0 to 1-4 are shown in the tables below.

TABLE 3

| | | | | | |
|---|---|---|---|---|---|
| | Light- | Light- | Light- | Light- | Light- |
| Thickness | emitting | emitting | emitting | emitting | emitting |
| (nm) | device 1-0 | device 1-1 | device 1-2 | device 1-3 | device 1-4 |

| Second electrode | | 100 | Al | |
|---|---|---|---|---|
| | | 1 | LiF | |
| Electron-transport | 2 | *2 | mPPhen2P | |
| layer | 1 | *1 | 6F-2TRZ | 2mPCCzPDBq |

| | | |
|---|---|---|
| Light-emitting layer | 40 | 8mpTP-4mDBtPBfpm:βNCCP:Ir(5mppy-d₃)₂(mbfpypy-d₃) |
| | | (0.5:0.5:0.1) |
| Hole-transport layer | 40 | PCBBiF |
| Hole-injection layer | 10 | PCBBiF:OCHD-003 (1:0.03) |
| First electrode | 70 | ITSO |

TABLE 4

| | *1 | *2 | |
|---|---|---|---|
| Light-emitting device 1-0 | 40 nm | 0 | nm |
| Light-emitting device 1-1 | | 5 | nm |
| Light-emitting device 1-2 | | 10 | nm |
| Light-emitting device 1-3 | | 20 | nm |
| Light-emitting device 1-4 | 20 nm | 20 | nm |

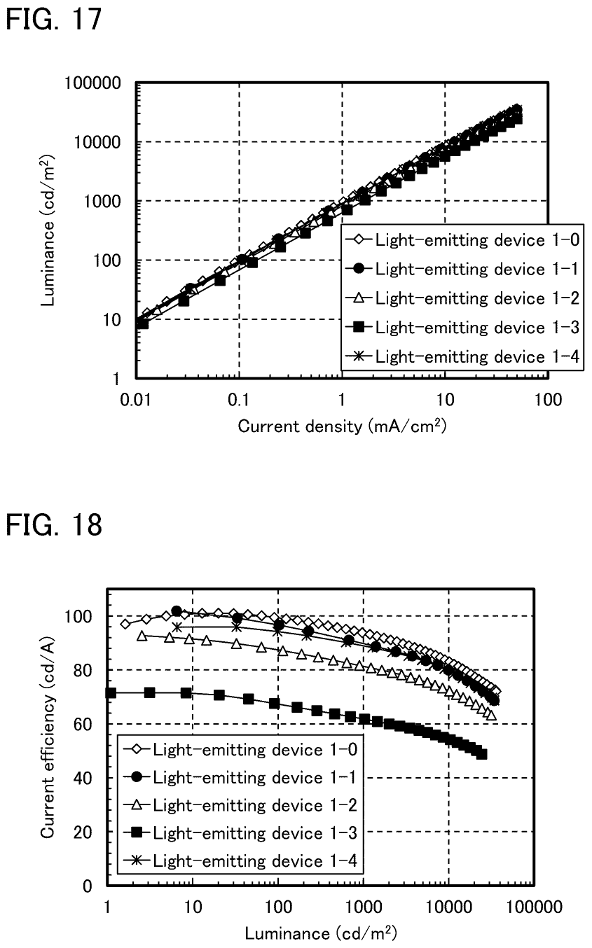

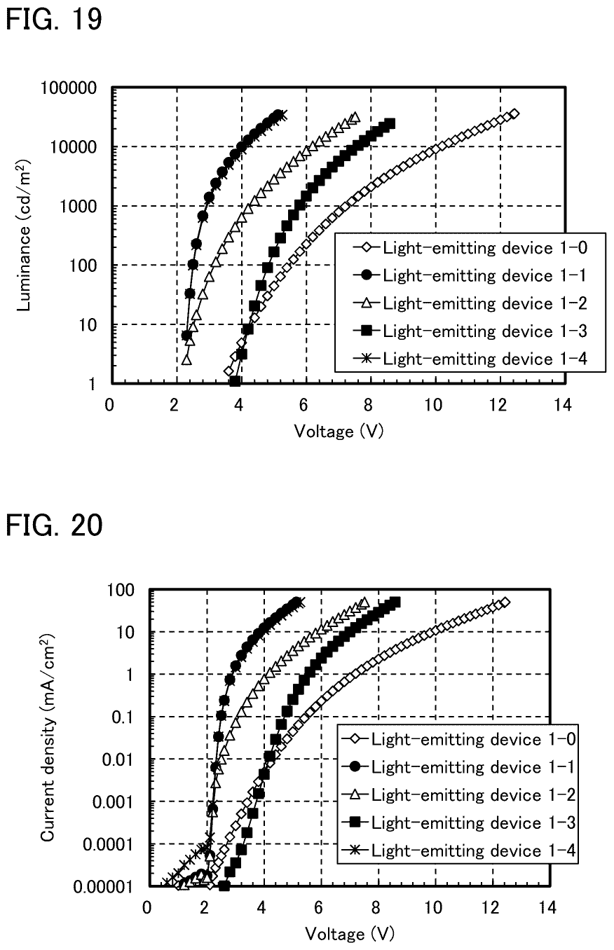

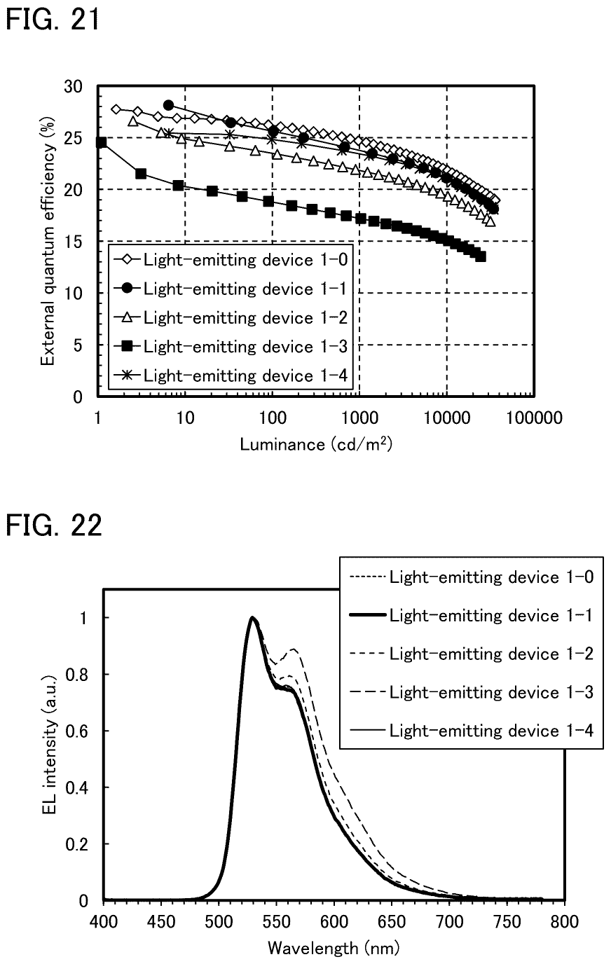

FIG. 17 shows the luminance-current density characteristics of the light-emitting devices 1-0 to 1-4. FIG. 18 shows the current efficiency-luminance characteristics thereof. FIG. 19 shows the luminance-voltage characteristics thereof. FIG. 20 shows the current density-voltage characteristics thereof. FIG. 21 shows the external quantum efficiency-luminance characteristics thereof. FIG. 22 shows the electroluminescence spectra thereof. Table 5 shows main characteristics of the light-emitting devices at luminance of approximately 1000 cd/m². The luminance, CIE chromaticity, and electroluminescence spectra were measured at normal temperature with a spectroradiometer (SR-UL1R produced by TOPCON TECHNOHOUSE CORPORATION). The external quantum efficiency was calculated from the measured luminance and emission spectrum, on the assumption that the light-emitting device had Lambertian light-distribution characteristics.

TABLE 5

| | | | | | | | | External |
|---|---|---|---|---|---|---|---|---|
| | | | Current | Chroma- | Chroma- | Current | Power | quantum |
| | Voltage | Current | density | ticity | ticity | efficiency | efficiency | efficiency |
| | (V) | (mA) | (mA/cm²) | x | y | (cd/A) | (lm/W) | (%) |
| Light- | 7.20 | 0.0413 | 1.03 | 0.372 | 0.606 | 93.8 | 40.9 | 24.7 |
| emitting | | | | | | | | |
| device 1-0 | | | | | | | | |
| Light- | 2.80 | 0.0297 | 0.742 | 0.372 | 0.606 | 91.1 | 102 | 24.1 |
| emitting | | | | | | | | |
| device 1-1 | | | | | | | | |
| Light- | 4.20 | 0.0440 | 1.10 | 0.382 | 0.598 | 81.7 | 61.1 | 21.9 |
| emitting | | | | | | | | |
| device 1-2 | | | | | | | | |
| Light- | 5.80 | 0.0669 | 1.67 | 0.402 | 0.580 | 61.7 | 33.4 | 17.2 |
| emitting | | | | | | | | |
| device 1-3 | | | | | | | | |
| Light- | 3.00 | 0.0580 | 1.45 | 0.372 | 0.606 | 88.3 | 92.4 | 23.3 |
| emitting | | | | | | | | |
| device 1-4 | | | | | | | | |

As described above, the light-emitting device 1-4 is a light-emitting device in which the electron-transport layer has a two-layer structure and the GSP_Slope of the second electron-transport layer on the cathode side is smaller than that of the first electron-transport layer on the anode side. The thickness of the second electron-transport layer of the light-emitting device is 20 nm. Since the GSP_Slope of a light-emitting device with such a structure increases toward the light-emitting layer, electrons can be easily injected as described in Embodiment 1; thus, the light-emitting device has a low driving voltage.

As described above, each of the light-emitting devices 1-1 to 1-3 is a light-emitting device in which the electron-transport layer has a two-layer structure and the GSP_Slope of the second electron-transport layer on the cathode side is larger than that of the first electron-transport layer on the anode side. The light-emitting devices 1-1 to 1-3 differ in the thickness of the second electron-transport layer.

Here, it is found that the driving voltages of the light-emitting devices 1-2 and 1-3 whose thickness of the second electron-transport layer is 10 nm and 20 nm, respectively, are significantly increased. This is because the GSP_Slope of the second electron-transport layer in each of the light-emitting devices 1-2 and 1-3 is larger than the GSP_Slope of the first electron-transport layer and thus injection of electrons from the cathode is difficult.

In contrast, the light-emitting device 1-1 with a thickness of the second electron-transport layer of 5 nm was found to have a low driving voltage like the light-emitting device 1-4 in which the GSP_Slope of the second electron-transport layer on the cathode side is smaller than that of the first electron-transport layer on the anode side, even though in the light-emitting device 1-1, the GSP_Slope of the second electron-transport layer on the cathode side is larger than that of the first electron-transport layer on the anode as in the light-emitting devices 1-2 and 1-3. This is because the thickness of the second electron-transport layer of the light-emitting device 1-1 is small as described in Embodiment 1 and thus carriers generated by the interaction between the material for the cathode and mPPhen2P for the second electron-transport layer cancel negative interface charges generated at the interface between the first electron-transport layer and the second electron-transport layer. Since an organic compound having a low refractive index in film form is used for the first electron-transport layer in the light-emitting device 1-1, the light-emitting device 1-1 exhibits higher current efficiency and higher external quantum efficiency than the light-emitting device 1-4 does. The light-emitting device 1-1 exhibits a low driving voltage and high current efficiency and thus has high power efficiency and is driven with low power consumption.

Note that the light-emitting device 1-0 has a structure in which the second electron-transport layer is not provided, that is, the electron-transport layer has a single-layer structure, and 6F-2TRZ and the cathode are in contact with each other. As can be seen from FIG. 19 and FIG. 20, the driving voltage of the light-emitting device 1-0 is significantly high. This is because 6F-2TRZ has difficulty with electron injection from the cathode. The light-emitting device of one embodiment of the present invention, which is obtained by providing an appropriate second electron-transport layer in such a light-emitting device, can have favorable characteristics.

When the electron-transport layer has a stacked-layer structure in this manner, a material that has difficulty with electron injection in a state of being in direct contact with the cathode can be used for the electron-transport layer. Furthermore, when the thickness of the second electron-transport layer in contact with the cathode is reduced, even in a light-emitting device in which the GSP_Slope of the second electron-transport layer on the cathode side is larger than the GSP_Slope of the first electron-transport layer on the anode side, an increase in driving voltage can be inhibited without being affected by the relation of the GSP_Slopes.

As a result, even an organic compound having an extremely small GSP_Slope in film form, such as 6F-2TRZ, can be used for the electron-transport layer, resulting in a wide range of material choices.

Note that 6F-2TRZ is an organic compound containing fluorine in its molecule. Since the atomic refraction of fluorine is low, the organic compound containing fluorine tends to have a low refractive index in film form. Providing a layer with a low refractive index in a light-emitting device can improve light extraction efficiency and make the light-emitting device have high emission efficiency.

Meanwhile, since fluorine has high electronegativity, an organic compound containing fluorine has an extremely large permanent electric dipole. Furthermore, a substituent bonded with fluorine has a low surface free energy. Accordingly, when a film of the organic compound containing fluorine is formed by a vacuum evaporation method, fluorine groups are likely to be oriented toward the film surface. Owing to the combination of the large electrical dipole and the orientation, the GSP_Slope of the evaporated film formed with the organic compound containing fluorine easily shows an extremely small value. An evaporated film of 6F-2TRZ also exhibits an extremely small GSP_Slope of −108 mV/nm.

Although 6F-2TRZ has a high carrier-transport property, it has been difficult to employ 6F-2TRZ as a material for a light-emitting device because of its poor electron injection property in the case of a single-layer electron transport layer (as shown by the results of the light-emitting device 1-0) and increased driving voltage due to an extremely small GSP_Slope of an evaporated film of 6F-2TRZ in the case of a stacked-layer electron transport layer (as shown by the results of the light-emitting devices 1-2 and 1-3). However, with the use of the structure of one embodiment of the present invention, a light-emitting device using 6F-2TRZ for the electron-transport layer can have a low driving voltage and favorable characteristics.

As described above, with the use of one embodiment of the present invention, materials that have not been adopted due to GSP_Slope mismatch can be utilized, which can greatly expand the range of material choices. As a result, a light-emitting device with a low driving voltage, high emission efficiency, and favorable characteristics can be easily obtained.

### Example 2

Described in this example are specific methods for fabricating a light-emitting device 2a-1, a light-emitting device 2a-2, a light-emitting device 2a-3, a light-emitting device 2a-4, a light-emitting device 2a-5, a light-emitting device 2a-6, a light-emitting device 2a-7, a light-emitting device 2a-8, a light-emitting device 2b-1, a light-emitting device 2b-2, a light-emitting device 2b-3, a light-emitting device 2b-4, and a light-emitting device 2b-5 and characteristics of the light-emitting devices. Structural formulae of main compounds used in this example are shown below.

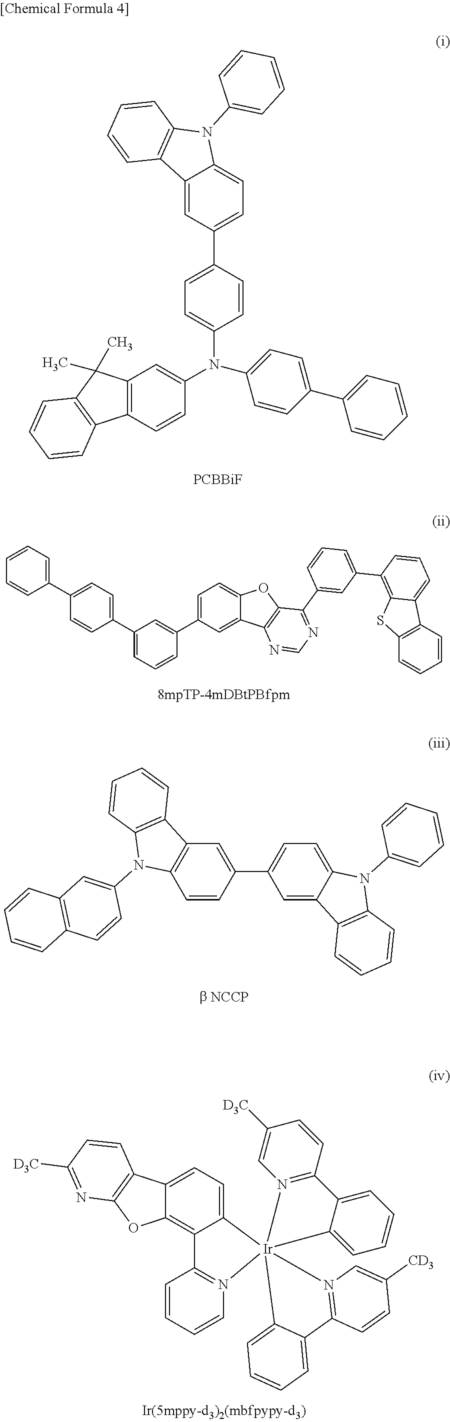

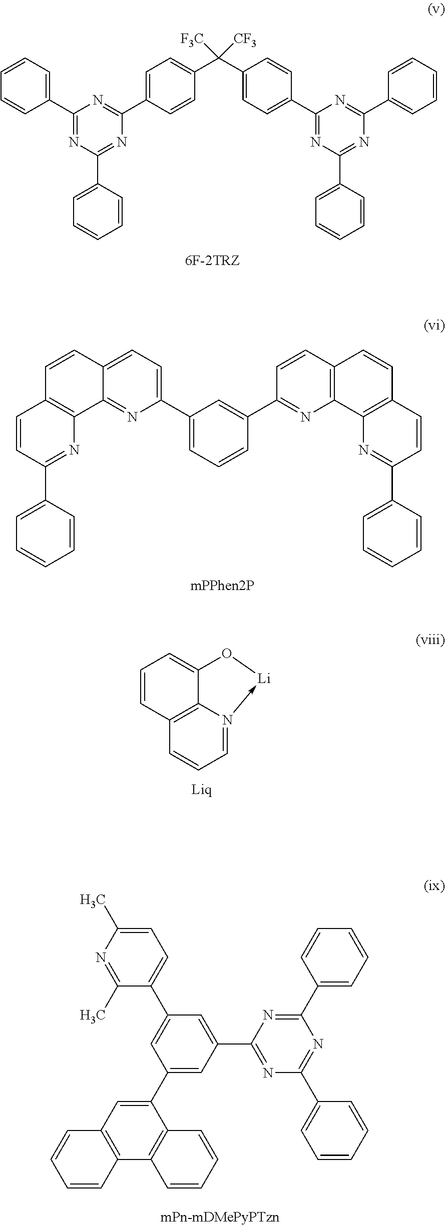

(Fabrication Method of Light-Emitting Devices 2a-1 and 2b-1)

First, indium tin oxide containing silicon oxide (ITSO) was deposited over a glass substrate to a thickness of 70 nm by a sputtering method, so that the first electrode 101 having a size of 2 mm×2 mm was formed. Note that the ITSO serves as an anode.

Then, pretreatment for formation of the light-emitting device over the substrate was performed by washing the substrate surface with water.

After that, the substrate was transferred into a vacuum evaporation apparatus where the internal pressure was reduced to approximately 1×10⁻⁴ Pa, and was subjected to vacuum baking at 170° C. for 30 minutes in a heating chamber of the vacuum evaporation apparatus, and then the substrate was cooled down for approximately 30 minutes.

Next, the substrate provided with the first electrode 101 was fixed to a substrate holder provided in the vacuum evaporation apparatus such that the surface on which the first electrode 101 was formed faced downward. Then, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron-acceptor material with a molecular weight of 672 (OCHD-003) were deposited over the inorganic insulating film and the first electrode 101 to a thickness of 10 nm by co-evaporation such that the weight ratio of PCBBiF to OCHD-003 was 1:0.03, whereby the hole-injection layer 111 was formed.

Over the hole-injection layer 111, PCBBiF was deposited by evaporation to a thickness of 40 nm, whereby the hole-transport layer 112 was formed.

Then, over the hole-transport layer 112, 8-(p-terphenyl-3-yl)-4-[3-(dibenzothiophen-4-yl)phenyl]-[1]benzofuro[3,2-d]pyrimidine (abbreviation: 8mpTP-4mDBtPBfpm) represented by Structural Formula (ii) above, 9-(2-naphthyl)-9′-phenyl-3,3′-bi-9H-carbazole (abbreviation: βNCCP) represented by Structural Formula (iii) above, and [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)) represented by Structural Formula (iv) above were deposited by co-evaporation to a thickness of 40 nm such that the weight ratio of 8mpTP-4mDBtPBfpm to βNCCP to Ir(5mppy-d₃)₂(mbfpypy-d₃) was 0.5:0.5:0.1, whereby the light-emitting layer 113 was formed. The GSP_Slope of the film formed by co-evaporation of 8mpTP-4mDBtPBfpm, βNCCP, and Ir(5mppy-d₃)₂(mbfpypy-d₃) with a weight ratio of 8mpTP-4mDBtPBfpm to βNCCP to Ir(5mppy-d₃)₂(mbfpypy-d₃) of 0.5:0.5:0.1 is 51.5 mV/nm. Note that the GSP_Slope of each of the materials in this example was measured by the method described in Embodiment 1.

After that, 6,6′-[(perfluoropropane-2,2-diyl)bis(4,1-phenylene)]bis(2,4-diphenyl-1,3,5-triazine) (abbreviation: 6F-2TRZ) represented by Structural Formula (v) above was deposited by evaporation to a thickness of 35 nm, whereby the electron-transport layer was formed. The evaporated film of 6F-2TRZ has an extremely small GSP_Slope of −108 mV/nm.

After the electron-transport layer was formed, lithium fluoride (LiF) was deposited by evaporation to a thickness of 1 nm, and then aluminum (Al) was deposited by evaporation to a thickness of 100 nm, whereby the second electrode 102 (cathode) was formed. That is, each of the light-emitting devices 2a-1 and 2b-1 includes an electron-transport layer with a single-layer structure.

Next, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under atmospheric pressure for one hour. In this manner, the light-emitting devices 2a-1 and 2b-1 were fabricated.

(Fabrication Methods of Light-Emitting Devices 2a-2 to 2a-8)

The light-emitting device 2a-2 was fabricated in a manner similar to that of the light-emitting device 2a-1 except that the electron-transport layer in the light-emitting device 2a-2 was formed in the following manner: 6F-2TRZ was deposited by evaporation to a thickness of 35 nm to form the first electron-transport layer, and then 6F-2TRZ and 8-quinolinolato-lithium (abbreviation: Liq) represented by Structural Formula (viii) above were deposited by co-evaporation to a thickness of 1 nm with a weight ratio of 6F-2TRZ to Liq of 1:1 to form the second electron-transport layer.

The thickness of the second electron-transport layer was 3 nm in the light-emitting device 2a-3, 5 nm in the light-emitting device 2a-4, 7 nm in the light-emitting device 2a-5, 10 nm in the light-emitting device 2a-6, 15 nm in the light-emitting device 2a-7, and 20 nm in the light-emitting device 2a-8. Each second electron-transport layer was formed by co-evaporation. The other components were formed in a manner similar to that of the light-emitting device 2a-2.

Note that the GSP_Slope of the film formed by co-evaporation of 6F-2TRZ and Liq was −53.5 mV/nm. That is, each of the light-emitting devices 2a-2 to 2a-8 includes the first electron-transport layer on the anode side and the second electron-transport layer on the cathode side; the first electron-transport layer is in contact with the second electron-transport layer; the second electron-transport layer is in contact with the cathode; the GSP_Slope of an evaporated film of the material included in the second electron-transport layer is larger than the GSP_Slope of an evaporated film of the material included in the first electron-transport layer. In the light-emitting devices 2a-2 to 2a-8, the difference in GSP_Slope between the first electron-transport layer and the second electron-transport layer is larger than or equal to 50 mV/nm.

Furthermore, Liq and 6F-2TRZ, which are included in the second electron-transport layers of the light-emitting devices 2a-2 to 2a-8, are an organic complex of an alkali metal and an organic compound including a π-electron deficient heteroaromatic ring, respectively. In the light-emitting devices 2a-2 to 2a-8, the first electron-transport layer and the second electron-transport layer contain the same organic compound including a π-electron deficient heteroaromatic ring, and the second electron-transport layer contains an organic complex of an alkali metal.

(Fabrication Methods of Light-Emitting Devices 2b-2 to 2b-5)

The light-emitting device 2b-2 was fabricated in a manner similar to that of the light-emitting device 2b-1 except that the electron-transport layer in the light-emitting device 2b-2 was formed in the following manner: after the first electron-transport layer was formed to a thickness of 35 nm by evaporation of 6F-2TRZ, the second electron-transport layer was formed to a thickness of 5 nm by co-evaporation of 2-[3-(2,6-dimethyl-3-pyridinyl)-5-(9-phenanthryl)phenyl]-4,6-diphenyl-1,3,5-triazine (abbreviation: mPn-mDMePyPTzn) represented by Structural Formula (ix) above and Liq with a weight ratio of mPn-mDMePyPTzn to Liq of 1:1.

The light-emitting devices 2b-3, 2b-4, and 2b-5 were fabricated in a manner similar to that of the light-emitting device 2b-2 except that the second electron-transport layers were formed to have thicknesses of 10 nm, 15 nm, and 20 nm in the light-emitting devices 2b-3, 2b-4, and 2b-5, respectively.

Note that the GSP_Slope of the film formed by co-evaporation of mPn-mDMePyPTzn and Liq was 14.3 mV/nm. That is, each of the light-emitting devices 2b-2 to 2b-5 includes the first electron-transport layer on the anode side and the second electron-transport layer on the cathode side; the first electron-transport layer is in contact with the second electron-transport layer; the second electron-transport layer is in contact with the cathode; the GSP_Slope of an evaporated film of the material included in the second electron-transport layer is larger than the GSP_Slope of an evaporated film of the material included in the first electron-transport layer. In the light-emitting devices 2b-2 to 2b-5, the difference in GSP_Slope between the first electron-transport layer and the second electron-transport layer is larger than or equal to 50 mV/nm.

Furthermore, Liq and mPn-mDMePyPTzn, which are included in the second electron-transport layers of the light-emitting devices 2b-2 to 2b-5, are an organic complex of an alkali metal and an organic compound including a π-electron deficient heteroaromatic ring, respectively.

Device structures of the light-emitting devices 2a-1 to 2a-8 and the light-emitting devices 2b-1 to 2b-5 are shown in the table below.

TABLE 6

| | | Thickness | | |
|---|---|---|---|---|
| | | (nm) | Light-emitting device 2a-X | Light-emitting device 2b-Y |
| Second electrode | | 100 | Al | |
| | | 1 | LiF | |
| Electron-transport | 2 | *3 | 6F-2TRZ:Liq | mPn-mDMePyPTzn:Liq |
| layer | | | (1:1) | (1:1) |

| | | |
|---|---|---|
| 1 | 35 | 6F-2TRZ |

| | | |
|---|---|---|
| Light-emitting layer | 40 | 8mpTP-4mDBtPBfpm:βNCCP:Ir(5mppy-d₃)₂(mbfpypy-d₃) |
| | | (0.5:0.5:0.1) |
| Hole-transport layer | 40 | PCBBiF |
| Hole-injection layer | 10 | PCBBiF:OCHD-003 (1:0.03) |
| First electrode | 70 | ITSO |

X = 1 to 8,
Y = 1 to 5

TABLE 7

| Light-emitting device | | *3 | |
|---|---|---|---|
| X = 1 | Y = 1 | 0 | nm |
| X = 2 | — | 1 | nm |
| X = 3 | — | 3 | nm |
| X = 4 | Y = 2 | 5 | nm |
| X = 5 | — | 7 | nm |
| X = 6 | Y = 3 | 10 | nm |
| X = 7 | Y = 4 | 15 | nm |
| X = 8 | Y = 5 | 20 | nm |

Table 8 shows main characteristics of the light-emitting devices at luminance of approximately 1000 cd/m². The luminance, CIE chromaticity, and electroluminescence spectra were measured at normal temperature with a spectroradiometer (SR-UL1R produced by TOPCON TECHNOHOUSE CORPORATION). The external quantum efficiency was calculated from the measured luminance and emission spectrum, on the assumption that the light-emitting device had Lambertian light-distribution characteristics.

TABLE 8

| | | | | | | | | External |
|---|---|---|---|---|---|---|---|---|
| | | | | Current | Chroma- | Chroma- | Current | quantum |
| | | Voltage | Current | density | ticity | ticity | efficiency | efficiency |
| | | (V) | (mA) | (mA/cm²) | x | y | (cd/A) | (%) |
| Light- | X = 1 | 5.80 | 0.0399 | 0.998 | 0.333 | 0.637 | 106 | 27.4 |
| emitting | X = 2 | 3.80 | 0.0421 | 1.05 | 0.335 | 0.635 | 107 | 27.7 |
| device 2a-X | X = 3 | 2.80 | 0.0385 | 0.964 | 0.337 | 0.634 | 108 | 27.8 |
| | X = 4 | 2.80 | 0.0449 | 1.12 | 0.340 | 0.632 | 108 | 27.9 |
| | X = 5 | 2.80 | 0.0435 | 1.09 | 0.341 | 0.630 | 108 | 27.8 |
| | X = 6 | 4.20 | 0.0378 | 0.945 | 0.350 | 0.624 | 107 | 27.7 |
| | X = 7 | 4.20 | 0.0373 | 0.932 | 0.357 | 0.618 | 104 | 27.0 |
| | X = 8 | 4.20 | 0.0324 | 0.810 | 0.366 | 0.611 | 90.3 | 23.6 |
| Light- | Y = 1 | 5.80 | 0.0399 | 0.998 | 0.333 | 0.637 | 106 | 27.4 |
| emitting | Y = 2 | 2.90 | 0.0395 | 0.987 | 0.337 | 0.634 | 105 | 27.2 |
| device 2b-Y | Y = 3 | 5.00 | 0.0349 | 0.872 | 0.346 | 0.627 | 108 | 28.0 |
| | Y = 4 | 5.40 | 0.0607 | 1.52 | 0.354 | 0.621 | 66.1 | 17.2 |
| | Y = 5 | 5.60 | 0.129 | 3.24 | 0.363 | 0.613 | 24.6 | 6.43 |

The tables show that the light-emitting devices 2a-2 to 2a-5 and 2b-2 in which the thickness of the second electron-transport layer is in the range of 1 nm to 7 nm have a low driving voltage and favorable characteristics. In contrast, it was found that the light-emitting devices 2a-1, 2a-6 to 2a-8, 2b-1, and 2b-3 to 2b-5 in which the thickness of the second electron-transport layer is 0 nm or greater than or equal to 10 nm have a high driving voltage.

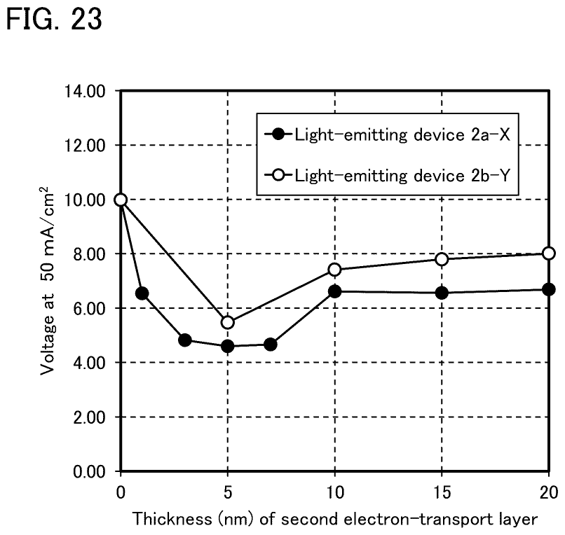

FIG. 23 is a graph showing the relation between a voltage at 50 mA/cm² and the thickness of the second electron-transport layer of each of the above light-emitting devices. FIG. 23 also shows that the light-emitting devices 2a-2 to 2a-5 and 2b-2 each have a low driving voltage and favorable characteristics, and the light-emitting devices 2a-1, 2a-6 to 2a-8, 2b-1, and 2b-3 to 2b-5 each have a high driving voltage.

In each of the light-emitting devices 2a-1 and 2b-1, the second electron-transport layer is not provided and the electron-transport layer has a single-layer structure, and 6F-2TRZ included in the electron-transport layer is in contact with the cathode. The voltage at 50 mA/cm² of each of the light-emitting devices 2a-1 and 2b-1 is extremely high, 9.98 V because it is difficult to directly inject electrons from the cathode into 6F-2TRZ included in the electron-transport layer.

In the light-emitting devices 2a-2 to 2a-8 and 2b-2 to 2b-5, the electron-transport layer has a two-layer structure. When the electron-transport layer has a two-layer structure and a layer that facilitates direct electron injection from the cathode is used as a layer that is closer to the cathode, a material that has difficulty with direct injection of electrons from the cathode, such as 6F-2TRZ, can be used as a material included in the electron-transport layer.

In the light-emitting devices 2a-2 to 2a-8, the electron-transport layer on the cathode side (the second electron-transport layer) is a mixed film of 6F-2TRZ and Liq. In the light-emitting devices 2b-2 to 2b-5, the second electron-transport layer is a mixed film of mPn-mDMePyPTzn and Liq. When a mixed film of the organic compound including a π-electron deficient heteroaromatic ring and the organic complex of an alkali metal is used as the second electron-transport layer, electrons can be easily injected from the cathode; thus, even with use of 6F-2TRZ, a light-emitting device with a suppressed increase in driving voltage can be obtained. Note that the second electron-transport layer in each of the light-emitting devices 2a-2 to 2a-8 is formed by adding Liq to 6F-2TRZ included in the first electron-transport layer, so that the material can be shared and thus the productivity can be improved.

Here, the GSP_Slope of the co-evaporated film of 6F-2TRZ and Liq with a weight ratio of 6F-2TRZ to Liq of 1:1 is −53.5 mV/nm, and the GSP_Slope of the co-evaporated film of mPn-mDMePyPTzn and Liq with a weight ratio of mPn-mDMePyPTzn to Liq of 1:1 is 14.3 mV/nm. Since the GSP_Slope of 6F-2TRZ is −108 mV/nm, the light-emitting devices 2a-2 to 2a-8 and 2b-2 to 2b-5 have a structure in which the GSP_Slope of the second electron-transport layer is larger than that of the first electron-transport layer. In the light-emitting device having a structure in which the GSP_Slope of the second electron-transport layer is larger than that of the first electron-transport layer, electron injection is inhibited by the influence of negative interface charges, and thus the driving voltage is increased in some cases.

Table 8 and FIG. 23 show that the light-emitting devices 2a-6 to 2a-8 and 2b-3 to 2b-5 have high driving voltages. This is a result of inhibition of electron injection due to the influence of negative interface charges owing to the structure in which the GSP_Slope of the second electron-transport layer is larger than that of that of the first electron-transport layer.

In contrast, the driving voltages of the light-emitting devices 2a-2 to 2a-5 and 2b-2 are low. This is because the thickness of the second electron-transport layer in each of the light-emitting devices 2a-2 to 2a-5 and 2b-2 is less than 10 nm and thus carriers generated by the interaction between the material for the cathode and Liq were diffused and transferred to the interface between the first electron-transport layer and the second electron-transport layer, so that the negative interface charges were canceled by the carriers, whereby electrons were easily injected from the cathode. As described above, negative interface charges that would inhibit electron injection from the cathode to the EL layer can be eliminated by carriers generated by the interaction between the material for the cathode and Liq; accordingly, the light-emitting devices 2a-2 to 2a-5 and 2b-2 were able to have low driving voltages.

In consideration of the diffusion distance of carriers generated by the interaction between the material for the cathode and Liq, the thickness of the second electron-transport layer is preferably less than 10 nm in consideration of the diffusion distance of carriers generated by the interaction between the cathode and Liq, further preferably less than or equal to 7 nm, in which case the driving voltage can be reduced. The thickness of the second electron-transport layer is preferably greater than 0 nm, further preferably greater than 1 nm, still further preferably greater than or equal to 3 nm, in which case the driving voltage can be further reduced. That is, it is particularly preferable that the thickness of the second electron-transport layer be greater than or equal to 3 nm and less than or equal to 7 nm.

When the electron-transport layer has a stacked-layer structure in this manner, a material that has difficulty with electron injection in a state of being in direct contact with the cathode can be used for the electron-transport layer. Furthermore, when the thickness of the second electron-transport layer in contact with the cathode is reduced, even in a light-emitting device in which the GSP_Slope of the second electron-transport layer on the cathode side is larger than the GSP_Slope of the first electron-transport layer on the anode side, an increase in driving voltage can be inhibited without being affected by the relation of the GSP_Slopes.

As a result, even an organic compound having an extremely small GSP_Slope in film form, such as 6F-2TRZ, can be used for the electron-transport layer, resulting in a wide range of material choices.

Note that 6F-2TRZ is an organic compound containing fluorine in its molecule. Since the atomic refraction of fluorine is low, the organic compound containing fluorine tends to have a low refractive index in film form. Providing a layer with a low refractive index in a light-emitting device can improve light extraction efficiency and make the light-emitting device have high emission efficiency.

Meanwhile, since fluorine has high electronegativity, an organic compound containing fluorine has an extremely large permanent electric dipole. Furthermore, a substituent bonded with fluorine has a low surface free energy. Accordingly, when a film of the organic compound containing fluorine is formed by a vacuum evaporation method, fluorine groups are likely to be oriented toward the film surface. Owing to the combination of the large electrical dipole and the orientation, the GSP_Slope of the evaporated film formed with the organic compound containing fluorine easily shows an extremely small value. An evaporated film of 6F-2TRZ also exhibits an extremely small GSP_Slope of −108 mV/nm.

Although 6F-2TRZ has a high carrier-transport property, it has been difficult to employ 6F-2TRZ as a material for a light-emitting device because of its poor electron injection property in the case of a single-layer electron transport layer (as shown by the results of the light-emitting device 1-0) and increased driving voltage due to an extremely small GSP_Slope of an evaporated film of 6F-2TRZ in the case of a stacked-layer electron transport layer (as shown by the results of the light-emitting devices 1-2 and 1-3). However, with the use of the structure of one embodiment of the present invention, a light-emitting device using 6F-2TRZ for the electron-transport layer can have a low driving voltage and favorable characteristics. However, with the use of the structure of one embodiment of the present invention for the electron-transport layer, the light-emitting device with a low driving voltage and favorable characteristics was able to be obtained.

As described above, with the use of one embodiment of the present invention, materials that have not been adopted due to GSP_Slope mismatch can be utilized, which can greatly expand the range of material choices. As a result, a light-emitting device with a low driving voltage, high emission efficiency, and favorable characteristics can be easily obtained. The thickness of the second electron-transport layer is preferably less than 10 nm, further preferably less than or equal to 7 nm, in which case the driving voltage can be reduced. The thickness of the second electron-transport layer is preferably greater than 0 nm, further preferably greater than 1 nm, still further preferably greater than or equal to 3 nm, in which case the driving voltage can be further reduced. That is, it is particularly preferable that the thickness of the second electron-transport layer be greater than or equal to 3 nm and less than or equal to 7 nm.

### Example 3

Described in this example are specific methods for fabricating a light-emitting device 3-1, a light-emitting device 3-2, and a light-emitting device 3-3 and characteristics of the light-emitting devices. Structural formulae of main compounds used in this example are shown below.

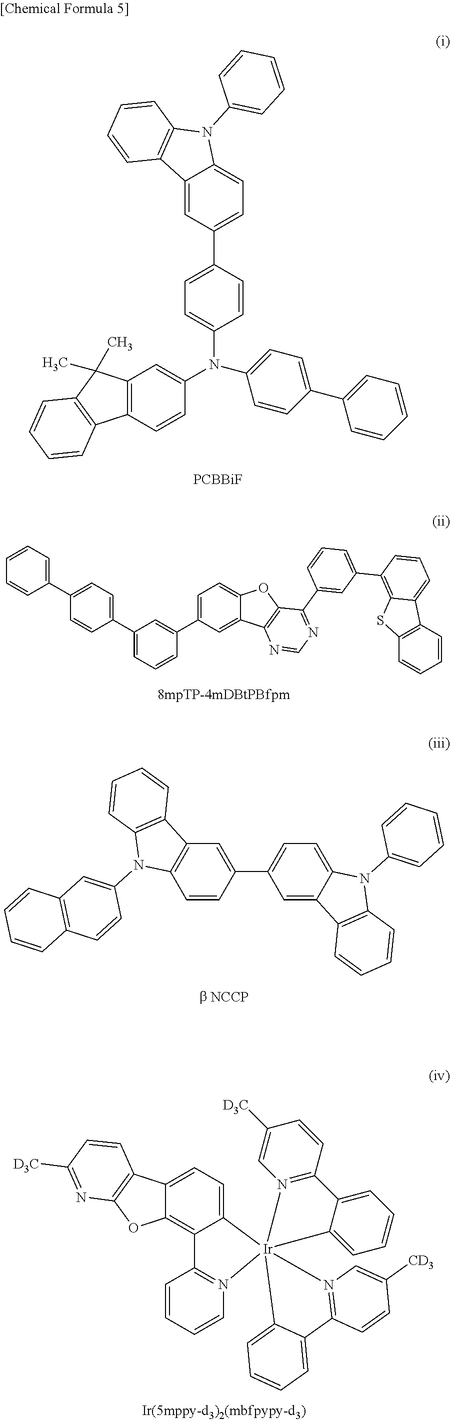

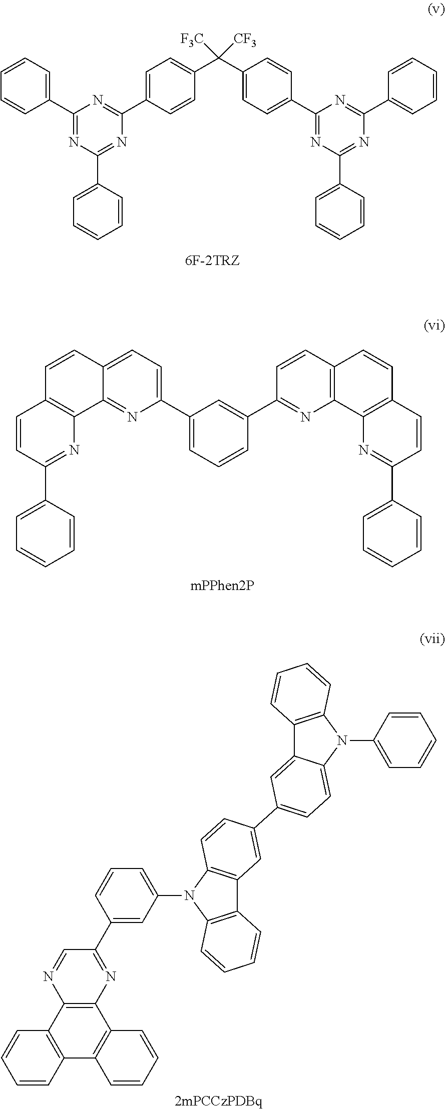 [SMILES: FC(F)(F)C(c1ccc(-c2nc(-c3ccccc3)nc(-c3ccccc3)n2)cc1)(c1ccc(-c2nc(-c3ccccc3)nc(-c3ccccc3)n2)cc1)C(F)(F)F ; c1ccc(-c2ccc3ccc4ccc(-c5cccc(-c6ccc7ccc8ccc(-c9ccccc9)nc8c7n6)c5)nc4c3n2)cc1 ; c1ccc(-n2c3ccccc3c3cc(-c4ccc5c(c4)c4ccccc4n5-c4cccc(-c5cnc6c7ccccc7c7ccccc7c6n5)c4)ccc32)cc1]

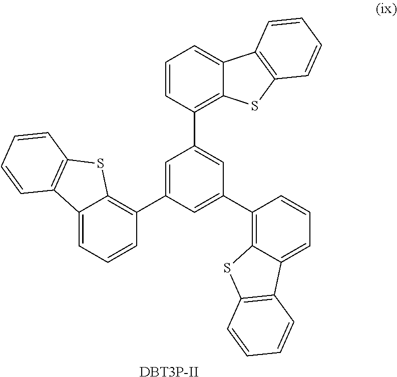 [SMILES: c1ccc2c(c1)sc1c(-c3cc(-c4cccc5c4sc4ccccc45)cc(-c4cccc5c4sc4ccccc45)c3)cccc12 ; "DBT3P-II"]

### (Fabrication Method of Light-Emitting Device 3-1)

First, silver (Ag) was deposited over a glass substrate to a thickness of 100 nm by a sputtering method, and then indium tin oxide including silicon oxide (ITSO) was deposited thereover to a thickness of 85 nm by a sputtering method, so that the first electrode 101 having a size of 2 mm×2 mm was formed. Note that the ITSO serves as an anode.

Then, pretreatment for formation of the light-emitting device over the substrate was performed by washing the substrate surface with water.

After that, the substrate was transferred into a vacuum evaporation apparatus where the internal pressure was reduced to approximately 1×10 Pa, and was subjected to vacuum baking at 170° C. for 30 minutes in a heating chamber of the vacuum evaporation apparatus, and then the substrate was cooled down for approximately 30 minutes.

Next, the substrate provided with the first electrode 101 was fixed to a substrate holder provided in the vacuum evaporation apparatus such that the surface on which the first electrode 101 was formed faced downward. Then, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron-acceptor material with a molecular weight of 672 (OCHD-003) were deposited over the inorganic insulating film and the first electrode 101 to a thickness of 10 nm by co-evaporation such that the weight ratio of PCBBiF to OCHD-003 was 1:0.03, whereby the hole-injection layer 111 was formed.

Over the hole-injection layer 111, PCBBiF was deposited by evaporation to a thickness of 60 nm, whereby the hole-transport layer 112 was formed.

Then, over the hole-transport layer 112, 8-(p-terphenyl-3-yl)-4-[3-(dibenzothiophen-4-yl)phenyl]-[1]benzofuro[3,2-d]pyrimidine (abbreviation: 8mpTP-4mDBtPBfpm) represented by Structural Formula (ii) above, 9-(2-naphthyl)-9′-phenyl-3,3′-bi-9H-carbazole (abbreviation: QNCCP) represented by Structural Formula (iii) above, and [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)) represented by Structural Formula (iv) above were deposited by co-evaporation to a thickness of 40 nm such that the weight ratio of 8mpTP-4mDBtPBfpm to βNCCP to Ir(5mppy-d₃)₂(mbfpypy-d₃) was 0.5:0.5:0.1, whereby the light-emitting layer 113 was formed. The GSP_Slope of the film formed by co-evaporation of 8mpTP-4mDBtPBfpm, βNCCP, and Ir(5mppy-d₃)₂(mbfpypy-d₃) with a weight ratio of 8mpTP-4mDBtPBfpm to βNCCP to Ir(5mppy-d₃)₂(mbfpypy-d₃) of 0.5:0.5:0.1 is 51.5 mV/nm. Note that the GSP_Slope of each of the materials in this example was measured by the method described in Embodiment 1.

After that, 6,6′-[(perfluoropropane-2,2-diyl)bis(4,1-phenylene)]bis(2,4-diphenyl-1,3,5-triazine) (abbreviation: 6F-2TRZ) represented by Structural Formula (v) above was deposited by evaporation to a thickness of 40 nm to form the first electron-transport layer, and then 2,2′-(1,3-phenylene)bis(9-phenyl-1,10-phenanthroline) (abbreviation: mPPhen2P) represented by Structural Formula (vi) above was deposited by evaporation to a thickness of 5 nm to form the second electron-transport layer, whereby the electron-transport layer was formed. The evaporated film of 6F-2TRZ has an extremely small GSP_Slope of −108 mV/nm, and the evaporated film of mPPhen2P has a GSP_Slope of 1.50 mV/nm.

After the formation of the electron-transport layer, lithium fluoride (LiF) and ytterbium (Yb) were deposited by co-evaporation to a thickness of 1.5 nm such that the volume ratio of LiF to Yb was 1:0.5, and then silver (Ag) and magnesium (Mg) were deposited by co-evaporation to a thickness of 15 nm such that the volume ratio of Ag to Mg was 1:0.1, whereby the second electrode 102 (cathode) was formed. Over the second electrode 102, 4,4′,4″-(benzene-1,3,5-triyl)tri(dibenzothiophene) (abbreviation: DBT3P-II) represented by Structural Formula (ix) above was deposited by evaporation to a thickness of 70 nm, whereby a cap layer was formed.

Next, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under atmospheric pressure for one hour. In this manner, the light-emitting device 3-1 was fabricated.

That is, the light-emitting device 3-1 includes the first electron-transport layer on the anode side and the second electron-transport layer on the cathode side; the first electron-transport layer is in contact with the second electron-transport layer; the second electron-transport layer is in contact with the cathode; the GSP_Slope of an evaporated film of the material included in the second electron-transport layer is larger than the GSP_Slope of an evaporated film of the material included in the first electron-transport layer; and the thickness of the second electron-transport layer is 5 nm. Note that the difference in GSP_Slope between the first electron-transport layer and the second electron-transport layer is larger than or equal to 100 mV/nm, and mPPhen2P included in the second electron-transport layer is an organic compound including a pyridine ring and having an acid dissociation constant pKₐ greater than 3. The pKₐ of mPPhen2P is 5.16.

### (Fabrication Method of Light-Emitting Device 3-2)

The light-emitting device 3-2 was fabricated in a manner similar to that of the light-emitting device 3-1 except that 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (vii) above was used for the first electron-transport layer in the light-emitting device 3-2. Note that the GSP_Slope of the evaporated film of 2mPCCzPDBq was 12.4 mV/nm, and the GSP_Slope of the evaporated film of mPPhen2P was 1.50 mV/nm.

That is, the light-emitting device 3-2 includes the first electron-transport layer on the anode side and the second electron-transport layer on the cathode side; the first electron-transport layer is in contact with the second electron-transport layer; the second electron-transport layer is in contact with the cathode; the GSP_Slope of an evaporated film of the material included in the second electron-transport layer is smaller than the GSP_Slope of an evaporated film of the material included in the first electron-transport layer; and the thickness of the second electron-transport layer is 5 nm.

### (Fabrication Method of Light-Emitting Device 3-3)

The light-emitting device 3-3 was fabricated in a manner similar to that of the light-emitting device 3-2 except that the thickness of the first electron-transport layer was 20 nm and the thickness of the second electron-transport layer was 20 nm.

That is, the light-emitting device 3-3 includes the first electron-transport layer on the anode side and the second electron-transport layer on the cathode side; the first electron-transport layer is in contact with the second electron-transport layer; the second electron-transport layer is in contact with the cathode; the GSP_Slope of an evaporated film of the material included in the second electron-transport layer is larger than the GSP_Slope of an evaporated film of the material included in the first electron-transport layer; and the thickness of the second electron-transport layer is 20 nm.

The device structures of the light-emitting devices 3-1 to 3-3 are shown in the tables below.

TABLE 9

| | | | |
|---|---|---|---|
| Thickness | Light-emitting | Light-emitting | Light-emitting |
| (nm) | device 3-1 | device 3-2 | device 3-3 |

| Cap layer | | 70 | DBT3P-II | |
|---|---|---|---|---|
| Second electrode | | 15 | Ag:Mg(1:0.1) | |
| | | 1.5 | LiF:Yb | |
| Electron-transport | 2 | *5 | mPPhen2P | |
| layer | 1 | *4 | 6F-2TRZ | 2mPCCzPDBq |

| | | |
|---|---|---|
| Light-emitting layer | 40 | 8mpTP-4mDBtPBfpm:βNCCP:Ir(5mppy-d₃)₂(mbfpypy-d₃) |
| | | (0.5:0.5:0.1) |
| Hole-transport layer | 60 | PCBBiF |
| Hole-injection layer | 10 | PCBBiF: OCHD-003 (1:0.03) |
| First electrode | 85 | ITSO |
| | 100 | Ag |

*4 Light-emitting devices 3-1 and 3-2: 35 nm, Light emitting device 3-3: 20 nm
*5 Light-emitting devices 3-1 and 3-2: 5 nm, Light-emitting device 3-3: 20 nm

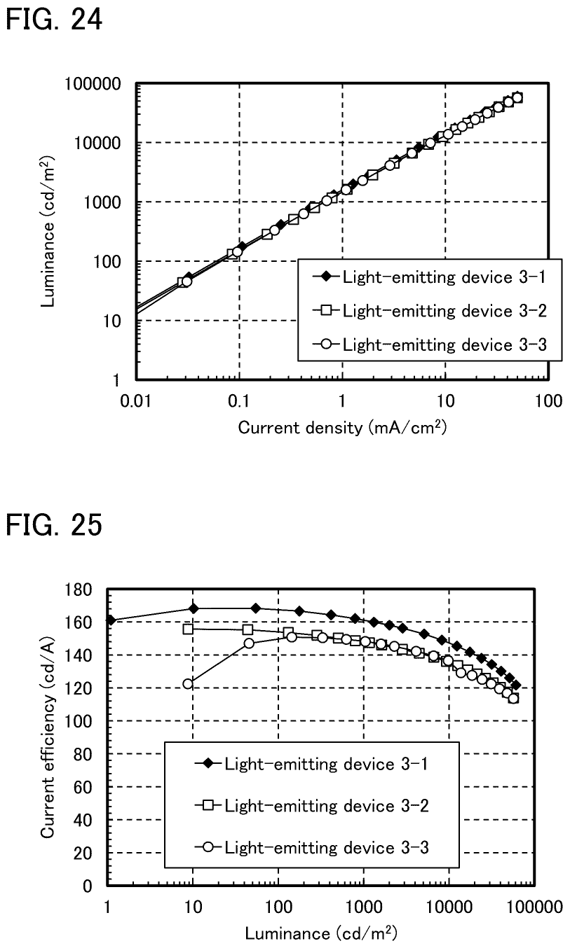

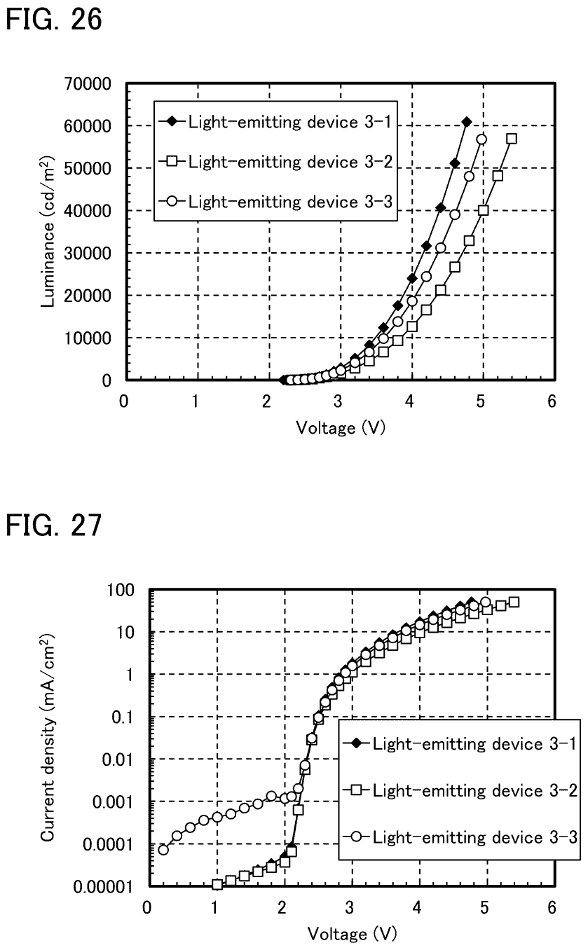

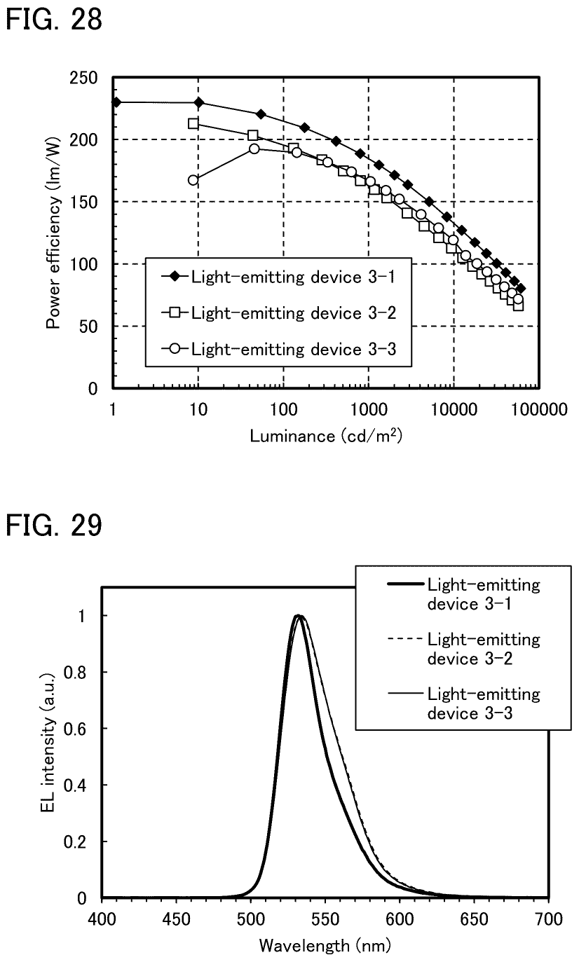

FIG. 24 shows the luminance-current density characteristics of the light-emitting devices 3-1 to 3-3. FIG. 25 shows the current efficiency-luminance characteristics thereof. FIG. 26 shows the luminance-voltage characteristics thereof. FIG. 27 shows the current density-voltage characteristics thereof. FIG. 28 shows the power efficiency-luminance characteristics thereof. FIG. 29 shows the electroluminescence spectra thereof. Table 10 shows main characteristics of the light-emitting devices at luminance of approximately 1000 cd/m². The luminance, CIE chromaticity, and electroluminescence spectra were measured at normal temperature with a spectroradiometer (SR-UL1R produced by TOPCON TECHNOHOUSE CORPORATION).

The external quantum efficiency was calculated from the measured luminance and emission spectrum, on the assumption that the light-emitting device had Lambertian light-distribution characteristics.

TABLE 10

| | | | | | | | | External |
|---|---|---|---|---|---|---|---|---|
| | | | Current | Chroma- | Chroma- | Current | Power | quantum |
| | Voltage | Current | density | ticity | ticity | efficiency | efficiency | efficiency |
| | (V) | (mA) | (mA/cm²) | x | y | (cd/A) | (lm/W) | (%) |
| Light- | 2.70 | 0.0196 | 0.490 | 0.268 | 0.701 | 162 | 189 | 38.0 |
| emitting | | | | | | | | |
| device 3-1 | | | | | | | | |
| Light- | 2.90 | 0.0317 | 0.793 | 0.295 | 0.680 | 147 | 160 | 34.3 |
| emitting | | | | | | | | |
| device 3-2 | | | | | | | | |
| Light- | 2.80 | 0.0282 | 0.706 | 0.293 | 0.682 | 148 | 166 | 34.4 |
| emitting | | | | | | | | |
| device 3-3 | | | | | | | | |

In the light-emitting device 3-1, the GSP_Slope of the second electron-transport layer is larger than that of the first electron-transport layer. In the light-emitting devices 3-2 and 3-3, the GSP_Slope of the second electron-transport layer is smaller than that of the first electron-transport layer.

In a light-emitting device in which the GSP_Slope of the second electron-transport layer is larger than that of the first electron-transport layer, negative interface charges are accumulated in the vicinity of the interface between the first electron-transport layer and the second electron-transport layer, which might cause an increase in driving voltage. However, in the light-emitting device 3-1 of one embodiment of the present invention, the thickness of the second electron-transport layer is as small as 5 nm; thus, carriers generated by the interaction between the electrode and mPPhen2P included in the second electron-transport layer are diffused to cancel the interface charges, so that an increase in driving voltage can be suppressed.

In each of the light-emitting devices 3-2 and 3-3, the GSP_Slope of the second electron-transport layer is smaller than that of the first electron-transport layer. In the light-emitting device having such a structure, electrons are easily injected from the cathode owing to interface charges accumulated in the vicinity of the interface between the first electron-transport layer and the second electron-transport layer; thus, the light-emitting device can have a low driving voltage.

Here, FIG. 26 shows that the driving voltage of the light-emitting device 3-1 is lower than that of each of the light-emitting devices 3-2 and 3-3. This is because 6F-2TRZ has a high electron-transport property. Note that the reason why the light-emitting device 3-2 has a higher driving voltage than the light-emitting device 3-1 is because the first electron-transport layer of the light-emitting device 3-2 has a larger thickness than that of the light-emitting device 3-1.

The light-emitting devices 3-1 to 3-3 each exhibited green light emission with a peak wavelength of electroluminescence spectrum of 533 nm. FIG. 25 and FIG. 28 show that the current efficiency and the power efficiency of the light-emitting device 3-1 are higher than those of the light-emitting devices 3-2 and 3-3. This is because the refractive index of the film of 6F-2TRZ is low. Note that the ordinary refractive index of the film of 6F-2TRZ at a wavelength of 533 nm is 1.68, the ordinary refractive index of the film of 2mPCCzPDBq at a wavelength of 533 nm is 1.92, and the ordinary refractive index of the film of mPPhen2P at a wavelength of 533 nm is 1.84. Thus, in the light-emitting device 3-1, the refractive index of the film of the material included in the first electron-transport layer is lower than that of the film of the material included in the second electron-transport layer. The ordinary refractive index of the film of 8mpTP-4mDBtPBfpm at a wavelength of 533 nm is 1.85, the ordinary refractive index of the film of QNCCP at a wavelength of 533 nm is 1.85, and the ordinary refractive index of the film of Ir(5mppy-d₃)₂(mbfpypy-d₃) at a wavelength of 533 nm is 1.85. Thus, in the light-emitting device 3-1, the refractive index of the film of the material included in the first electron-transport layer is lower than that of the film of the material included in the light-emitting layer. Note that the refractive indices of the films were measured with a spectroscopic ellipsometer (M-2000U manufactured by J.A. Woollam Japan Corp.).

As described above, since 6F-2TRZ is an organic compound having a high electron-transport property and a low refractive index in film form, the use of 6F-2TRZ is expected to enable the light-emitting device to have favorable characteristics. On the other hand, since 6F-2TRZ has difficulty with electron injection from a cathode and the GSP_Slope of the evaporated film of 6F-2TRZ is −108 mV/nm, which is extremely small, the use of 6F-2TRZ for an electron-transport layer in a light-emitting device having a conventional structure degrades the driving voltage characteristics.

However, when 6F-2TRZ is used for the first electron-transport layer of the light-emitting device having the structure of the present invention, as in the light-emitting device 3-1 of one embodiment of the present invention, the light-emitting device can have advantages due to the excellent characteristics of 6F-2TRZ, such as a high electron-transport property and a low refractive index in film form, while suppressing an increase in driving voltage.

Since 6F-2TRZ has a high electron-transport property, the driving voltage is not significantly increased even when the first electron-transport layer is made thick. That is, a layer of 6F-2TRZ with a low refractive index in film form can be formed thick. Accordingly, a light-emitting device with higher emission efficiency can be provided.

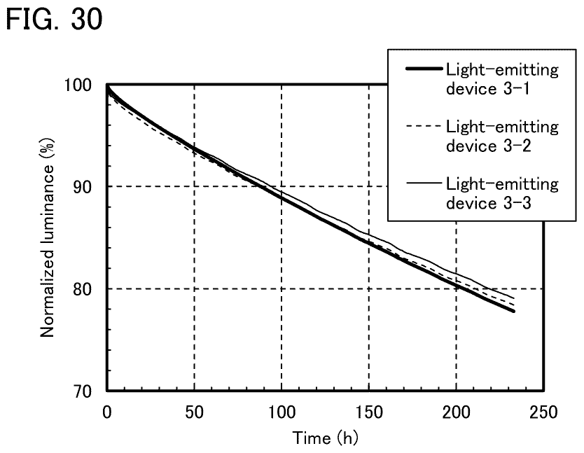

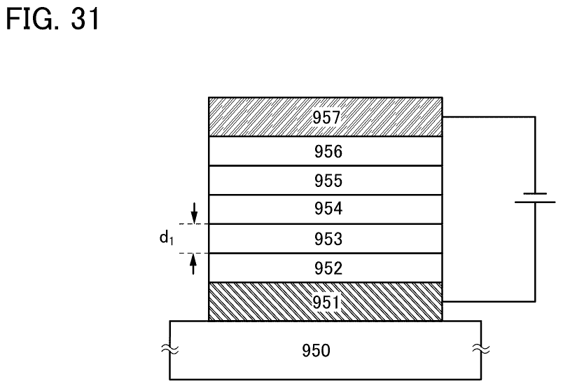

FIG. 30 is a graph showing a change in luminance over driving time at a current density of 50 mA/cm² when the initial luminance is 100%. FIG. 30 shows that the light-emitting devices 3-1 to 3-3 all have high reliability.

As described above, the use of one embodiment of the present invention enables materials that have excellent characteristics as a material included in an electron-transport layer of a light-emitting device but have not been adopted due to GSP_Slope mismatch with another layer to be used. That is, the use of one embodiment of the present invention can greatly expand the range of choices of materials for a light-emitting device.

This application is based on Japanese Patent Application Serial No. 2025-036779 filed with Japan Patent Office on Mar. 7, 2025, the entire contents of which are hereby incorporated by reference.

What is claimed is:

1. A light-emitting device comprising:
an anode over an insulating surface;
a cathode opposite to the anode; and
a first electron-transport layer and a second electron-transport layer which are between the anode and the cathode,
wherein the first electron-transport layer and the second electron-transport layer are in contact with each other,
wherein the second electron-transport layer and the cathode are in contact with each other, wherein a GSP_Slope (mV/nm) of an evaporated film of a material included in the first electron-transport layer is smaller than 0 mV/nm,
wherein a thickness of the second electron-transport layer is greater than 0 nm and less than 10 nm, and
wherein the GSP_Slope (mV/nm) is represented by ΔV/Δd, where ΔV (mV) is an amount of change in a surface potential with respect to an amount of change in a thickness Δd (nm).

2. The light-emitting device according to claim 1,
wherein the GSP_Slope (mV/nm) of the evaporated film of the material included in the first electron-transport layer is smaller than or equal to −50 mV/nm.

3. The light-emitting device according to claim 1,
wherein a refractive index of the evaporated film of the material included in the first electron-transport layer is lower than a refractive index of an evaporated film of a material included in the second electron-transport layer, and
wherein each of the refractive indexes is an ordinary refractive index at a peak wavelength of an emission spectrum of the light-emitting device.

4. The light-emitting device according to claim 1,
wherein a difference between the GSP_Slope (mV/nm) of the evaporated film of the material included in the first electron-transport layer and a GSP_Slope (mV/nm) of an evaporated film of a material included in the second electron-transport layer is larger than or equal to 10 mV/nm.

5. The light-emitting device according to claim 1,
wherein a difference between the GSP_Slope (mV/nm) of the evaporated film of the material included in the first electron-transport layer and a GSP_Slope (mV/nm) of an evaporated film of a material included in the second electron-transport layer is larger than or equal to 50 mV/nm.

6. The light-emitting device according to claim 1,
wherein the thickness of the second electron-transport layer is greater than or equal to 3 nm.

7. The light-emitting device according to claim 1,
wherein the first electron-transport layer contains an organic compound including a fluoro group or a cyano group.

8. A light-emitting device comprising:
an anode over an insulating surface;
a cathode opposite to the anode; and
a first electron-transport layer and a second electron-transport layer which are between the anode and the cathode,
wherein the first electron-transport layer and the second electron-transport layer are in contact with each other,
wherein the second electron-transport layer and the cathode are in contact with each other,
wherein a GSP_Slope (mV/nm) of an evaporated film of a material included in the second electron-transport layer is larger than a GSP_Slope (mV/nm) of an evaporated film of a material included in the first electron-transport layer,
wherein a thickness of the second electron-transport layer is greater than 0 nm and less than 10 nm, and
wherein each of the GSP_Slopes (mV/nm) is represented by ΔV/Δd, where ΔV (mV) is an amount of change in a surface potential with respect to an amount of change in a thickness Δd (nm).

9. The light-emitting device according to claim 8,
wherein the GSP_Slope (mV/nm) of the evaporated film of the material included in the first electron-transport layer is smaller than or equal to −50 mV/nm.

10. The light-emitting device according to claim 8,
wherein a refractive index of the evaporated film of the material included in the first electron-transport layer is lower than a refractive index of the evaporated film of the material included in the second electron-transport layer, and
wherein each of the refractive indexes is an ordinary refractive index at a peak wavelength of an emission spectrum of the light-emitting device.

11. The light-emitting device according to claim 8,
wherein a difference between the GSP_Slope (mV/nm) of the evaporated film of the material included in the first electron-transport layer and the GSP_Slope (mV/nm) of the evaporated film of the material included in the second electron-transport layer is larger than or equal to 10 mV/nm.

12. The light-emitting device according to claim 8,
wherein a difference between the GSP_Slope (mV/nm) of the evaporated film of the material included in the first electron-transport layer and the GSP_Slope (mV/nm) of the evaporated film of the material included in the second electron-transport layer is larger than or equal to 50 mV/nm.

13. The light-emitting device according to claim 8,
wherein the thickness of the second electron-transport layer is greater than or equal to 3 nm.

14. The light-emitting device according to claim 8,
wherein the GSP_Slope (mV/nm) of the evaporated film of the material included in the first electron-transport layer is smaller than 0 mV/nm.

15. The light-emitting device according to claim 8,
wherein the first electron-transport layer contains an organic compound including a fluoro group or a cyano group.

16. A light-emitting device comprising:
an anode over an insulating surface;
a cathode opposite to the anode; and
a first electron-transport layer and a second electron-transport layer which are between the anode and the cathode,
wherein the first electron-transport layer and the second electron-transport layer are in contact with each other,
wherein the second electron-transport layer and the cathode are in contact with each other,
wherein a GSP_Slope (mV/nm) of an evaporated film of a material included in the second electron-transport layer is larger than a GSP_Slope (mV/nm) of an evaporated film of a material included in the first electron-transport layer,
wherein a thickness of the second electron-transport layer is smaller than a thickness of the first electron-transport layer, and
wherein each of the GSP_Slopes (mV/nm) is represented by ΔV/Δd, where ΔV (mV) is an amount of change in a surface potential with respect to an amount of change in a thickness Δd (nm).

17. The light-emitting device according to claim 16,
wherein the GSP_Slope (mV/nm) of the evaporated film of the material included in the first electron-transport layer is smaller than or equal to −50 mV/nm.

18. The light-emitting device according to claim 16,
wherein a refractive index of the evaporated film of the material included in the first electron-transport layer is lower than a refractive index of the evaporated film of the material included in the second electron-transport layer, and
wherein each of the refractive indexes is an ordinary refractive index at a peak wavelength of an emission spectrum of the light-emitting device.

19. The light-emitting device according to claim 16,
wherein a difference between the GSP_Slope (mV/nm) of the evaporated film of the material included in the first electron-transport layer and the GSP_Slope (mV/nm) of the evaporated film of the material included in the second electron-transport layer is larger than or equal to 10 mV/nm.

20. The light-emitting device according to claim 16,
wherein a difference between the GSP_Slope (mV/nm) of the evaporated film of the material included in the first electron-transport layer and the GSP_Slope (mV/nm) of the evaporated film of the material included in the second electron-transport layer is larger than or equal to 50 mV/nm.

21. The light-emitting device according to claim 16,
wherein the thickness of the second electron-transport layer is greater than or equal to 3 nm.

22. The light-emitting device according to claim 16,
wherein the GSP_Slope (mV/nm) of the evaporated film of the material included in the first electron-transport layer is smaller than 0 mV/nm.

23. The light-emitting device according to claim 16,
wherein the first electron-transport layer contains an organic compound including a fluoro group or a cyano group.
